(19) United States
(12) Patent Application Publication
(10) Pub. No.: US 2024/0423025 A1
(43) Pub. Date: Dec. 19, 2024

(54) DISPLAY APPARATUS AND METHOD FOR MANUFACTURING DISPLAY APPARATUS

(71) Applicant: Semiconductor Energy Laboratory Co., Ltd., Atsugi-shi, Kanagawa-ken (JP)

(72) Inventors: Ryota HODO, Atsugi (JP); Yasunori SASAMURA, Hiratsuka (JP); Shinya SASAGAWA, Chigasaki (JP)

(21) Appl. No.: 18/701,269

(22) PCT Filed: Oct. 14, 2022
(86) PCT No.: PCT/IB2022/059841

§ 371 Date: Apr. 15, 2024

(30) Foreign Application Priority Data
Oct. 27, 2021 (JP) 2021-175483
Oct. 27, 2021 (JP) 2021-175545

(51) Int. Cl. H10K 59/122; H10K 59/12; H10K 59/80

(52) U.S. Cl. CPC H10K 59/122; H10K 59/1201; H10K 59/80515; H10K 59/80517

(57) ABSTRACT

A display apparatus with high display quality is provided. The display apparatus includes a first light-emitting device, a second light-emitting device, a first coloring layer, a second coloring layer, and a first insulating layer. The first light-emitting device includes a first pixel electrode over the first insulating layer, a first EL layer over the first pixel electrode, and a common electrode over the first EL layer. The second light-emitting device includes a second pixel electrode over the first insulating layer, a second EL layer over the second pixel electrode, and the common electrode over the second EL layer. The first coloring layer is provided to overlap with the first light-emitting device. The second coloring layer is provided to overlap with the second light-emitting device. The first coloring layer and the second coloring layer transmit light of different wavelength ranges. The first insulating layer includes a depressed portion between the first pixel electrode and the second pixel electrode. A third EL layer is provided in the depressed portion of the first insulating layer. The first EL layer, the second EL layer, and the third EL layer contain the same material. The sum of the thickness of the first pixel electrode and the depth of the depressed portion is larger than the thickness of the third EL layer.

### TECHNICAL FIELD

One embodiment of the present invention relates to a display apparatus. One embodiment of the present invention relates to an electronic device.

Note that one embodiment of the present invention is not limited to the above technical field. Examples of a technical field of one embodiment of the present invention disclosed in this specification and the like include a semiconductor device, a display apparatus, a light-emitting apparatus, a power storage device, a memory device, an electronic device, a lighting device, an input device, an input/output device, a driving method thereof, and a manufacturing method thereof. A semiconductor device refers to any device that can function by utilizing semiconductor characteristics.

### BACKGROUND ART

In recent years, higher-resolution display panels have been required. Examples of devices that require high-resolution display panels include a smartphone, a tablet terminal, and a notebook computer. Furthermore, higher resolution has been required for a stationary display apparatus such as a television device or a monitor device along with an increase in definition. An example of a device required to have the highest resolution is a device for virtual reality (VR) or augmented reality (AR).

Examples of a display apparatus that can be used for a display panel include, typically, a liquid crystal display apparatus, a light-emitting apparatus provided with a light-emitting device such as an organic EL (Electro Luminescence) element or a light-emitting diode (LED), and electronic paper performing display by an electrophoretic method or the like.

For example, the basic structure of an organic EL element is a structure where a layer containing a light-emitting organic compound is provided between a pair of electrodes. By voltage application to this element, light emission can be obtained from the light-emitting organic compound. A display apparatus containing such an organic EL element does not need a backlight that is necessary for a liquid crystal display apparatus and the like; thus, a thin, lightweight, high-contrast, and low-power-consumption display apparatus can be achieved. Patent Document 1, for example, discloses an example of a display apparatus using an organic EL element.

### REFERENCE

### Patent Document

[Patent Document 1] Japanese Published Patent Application No. 2002-324673

### SUMMARY OF THE INVENTION

### Problems to be Solved by the Invention

An object of one embodiment of the present invention is to provide a display apparatus with high display quality. An object of one embodiment of the present invention is to provide a display apparatus with a high aperture ratio. An object of one embodiment of the present invention is to provide a highly reliable display apparatus. An object of one embodiment of the present invention is to provide a display apparatus that can easily achieve a higher resolution. An object of one embodiment of the present invention is to provide a display apparatus with low power consumption.

An object of one embodiment of the present invention is to at least reduce at least one of problems of the conventional technique.

Note that the description of these objects does not preclude the existence of other objects. One embodiment of the present invention does not have to achieve all of these objects. Note that objects other than these can be derived from the description of the specification, the drawings, the claims, and the like.

### Means for Solving the Problems

One embodiment of the present invention is a display apparatus including a first light-emitting device, a second light-emitting device, a first coloring layer, a second coloring layer, and a first insulating layer. The first light-emitting device includes a first pixel electrode over the first insulating layer, a first EL layer over the first pixel electrode, and a common electrode over the first EL layer. The second light-emitting device includes a second pixel electrode over the first insulating layer, a second EL layer over the second pixel electrode, and the common electrode over the second EL layer. The first coloring layer is provided to overlap with the first light-emitting device. The second coloring layer is provided to overlap with the second light-emitting device. The first coloring layer and the second coloring layer transmit light of different wavelength ranges. The first insulating layer includes a depressed portion between the first pixel electrode and the second pixel electrode. A third EL layer is provided in the depressed portion of the first insulating layer. The first EL layer, the second EL layer, and the third EL layer contain the same material. A sum of a thickness of the first pixel electrode and a depth of the depressed portion is larger than a thickness of the third EL layer.

In the above, a structure where the third EL layer is in contact with a bottom surface and a side surface of the depression portion of the first insulating layer, a side surface of the first pixel electrode, and a side surface of the second pixel electrode may be employed.

In the above, the thickness of the first pixel electrode is preferably larger than or equal to the thickness of the third EL layer.

In the above, it is preferable that the depth of the depressed portion be larger than or equal to the thickness of the third EL layer, and the third EL layer be in contact with neither the first pixel electrode nor the second pixel electrode.

In the above, it is preferable that each of the first pixel electrode and the second pixel electrode include a first conductive layer over the first insulating layer and a second conductive layer over the first conductive layer, and a side surface of the second conductive layer project from a side surface of the first conductive layer. In the above, a sum of the thickness of the first pixel electrode in a portion lower than a bottom surface of the second conductive layer and the depth of the depression portion is preferably larger than or equal to the thickness of the third EL layer.

In the above, it is preferable that each of the first pixel electrode and the second pixel electrode include a third conductive layer under the first conductive layer, the first conductive layer have a reflecting property, and the second conductive layer and the third conductive layer have a function of protecting the first conductive layer.

In the above, the first conductive layer preferably contains aluminum. In the above, the second conductive layer preferably contains titanium oxide. In the above, the third conductive layer preferably contains titanium.

In the above, it is preferable that the first pixel electrode and the second pixel electrode each include a fourth conductive layer over the second conductive layer, the fourth conductive layer have a higher work function than the second conductive layer, the second conductive layer and the fourth conductive layer have a light-transmitting property, and the fourth conductive layer contain an oxide containing any one or more selected from indium, tin, zinc, gallium, titanium, aluminum, and silicon.

In the above, it is preferable that a second insulating layer over the third EL layer and a third insulating layer over the second insulating layer be included, the second insulating layer contain an inorganic material, the third insulating layer contain an organic material, part of the second insulating layer and part of the third insulating layer be provided in a position interposed between a side surface of the first EL layer and a side surface of the first pixel electrode, and a side surface of the second EL layer and the second pixel electrode, and another part of the third insulating layer overlap with part of a top surface of the first EL layer and part of a top surface of the second EL layer with the second insulating layer therebetween.

In the above, the second insulating layer is preferably in contact with the side surface of the first pixel electrode and a side surface of the second pixel electrode. In the above, the common electrode is preferably provided over the third insulating layer.

In the above, it is preferable that the first light-emitting device include a common layer provided between the first EL layer and the common electrode, and the second light-emitting device include the common layer provided between the second EL layer and the common electrode.

In the above, the first coloring layer and the second coloring layer are each preferably provided over the common electrode.

In the above, it is preferable that the first EL layer include a first light-emitting unit over the first pixel electrode, a first charge-generation layer over the first light-emitting unit, and a second light-emitting unit over the first charge-generation layer, the second EL layer include a third light-emitting unit over the second pixel electrode, a second charge-generation layer over the third light-emitting unit, and a fourth light-emitting unit over the second charge-generation layer, and the third EL layer include a fifth light-emitting unit over the first insulating layer, a third charge-generation layer over the fifth light-emitting unit, and a sixth light-emitting unit over the third charge-generation layer.

In the above, it is preferable that the first light-emitting unit, the third light-emitting unit, and the fifth light-emitting unit contain the same material, the first charge-generation layer, the second charge-generation layer, and the third charge-generation layer contain the same material, and the second light-emitting unit, the fourth light-emitting unit, and the sixth light-emitting unit contain the same material.

Another embodiment of the present invention is a method for manufacturing a display apparatus including a plurality of pixel electrodes each of which includes a first conductive layer, a second conductive layer, and a third conductive layer. In manufacturing the display apparatus including the plurality of pixel electrodes, a first conductive film, a second conductive film, and a third conductive film are formed in this order over an insulating layer. The third conductive film, the second conductive film, and the first conductive film are processed into the third conductive layer, the second conductive layer, and the first conductive layer by first dry etching. A side surface of the second conductive layer is processed by isotropic etching. A depressed portion is formed in a region of the insulating layer not overlapping with the plurality of pixel electrodes by second dry etching. An EL film is formed by an evaporation method. An etching rate of the second conductive layer is higher than an etching rate of the third conductive layer in the isotropic etching. The EL film is divided into first EL layers formed over the plurality of pixel electrodes and second EL layers formed between the plurality of pixel electrodes in a self-aligned manner.

In the above, a gas containing chlorine is preferably used for the isotropic etching.

### Effect of the Invention

A display apparatus with high display quality can be provided. According to one embodiment of the present invention, a display apparatus with a high aperture ratio can be provided. A highly reliable display apparatus can be provided. A display apparatus that can easily achieve a higher resolution can be provided. A display apparatus with low power consumption can be provided. At least one of problems of the conventional technique can be at least reduced.

Note that the description of these effects does not preclude the existence of other effects. One embodiment of the present invention does not need to have all of these effects. Note that effects other than these can be derived from the description of the specification, the drawings, the claims, and the like.

### BRIEF DESCRIPTION OF THE DRAWINGS

FIG. 1A is a top view illustrating an example of a display apparatus. FIG. 1B is a cross-sectional view illustrating an example of a display apparatus.

FIG. 2A to FIG. 2D are enlarged cross-sectional views illustrating examples of a display apparatus.

FIG. 3A to FIG. 3C are enlarged cross-sectional views illustrating examples of a display apparatus.

FIG. 4A and FIG. 4B are enlarged cross-sectional views illustrating examples of a display apparatus.

FIG. 5A and FIG. 5B are cross-sectional views illustrating examples of a display apparatus.

FIG. 6A to FIG. 6C are cross-sectional views illustrating examples of a display apparatus.

FIG. 7A to FIG. 7C are cross-sectional views illustrating an example of a method for manufacturing a display apparatus.

FIG. 8A to FIG. 8C are cross-sectional views illustrating an example of a method for manufacturing a display apparatus.

FIG. 9A to FIG. 9E are cross-sectional views illustrating an example of a method for manufacturing a display apparatus.

FIG. 10A is a cross-sectional view illustrating an example of a method for manufacturing a display apparatus, and FIG. 10B and FIG. 10C are cross-sectional views illustrating examples of a display apparatus.

FIG. 11A to FIG. 11G are top views illustrating examples of pixels.

FIG. 12A to FIG. 12I are top views illustrating examples of a pixel.

FIG. 13A to FIG. 13K are top views illustrating examples of pixels.

FIG. 14A and FIG. 14B are perspective views illustrating an example of a display apparatus.

FIG. 15 is a cross-sectional view illustrating an example of a display apparatus.

FIG. 16 is a cross-sectional view illustrating an example of a display apparatus.

FIG. 17 is a cross-sectional view illustrating an example of a display apparatus.

FIG. 18 is a cross-sectional view illustrating an example of a display apparatus.

FIG. 19 is a cross-sectional view illustrating an example of a display apparatus.

FIG. 20 is a cross-sectional view illustrating an example of a display apparatus.

FIG. 21 is a perspective view illustrating an example of a display apparatus.

FIG. 22A is a cross-sectional view illustrating an example of a display apparatus. FIG. 22B and FIG. 22C are cross-sectional views illustrating examples of transistors.

FIG. 23 is a cross-sectional view illustrating an example of a display apparatus.

FIG. 24A to FIG. 24D are cross-sectional views illustrating examples of a display apparatus.

FIG. 25A is a block diagram illustrating an example of a display apparatus. FIG. 25B to FIG. 25E are diagrams illustrating examples of a pixel circuit.

FIG. 26A to FIG. 26D are diagrams illustrating examples of transistors.

FIG. 27A to FIG. 27F are diagrams illustrating structure examples of a light-emitting device.

FIG. 28A to FIG. 28C are diagrams illustrating structure examples of a light-emitting device.

FIG. 29A to FIG. 29D are diagrams illustrating examples of electronic devices.

FIG. 30A to FIG. 30F are diagrams illustrating examples of electronic devices.

FIG. 31A to FIG. 31G are diagrams illustrating examples of electronic devices.

FIG. 32A to FIG. 32D are cross-sectional STEM images in Example.

### MODE FOR CARRYING OUT THE INVENTION

Embodiments will be described below with reference to the drawings. Note that the embodiments can be implemented with many different modes, and it will be readily understood by those skilled in the art that modes and details thereof can be changed in various ways without departing from the spirit and scope thereof. Therefore, the present invention should not be construed as being limited to the description of embodiments below.

Note that in structures of the invention described below, the same reference numerals are commonly used for the same portions or portions having similar functions in different drawings, and a repeated description thereof is omitted. Furthermore, the same hatch pattern is used for the portions having similar functions, and the portions are not especially denoted by reference numerals in some cases.

Note that in each drawing described in this specification, the size, the layer thickness, or the region of each component is exaggerated for clarity in some cases. Therefore, they are not limited to the illustrated scale.

Note that ordinal numbers such as “first” and “second” in this specification and the like are used in order to avoid confusion among components and do not limit the number of components.

In this specification and the like, a display apparatus may be rephrased as an electronic device.

In this specification and the like, a device manufactured using a metal mask or an FMM (a fine metal mask or a high-resolution metal mask) is sometimes referred to as a device having an MM (metal mask) structure. In this specification and the like, a device manufactured without using a metal mask or an FMM is sometimes referred to as a device having an MML (metal maskless) structure.

In this specification and the like, a hole or an electron is sometimes referred to as a “carrier”. Specifically, a hole-injection layer or an electron-injection layer may be referred to as a “carrier-injection layer”, a hole-transport layer or an electron-transport layer may be referred to as a “carrier-transport layer”, and a hole-blocking layer or an electron-blocking layer may be referred to as a “carrier-blocking layer”. Note that in some cases, the above-described carrier-injection layer, carrier-transport layer, and carrier-blocking layer cannot be distinguished from one another on the basis of the cross-sectional shape, properties, or the like. Furthermore, one layer may have two or three functions of the carrier-injection layer, the carrier-transport layer, and the carrier-blocking layer in some cases.

In this specification and the like, a light-emitting device (also referred to as a light-emitting element) includes an EL layer between a pair of electrodes. The EL layer includes at least a light-emitting layer. Here, examples of a layer included in the EL layer (also referred to as a functional layer) include a light-emitting layer, carrier-injection layers (a hole-injection layer and an electron-injection layer), carrier-transport layers (a hole-transport layer and an electron-transport layer), and carrier-blocking layers (a hole-blocking layer and an electron-blocking layer).

### Embodiment 1

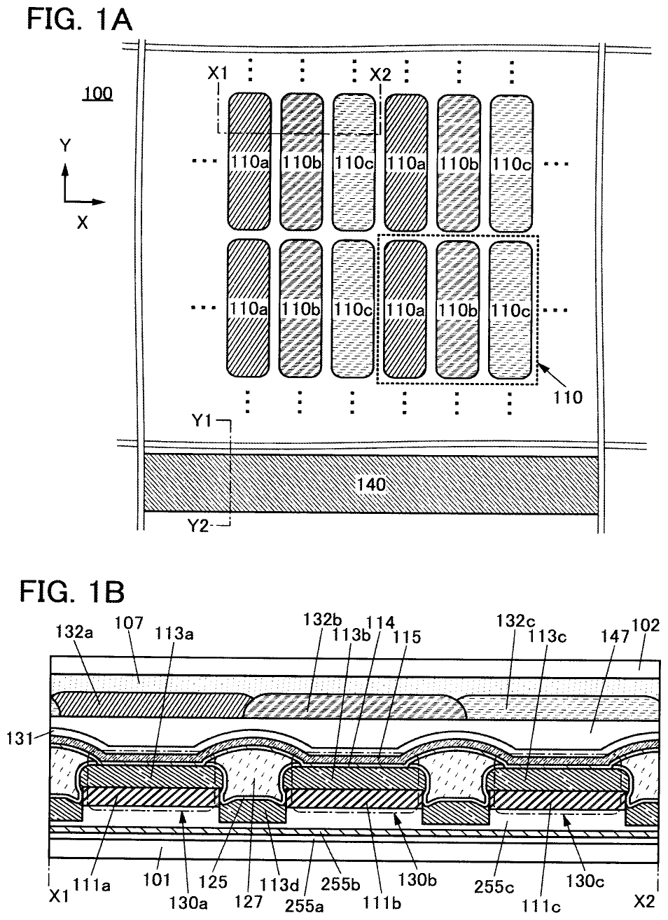

In this embodiment, a display apparatus of one embodiment of the present invention is described with reference to FIG. 1 to FIG. 9.

One embodiment of the present invention is a display apparatus that includes a display portion capable of full-color display. The display portion includes a first subpixel and a second subpixel that emit light of different colors. The first subpixel includes a first light-emitting device that emits white light and the second subpixel includes a second light-emitting device that also emits white light. A first coloring layer is provided to overlap with the first light-emitting device in the first subpixel and a second coloring layer is provided to overlap with the second light-emitting device in the second subpixel. The first coloring layer and the second coloring layer transmit light of different wavelength ranges. Coloring layers that can transmit visible light of different colors are thus used in each subpixel, whereby full-color display can be performed. Furthermore, light-emitting devices used in each subpixel can be formed using the same materials; thus, the manufacturing process can be simplified and the manufacturing cost can be reduced.

Here, in the case where each subpixel is formed using a light-emitting device that emits white light, separate formation of light-emitting layers in the subpixels is not necessary. Thus, layers other than a pixel electrode included in the light-emitting device (e.g., a light-emitting layer) can be shared in each of the subpixels. However, some layers included in the light-emitting device have relatively high conductivity; when a layer having high conductivity is shared in each of the subpixels, leakage current might be generated between the subpixels. Particularly when the increase in resolution or aperture ratio of a display apparatus reduces the distance between the subpixels, the leakage current might become too large to ignore. This causes a decrease in luminance, a decrease in contrast, or the like, leading to a reduction in display quality. Furthermore, power efficiency, power consumption, or the like is adversely affected by the leakage current.

Therefore, in one embodiment of the present invention, by making a step formed by a pixel electrode and a depressed portion of an insulating layer under the pixel electrode sufficiently large, a formed EL film is divided in a self-aligned manner into an EL layer over the pixel electrode and an EL layer formed between the pixel electrodes. Here, the step formed by the pixel electrode and the depressed portion of the insulating layer under the pixel electrode is preferably larger than the thickness of the EL layer formed between the pixel electrodes.

With such a structure, a leakage current path between two adjacent light-emitting devices can be cut, whereby leakage current can be inhibited. Accordingly, a higher luminance, a higher contrast, higher display quality, higher power efficiency, lower power consumption, or the like can be achieved.

As described above, the EL layers formed in the method for manufacturing a display apparatus of one embodiment of the present invention are formed not by using a metal mask having a fine pattern but by dividing, in a self-aligned manner, an EL film formed over the entire surface. Accordingly, a high-resolution display apparatus or a display apparatus with a high aperture ratio, which has been difficult to achieve, can be achieved.

It is difficult to reduce the distance between adjacent light-emitting devices to less than 10 mm with a formation method using a fine metal mask, for example. However, the above method can shorten the distance between adjacent light-emitting devices, adjacent EL layers, or adjacent pixel electrodes to less than 10 mm, less than or equal to 8 mm, less than or equal to 5 mm, less than or equal to 3 mm, less than or equal to 2 mm, less than or equal to 1.5 mm, less than or equal to 1 mm, or even less than or equal to 0.5 mm, for example, in a process over a glass substrate. Accordingly, the area of a non-light-emitting region that could exist between two light-emitting devices can be significantly reduced, and the aperture ratio can be close to 100%. For example, the aperture ratio of the display apparatus of one embodiment of the present invention is higher than or equal to 40%, higher than or equal to 50%, higher than or equal to 60%, higher than or equal to 70%, higher than or equal to 80%, or higher than or equal to 90%; that is, an aperture ratio lower than 100% can be achieved.

Increasing the aperture ratio of the display apparatus can improve the reliability of the display apparatus. Specifically, with reference to the lifetime of a display apparatus including an organic EL element and having an aperture ratio of 10%, a display apparatus having an aperture ratio of 20% (i.e., having an aperture ratio two times higher than the reference) has a lifetime approximately 3.25 times longer than the reference, and a display apparatus having an aperture ratio of 40% (i.e., having an aperture ratio four times higher than the reference) has a lifetime approximately 10.6 times longer than the reference. Thus, the density of current flowing to the organic EL element can be reduced with increasing aperture ratio, and accordingly the lifetime of the display apparatus can be increased. The display apparatus of one embodiment of the present invention can have a higher aperture ratio and thus the display apparatus can have higher display quality. Furthermore, an excellent effect that the reliability (especially the lifetime) of the display apparatus is significantly improved with increasing aperture ratio of the display apparatus can be produced.

### [Structure Example 1 of Display Apparatus]

FIG. 1 to FIG. 12 illustrate a display apparatus of one embodiment of the present invention.

FIG. 1A is a top view of a display apparatus 100. The display apparatus 100 includes a display portion in which a plurality of pixels 110 are arranged, and a connection portion 140 outside the display portion. A plurality of subpixels are arranged in a matrix in the display portion. FIG. 1A illustrates subpixels arranged in two rows and six columns, which form pixels in two rows and two columns. The connection portion 140 can also be referred to as a cathode contact portion.

The pixel 110 illustrated in FIG. 1A employs stripe arrangement. The pixel 110 illustrated in FIG. 1A is composed of three subpixels 110a, 110b, and 110c. The subpixels 110a, 110b, and 110c each include a light-emitting device that emit white light. A coloring layer 132a, a coloring layer 132b, or a coloring layer 132c (hereinafter collectively referred to as a coloring layer 132 in some cases) is provided to overlap with each of the above-described light-emitting devices in the subpixel 110a, the subpixel 110b, and the subpixel 110c. Note that the coloring layer 132a, the coloring layer 132b, and the coloring layer 132c transmit light of different wavelengths; thus, the subpixel 110a, the subpixel 110b, and the subpixel 110c emit light of different colors. As the subpixels 110a, 110b, and 110c, subpixels of three colors of red (R), green (G), and blue (B) or subpixels of three colors of yellow (Y), cyan (C), and magenta (M) can be given, for example. The number of types of subpixels is not limited to three, and may be four or more. As the four subpixels, subpixels of four colors of R, G, B, and white (W) and subpixels of four colors of R, G, B, and Y can be given, for example.

In this specification and the like, the row direction and the column direction are sometimes referred to as the X direction and the Y direction, respectively. The X direction and the Y direction intersect with each other and are, for example, orthogonal to each other (see FIG. 1A).

FIG. 1A illustrates an example where subpixels of different colors are arranged in the X direction and subpixels of the same color are arranged in the Y direction.

Although FIG. 1A illustrates an example where the connection portion 140 is positioned on the lower side of the display portion in the top view, one embodiment of the present invention is not particularly limited. The connection portion 140 only needs to be provided on at least one of the upper side, the right side, the left side, and the lower side of the display portion, and may be provided to surround the four sides of the display portion in the top view. The top surface shape of the connection portion 140 can be a belt-like shape, an L shape, a U shape, a frame-like shape, or the like. The number of the connection portions 140 can be one or more.

FIG. 1B is a cross-sectional view along dashed-dotted line X1-X2 in FIG. 1A. In the display apparatus 100, a layer including a transistor is provided over a substrate 101, insulating layers 255a, 255b, and 255c are provided over the layer including the transistor, light-emitting devices 130a, 130b, and 130c are provided over the insulating layers 255a, 255b, and 255c, and a protective layer 131 is provided to cover these light-emitting devices. In a region between adjacent light-emitting devices, an insulating layer 125 and an insulating layer 127 over the insulating layer 125 are provided. Hereinafter, the light-emitting devices 130a, 130b, and 130c are collectively referred to as a “light-emitting device 130” in some cases.

Although FIG. 1B and the like illustrate a plurality of cross sections of the insulating layers 125 and the insulating layers 127, when the display apparatus 100 is seen from above, the insulating layers 125 and the insulating layers 127 are each one continuous layer. In other words, the display apparatus 100 can have a structure including one the insulating layer 125 and one the insulating layer 127, for example. Note that the display apparatus 100 may include a plurality of the insulating layers 125 which are separated from each other and a plurality of the insulating layers 127 which are separated from each other.

In FIG. 1B and the like, a resin layer 147 is provided over the protective layer 131, the coloring layer 132 is provided over the resin layer 147. Here, the coloring layer 132a is provided to overlap with the light-emitting device 130a, the coloring layer 132b is provided to overlap with the light-emitting device 130b, and the coloring layer 132c is provided to overlap with the light-emitting device 130c.

As illustrated in FIG. 1B, in the display apparatus 100, an adhesive layer 107 and a substrate 102 are provided over the coloring layer 132. The substrate 102 is bonded to the substrate 101 with the adhesive layer 107 therebetween. Here, the adhesive layer 107 is in contact with the coloring layer 132 and the substrate 102.

As illustrated in FIG. 1B, the display apparatus of one embodiment of the present invention is a top-emission structure in which light is emitted in a direction opposite to the substrate where the light-emitting device is formed. However, this invention is not limited thereto, a bottom-emission structure in which light is emitted toward the substrate where the light-emitting device is formed or a dual-emission structure in which light is emitted toward both surfaces may be employed.

As the light-emitting devices 130a, 130b, and 130c, a light-emitting device such as an OLED (Organic Light Emitting Diode) or a QLED (Quantum-dot Light Emitting Diode) is preferably used. Examples of a light-emitting substance contained in the light-emitting device include a substance that emits fluorescent light (a fluorescent material), a substance that emits phosphorescent light (a phosphorescent material), an inorganic compound (a quantum dot material or the like), and a substance that exhibits thermally activated delayed fluorescence (a thermally activated delayed fluorescent (TADF) material). Note that as a TADF material, a material in which a singlet excited state and a triplet excited state are in a thermal equilibrium state may be used. Since such a TADF material enables a short emission lifetime (excitation lifetime), an efficiency decrease of a light-emitting device in a high-luminance region can be inhibited.

The light-emitting device includes an EL layer between a pair of electrodes. The EL layer includes at least a light-emitting layer. In this specification and the like, one of the pair of electrodes may be referred to as a pixel electrode and the other may be referred to as a common electrode.

One of the pair of electrodes of the light-emitting device functions as an anode, and the other electrode functions as a cathode. The case where the pixel electrode functions as an anode and the common electrode functions as a cathode will be described below as an example in some cases.

The light-emitting device 130a includes the pixel electrode 111a over the insulating layer 255c, the island-shaped first layer 113a over the pixel electrode 111a, a common layer 114 over the island-shaped first layer 113a, and a common electrode 115 over the common layer 114. Here, the first layer 113a functions as an EL layer including a light-emitting layer. In the light-emitting device 130a, the first layer 113a and the common layer 114 can also be collectively referred to as an EL layer.

The light-emitting device 130b includes a pixel electrode 111b over the insulating layer 255c, an island-shaped second layer 113b over the pixel electrode 111b, the common layer 114 over the island-shaped second layer 113b, and the common electrode 115 over the common layer 114. Here, the second layer 113b functions as an EL layer including a light-emitting layer. In the light-emitting device 130b, the second layer 113b and the common layer 114 can be collectively referred to as an EL layer.

The light-emitting device 130c includes a pixel electrode 111c over the insulating layer 255c, an island-shaped third layer 113c over the pixel electrode 111c, the common layer 114 over the island-shaped third layer 113c, and the common electrode 115 over the common layer 114. Here, the third layer 113c functions as an EL layer including a light-emitting layer. In the light-emitting device 130c, the third layer 113c and the common layer 114 can be collectively referred to as an EL layer. Hereinafter, the first layer 113a, the second layer 113b, and the third layer 113c are collectively referred to as an EL layer 113 in some cases.

Note that in this specification and the like, the term “island shape” refers to a state where two or more layers formed using the same material in the same step are physically separated from each other. For example, “island-shaped light-emitting layer” means a state where the light-emitting layer and its adjacent light-emitting layer are physically separated from each other. The pixel electrodes 111a, 111b, and 111c are collectively referred to as a pixel electrode 111 in some cases.

As a material for forming the pixel electrode 111, a metal, an alloy, an electrically conductive compound, a mixture thereof, and the like can be used as appropriate. Specific examples include indium tin oxide (In—Sn oxide, also referred to as ITO), In—Si—Sn oxide (also referred to as ITSO), indium zinc oxide (In—Zn oxide), In—W—Zn oxide, an alloy containing aluminum (an aluminum alloy) such as an alloy of aluminum, nickel, and lanthanum (Al—Ni—La), and an alloy of silver, palladium, and copper (Ag—Pd—Cu, also referred to as APC). In addition, it is possible to use a metal such as aluminum (Al), magnesium (Mg), titanium (Ti), chromium (Cr), manganese (Mn), iron (Fe), cobalt (Co), nickel (Ni), copper (Cu), gallium (Ga), zinc (Zn), indium (In), tin (Sn), molybdenum (Mo), tantalum (Ta), tungsten (W), palladium (Pd), gold (Au), platinum (Pt), silver (Ag), yttrium (Y), or neodymium (Nd) or an alloy containing an appropriate combination of any of these metals. It is also possible to use a Group 1 element or a Group 2 element in the periodic table, which is not exemplified above (e.g., lithium (Li), cesium (Cs), calcium (Ca), or strontium (Sr)), a rare earth metal such as europium (Eu) or ytterbium (Yb), an alloy containing an appropriate combination of any of these elements, graphene, or the like.

The layer including a transistor above the substrate 101 can have a stacked-layer structure in which a plurality of transistors are provided over a substrate and an insulating layer is provided to cover these transistors, for example. The insulating layer over the transistors may have a single-layer structure or a stacked-layer structure. In FIG. 1B and the like, the insulating layer 255a, the insulating layer 255b over the insulating layer 255a, and the insulating layer 255c over the insulating layer 255b are illustrated as the insulating layer over the transistors. These insulating layers may have a depressed portion between adjacent light-emitting devices. FIG. 1B and the like illustrate an example in which a depressed portion is provided in a region of the insulating layer 255c that does not overlap with the pixel electrode 111 (e.g., a region between the pixel electrode 111a and the pixel electrode 111b).

As each of the insulating layer 255a, the insulating layer 255b, and the insulating layer 255c, any of a variety of inorganic insulating films such as an oxide insulating film, a nitride insulating film, an oxynitride insulating film, and a nitride oxide insulating film can be suitably used. As each of the insulating layer 255a and the insulating layer 255c, an oxide insulating film or an oxynitride insulating film, such as a silicon oxide film, a silicon oxynitride film, or an aluminum oxide film, is preferably used. As the insulating layer 255b, a nitride insulating film or a nitride oxide insulating film, such as a silicon nitride film or a silicon nitride oxide film, is preferably used. More specifically, it is preferable that a silicon oxide film be used as the insulating layer 255a and the insulating layer 255c and a silicon nitride film be used as the insulating layer 255b. The insulating layer 255b preferably has a function of an etching protective film. When such a structure is employed, at the time of formation of the depressed portion in the insulating layer 255c, formation of the depressed portion can be stopped with the insulating layer 255b

Note that in this specification and the like, oxynitride refers to a material that contains more oxygen than nitrogen in its composition, and nitride oxide refers to a material that contains more nitrogen than oxygen in its composition. For example, silicon oxynitride refers to a material in which an oxygen content is higher than a nitrogen content, and silicon nitride oxide refers to a material in which a nitrogen content is higher than an oxygen content.

Structure examples of the layer including a transistor above the substrate 101 are described in detail in Embodiment 3 and Embodiment 4.

The first layer 113a, the second layer 113b, and the third layer 113c preferably emit white (W) light. The first layer 113a, the second layer 113b, and the third layer 113c each are a layer including at least a light-emitting layer. The coloring layer 132a is provided to overlap with the first layer 113a, the coloring layer 132b is provided to overlap with the second layer 113b, and the coloring layer 132c is provided to overlap with the third layer 113c. Since the coloring layers 132 transmit light of different wavelengths, the subpixel 110a, the subpixel 110b, and the subpixel 110c can be formed to emit light of different colors. Note that there is no particular limitation on the structure of the light-emitting device in this embodiment, and the light-emitting device can have a single structure or a tandem structure. Note that embodiments described later can be referred to for the structure example of the light-emitting device.

In this embodiment, in the EL layers included in the light-emitting devices, the island-shaped layers provided in the light-emitting devices are referred to as the first layer 113a, the second layer 113b, and the third layer 113c, and the layer shared by the plurality of light-emitting devices is referred to as the common layer 114.

When one EL film is divided at end portions of the pixel electrodes 111 in a self-aligned manner, the first layer 113a, the second layer 113b, and the third layer 113c are provided to be apart from each other in island shapes. Thus, a leakage current path between adjacent EL layers can be cut, whereby leakage current can be inhibited. In this manner, in the light-emitting device, it is possible to increase luminance, contrast, display quality, and power efficiency or to reduce power consumption, for example.

When the first layer 113a, the second layer 113b, and the third layer 113c are formed in a self-aligned manner, a fourth layer 113d is formed in the depressed portion of the insulating layer 255c. The fourth layer 113d is in contact with the bottom surface and a side surface of the depressed portion of the insulating layer 255c and a side surface of the pixel electrode 111. The insulating layer 125 is formed over the fourth layer 113d. The fourth layer 113d is preferably separated from the first layer 113a, the second layer 113b, and the third layer 113c. The fourth layer 113d is formed from the same EL film as the first layer 113a, the second layer 113b, and the third layer 113c; thus, the fourth layer 113d has the same material and the same structure as those of the first layer 113a, the second layer 113b, and the third layer 113c.

Each of the first layer 113a, the second layer 113b, the third layer 113c, and the fourth layer 113d may include one or more of a hole-injection layer, a hole-transport layer, a hole-blocking layer, a charge-generation layer, an electron-blocking layer, an electron-transport layer, and an electron-injection layer.

For example, the first layer 113a, the second layer 113b, the third layer 113c, and the fourth layer 113d may each include a hole-injection layer, a hole-transport layer, a light-emitting layer, and an electron-transport layer. In addition, an electron-blocking layer may be provided between the hole-transport layer and the light-emitting layer. Furthermore, an electron-injection layer may be provided over the electron-transport layer.

The first layer 113a, the second layer 113b, the third layer 113c, and the fourth layer 113d may each include an electron-injection layer, an electron-transport layer, a light-emitting layer, and a hole-transport layer in this order, for example. In addition, a hole-blocking layer may be provided between the electron-transport layer and the light-emitting layer. Furthermore, a hole-injection layer may be provided over the hole-transport layer.

The first layer 113a, the second layer 113b, and the third layer 113c each preferably include a light-emitting layer and a carrier-transport layer (an electron-transport layer or a hole-transport layer) over the light-emitting layer. Since the surfaces of the first layer 113a, the second layer 113b, and the third layer 113c are exposed in the manufacturing process of the display apparatus, providing the carrier-transport layer over the light-emitting layer inhibits the light-emitting layer from being exposed on the outermost surface, so that damage to the light-emitting layer can be reduced. Thus, the reliability of the light-emitting device can be increased.

The first layer 113a, the second layer 113b, the third layer 113c, and the fourth layer 113d may each include a first light-emitting unit, a charge-generation layer, and a second light-emitting unit, for example. The second light-emitting unit preferably includes the light-emitting layer and a carrier-transport layer (an electron-transport layer or a hole-transport layer) over the light-emitting layer. Since a surface of the second light-emitting unit is exposed in the manufacturing process of the display apparatus, providing the carrier-transport layer over the light-emitting layer inhibits the light-emitting layer from being exposed on the outermost surface, so that damage to the light-emitting layer can be reduced. Thus, the reliability of the light-emitting device can be increased.

The first layer 113a, the second layer 113b, and the third layer 113c can emit white light. Thus, the first layer 113a, the second layer 113b, and the third layer 113c have the same structure. Accordingly, the first layer 113a, the second layer 113b, and the third layer 113c are formed by forming a stacked film using common materials and dividing it at the end portions of the pixel electrode 111 in a self-aligned manner. Since the fourth layer 113d is also formed at the same time, the first layer 113a, the second layer 113b, the third layer 113c, and the fourth layer 113d have the same structure. In this manner, the manufacturing process of the display apparatus can be simplified, and the manufacturing cost can be reduced.

The common layer 114 includes an electron-injection layer or a hole-injection layer, for example. Alternatively, the common layer 114 may include a stack of an electron-transport layer and an electron-injection layer, and may include a stack of a hole-transport layer and a hole-injection layer. The common layer 114 is shared by the light-emitting devices 130a, 130b, and 130c.

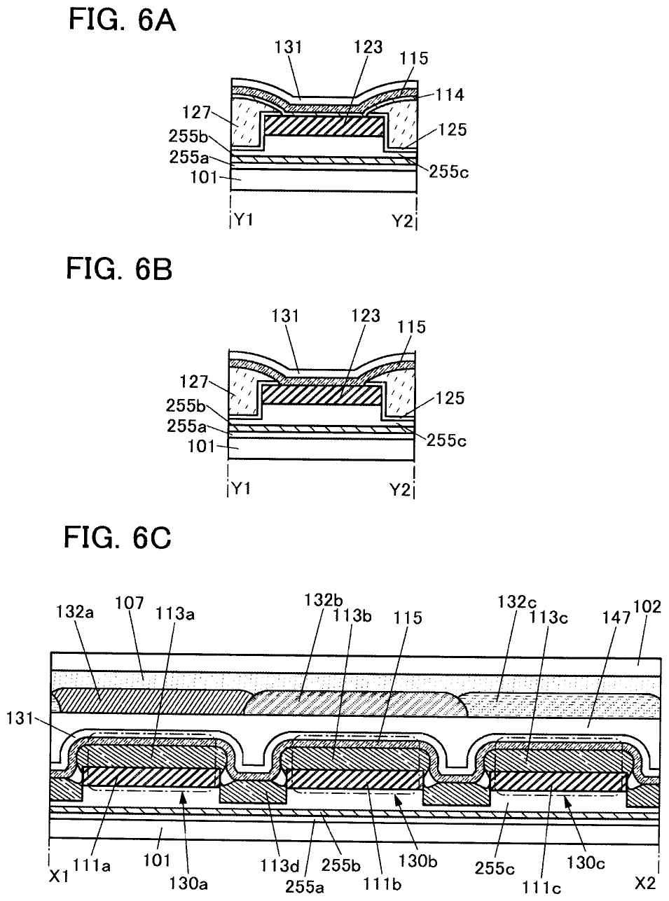

The common electrode 115 is shared by the light-emitting devices 130a, 130b, and 130c. As illustrated in FIG. 6A and FIG. 6B, the common electrode 115 shared by the plurality of light-emitting devices is electrically connected to a conductive layer 123 provided in the connection portion 140. Here, FIG. 6A and FIG. 6B are each a cross-sectional view along dashed-dotted line Y1-Y2 in FIG. 1A. Although a structure above the protective layer 131 is not illustrated in FIG. 6A and FIG. 6B, at least one or more of the resin layer 147, the adhesive layer 107, and the substrate 102 can be provided as appropriate. Alternatively, as the conductive layer 123, a conductive layer formed using the same material in the same step as the pixel electrode 111 is preferably used.

Note that FIG. 6A illustrates an example in which the common layer 114 is provided over the conductive layer 123 and the conductive layer 123 and the common electrode 115 are electrically connected to each other through the common layer 114. The common layer 114 is not necessarily provided in the connection portion 140. In FIG. 6B, the conductive layer 123 and the common electrode 115 are directly connected to each other. For example, by using a mask for specifying a film formation area (also referred to as an area mask, a rough metal mask, or the like to be distinguished from a fine metal mask), the common layer 114 and the common electrode 115 can be formed in different regions.

The protective layer 131 is preferably provided over the light-emitting devices 130a, 130b, and 130c. Providing the protective layer 131 can improve the reliability of the light-emitting devices. The protective layer 131 may have a single-layer structure or a stacked-layer structure of two or more layers.

There is no limitation on the conductivity of the protective layer 131. As the protective layer 131, at least one kind of an insulating film, a semiconductor film, and a conductive film can be used.

The protective layer 131 including an inorganic film can inhibit deterioration of the light-emitting devices by preventing oxidation of the common electrode 115 and inhibiting entry of impurities (e.g., moisture and oxygen) into the light-emitting devices, for example; thus, the reliability of the display apparatus can be improved.

As the protective layer 131, an inorganic insulating film such as an oxide insulating film, a nitride insulating film, an oxynitride insulating film, or a nitride oxide insulating film can be used, for example. Examples of the oxide insulating film include a silicon oxide film, an aluminum oxide film, a gallium oxide film, a germanium oxide film, an yttrium oxide film, a zirconium oxide film, a lanthanum oxide film, a neodymium oxide film, a hafnium oxide film, and a tantalum oxide film. Examples of the nitride insulating film include a silicon nitride film and an aluminum nitride film. Examples of the oxynitride insulating film include a silicon oxynitride film and an aluminum oxynitride film. Examples of the nitride oxide insulating film include a silicon nitride oxide film and an aluminum nitride oxide film. In particular, the protective layer 131 preferably includes a nitride insulating film or a nitride oxide insulating film, and further preferably includes a nitride insulating film.

As the protective layer 131, an inorganic film containing In—Sn oxide (also referred to as ITO), In—Zn oxide, Ga—Zn oxide, Al—Zn oxide, indium gallium zinc oxide (In—Ga—Zn oxide, also referred to as IGZO), or the like can also be used. The inorganic film preferably has high resistance, specifically, higher resistance than the common electrode 115. The inorganic film may further contain nitrogen.

When light emitted from the light-emitting device is extracted through the protective layer 131, the protective layer 131 preferably has a high property of transmitting visible light. For example, ITO, IGZO, and aluminum oxide are preferable because they are inorganic materials having a high property of transmitting visible light.

The protective layer 131 can have, for example, a stacked-layer structure of an aluminum oxide film and a silicon nitride film over the aluminum oxide film, or a stacked-layer structure of an aluminum oxide film and an IGZO film over the aluminum oxide film. Such a stacked-layer structure can inhibit entry of impurities (such as water and oxygen) into the EL layer.

Furthermore, the protective layer 131 may include an organic film. For example, the protective layer 131 may include both an organic film and an inorganic film. Examples of an organic material that can be used for the protective layer 131 include organic insulating materials that can be used for the resin layer 147 described later.

The protective layer 131 may have a stacked-layer structure of two layers which are formed by different formation methods. Specifically, the first layer of the protective layer 131 may be formed by an atomic layer deposition (ALD) method, and the second layer of the protective layer 131 may be formed by a sputtering method.

In FIG. 1B and the like, an insulating layer covering an end portion of the top surface of the pixel electrode 111a is not provided between the pixel electrode 111a and the first layer 113a. An insulating layer covering an end portion of the top surface of the pixel electrode 111b is not provided between the pixel electrode 111b and the second layer 113b. An insulating layer covering an end portion of the top surface of the pixel electrode 111c is not provided between the pixel electrode 111c and the third layer 113c. Thus, the distance between adjacent light-emitting devices can be extremely shortened. Accordingly, the display apparatus can have high resolution or high definition.

As illustrated in FIG. 1B, side surfaces of the first layer 113a, the second layer 113b, and the third layer 113c are each covered with the insulating layer 127 and the insulating layer 125. In other words, part of the insulating layer 125 and part of the insulating layer 127 are interposed between side surfaces of adjacent EL layers (e.g., the side surface of the first layer 113a and the side surface of the second layer 113b) and between side surfaces of adjacent pixel electrodes (e.g., the side surface of the pixel electrode 111a and the side surface of the pixel electrode 111b). Each of the top surfaces of the first layer 113a, the second layer 113b, and the third layer 113c is partly covered with the insulating layer 127, and the insulating layer 125.

The insulating layer 125 preferably covers at least one of the side surfaces of the island-shaped EL layers, and further preferably covers both of the side surfaces of the island-shaped EL layers. The insulating layer 125 can be in contact with the side surfaces of the island-shaped EL layers. The insulating layer 125 is in contact with the side surfaces of the island-shaped pixel electrodes.

In FIG. 1B and the like, the insulating layer 125 covers the side surface and part of the top surface of the first layer 113a and is in contact with the side surface of the pixel electrode 111a. Similarly, the insulating layer 125 covers the side surface and part of the top surface of the second layer 113b and is in contact with the side surface of the pixel electrode 111b. Similarly, the insulating layer 125 covers the side surface and part of the top surface of the third layer 113c and is in contact with the side surface of the pixel electrode 111c.

With the above-described structure, the common layer 114 (or the common electrode 115) can be inhibited from being in contact with the side surfaces of the pixel electrodes 111a, 111b, and 111c, the first layer 113a, the second layer 113b, and the third layer 113c, whereby a short circuit in the light-emitting device can be inhibited. Thus, the reliability of the light-emitting device can be increased.

The insulating layer 127 is provided over the insulating layer 125 to fill a depressed portion of the insulating layer 125. The insulating layer 127 can overlap with the side surfaces and parts of the top surfaces of each of the first layer 113a, the second layer 113b, and the third layer 113c (in other words, the insulating layer 127 can cover the side surfaces) with the insulating layer 125 therebetween.

The insulating layer 125 and the insulating layer 127 can fill a space between adjacent island-shaped EL layers and between adjacent pixel electrodes, whereby unevenness with a large level difference on the formation surface of a layer (e.g., the carrier-injection layer and the common electrode) provided over the island-shaped EL layers can be reduced and the formation surface can be flatter. Thus, the coverage with the carrier-injection layer, the common electrode, and the like can be increased and disconnection of the carrier-injection layer, the common electrode, and the like can be prevented.

The common layer 114 and the common electrode 115 are provided over the first layer 113a, the second layer 113b, the third layer 113c, the insulating layer 125, and the insulating layer 127. At the stage before the insulating layer 125 and the insulating layer 127 are provided, a step due to a region where the pixel electrode and the EL layer are provided and a region where the pixel electrode and the EL layer are not provided (a region between the light-emitting devices) is caused. In the display apparatus of one embodiment of the present invention, the step can be eliminated with the insulating layer 125 and the insulating layer 127, and the coverage with the common layer 114 and the common electrode 115 can be improved. Consequently, it is possible to inhibit a connection defect due to disconnection. Alternatively, it is possible to inhibit an increase in electric resistance due to local thinning of the common electrode 115 caused by the step.

The top surface of the insulating layer 127 preferably has higher flatness, but may include a projected portion, a convex surface, a concave surface, or a depressed portion. For example, the top surface of the insulating layer 127 preferably has a smooth convex shape with high flatness.

The insulating layer 125 can be provided in contact with the island-shaped EL layers. Thus, peeling of the island-shaped EL layers can be prevented. When the insulating layer 125 and the island-shaped EL layer are in close contact with each other, an effect of fixing adjacent island-shaped EL layers by or attaching the adjacent island-shaped EL layers to the insulating layer 125 can be attained. Thus, the reliability of the light-emitting device can be increased. In addition, the manufacturing yield of the light-emitting device can be increased.

The insulating layer 125 includes a region in contact with the side surface of the island-shaped EL layer and functions as a protective insulating layer of the EL layer. By providing the insulating layer 125, entry of impurities (e.g., oxygen and moisture) from the side surface of the island-shaped EL layer into its inside can be inhibited, and thus a highly reliable display apparatus can be obtained.

Next, examples of materials and formation methods of the insulating layer 125 and the insulating layer 127 are described.

The insulating layer 125 can be an insulating layer containing an inorganic material. As the insulating layer 125, an inorganic insulating film such as an oxide insulating film, a nitride insulating film, an oxynitride insulating film, or a nitride oxide insulating film can be used, for example. The insulating layer 125 may have a single-layer structure or a stacked-layer structure. Examples of the oxide insulating film include a silicon oxide film, an aluminum oxide film, a magnesium oxide film, an indium gallium zinc oxide film, a gallium oxide film, a germanium oxide film, an yttrium oxide film, a zirconium oxide film, a lanthanum oxide film, a neodymium oxide film, a hafnium oxide film, and a tantalum oxide film. Examples of the nitride insulating film include a silicon nitride film and an aluminum nitride film. Examples of the oxynitride insulating film include a silicon oxynitride film and an aluminum oxynitride film. Examples of the nitride oxide insulating film include a silicon nitride oxide film and an aluminum nitride oxide film. Aluminum oxide is particularly preferable because it has high selectivity with the EL layer in etching and has a function of protecting the EL layer in forming the insulating layer 127 which is to be described later. In particular, when an inorganic insulating film such as an aluminum oxide film, a hafnium oxide film, or a silicon oxide film formed by an ALD method is used as the insulating layer 125, the insulating layer 125 having few pinholes and an excellent function of protecting the EL layer can be formed. The insulating layer 125 may have a stacked-layer structure of a film formed by an ALD method and a film formed by a sputtering method. For example, the insulating layer 125 may have a stacked-layer structure of an aluminum oxide film formed by an ALD method and a silicon nitride film formed by a sputtering method.

The insulating layer 125 preferably has a function of a barrier insulating layer against at least one of water and oxygen. Alternatively, the insulating layer 125 preferably has a function of inhibiting diffusion of at least one of water and oxygen. Alternatively, the insulating layer 125 preferably has a function of capturing or fixing (also referred to as gettering) at least one of water and oxygen.

Note that in this specification and the like, a barrier insulating layer refers to an insulating layer having a barrier property. A barrier property in this specification and the like refers to a function of inhibiting diffusion of a particular substance (also referred to as having low permeability). Alternatively, a barrier property refers to a function of capturing or fixing (also referred to as gettering) a particular substance.

When the insulating layer 125 has a function of a barrier insulating layer or a gettering function, entry of impurities (typically, at least one of water and oxygen) that might diffuse into the light-emitting devices from the outside can be inhibited. With this structure, a highly reliable light-emitting device and a highly reliable display apparatus can be provided.

The insulating layer 125 preferably has a low impurity concentration. In this case, deterioration of the EL layer due to entry of impurities from the insulating layer 125 into the EL layer can be inhibited. In addition, when having a low impurity concentration, the insulating layer 125 can have a high barrier property against at least one of water and oxygen. For example, the insulating layer 125 preferably has one of a sufficiently low hydrogen concentration and a sufficiently low carbon concentration, desirably has both of them.

Examples of the formation method of the insulating layer 125 include a sputtering method, a chemical vapor deposition (CVD) method, a pulsed laser deposition (PLD) method, and an ALD method. The insulating layer 125 is preferably formed by an ALD method achieving good coverage.

When the substrate temperature in forming the insulating layer 125 is increased, the formed insulating layer 125, even with a small thickness, can have a low impurity concentration and a high barrier property against at least one of water and oxygen. Therefore, the substrate temperature is preferably higher than or equal to 60° C., more preferably higher than or equal to 80° C., further preferably higher than or equal to 100° C., still further preferably higher than or equal to 120° C. Meanwhile, the insulating layer 125 is formed after formation of an island-shaped EL layer, and thus is preferably formed at a temperature lower than the upper temperature limit of the EL layer. Therefore, the substrate temperature is preferably lower than or equal to 200° C., more preferably lower than or equal to 180° C., further preferably lower than or equal to 160° C., still further preferably lower than or equal to 150° C., yet still further preferably lower than or equal to 140° C.

Examples of indicators of the upper temperature limit include the glass transition point, the softening point, the melting point, the thermal decomposition temperature, and the 5% weight loss temperature. The upper temperature limit of the EL layer can be, for example, any of the above temperatures, preferably the lowest temperature thereof.

As the insulating layer 125, an insulating film is preferably formed to have a thickness greater than or equal to 3 nm, greater than or equal to 5 nm, or greater than or equal to 10 nm and less than or equal to 200 nm, less than or equal to 150 nm, less than or equal to 100 nm, or less than or equal to 50 nm.

The insulating layer 127 provided over the insulating layer 125 has a planarization function for unevenness with a large level difference on the insulating layer 125 formed between adjacent light-emitting devices. In other words, the insulating layer 127 has an effect of improving the planarity of the surface where the common electrode 115 is formed.

As the insulating layer 127, an insulating layer containing an organic material can be suitably used. As the organic material, a photosensitive organic resin is preferably used; for example, a photosensitive resin composition containing an acrylic resin is used. The viscosity of the material for the insulating layer 127 is greater than or equal to 1 cP and less than or equal to 1500 cP, and is preferably greater than or equal to 1 cP and less than or equal to 12 cP. By setting the viscosity of the material for the insulating layer 127 in the above range, the insulating layer 127 having a tapered shape, which is to be described later, can be formed relatively easily. Note that in this specification and the like, an acrylic resin refers to not only a polymethacrylic acid ester or a methacrylic resin, but also all the acrylic polymer in a broad sense in some cases.

Note that the organic material usable for the insulating layer 127 is not limited to the above-described materials as long as a side surface of the insulating layer 127 has a tapered shape as described later. For example, the insulating layer 127 can be formed using an acrylic resin, a polyimide resin, an epoxy resin, an imide resin, a polyamide resin, a polyimide-amide resin, a silicone resin, a siloxane resin, a benzocyclobutene-based resin, a phenol resin, precursors of these resins, or the like in some cases. Alternatively, an organic material such as polyvinyl alcohol (PVA), polyvinylbutyral, polyvinylpyrrolidone, polyethylene glycol, polyglycerin, pullulan, water-soluble cellulose, or an alcohol-soluble polyamide resin can be used for the insulating layer 127 in some cases. As the photosensitive resin, a photoresist can be used in some cases. As the photosensitive resin, a positive material or a negative material can be used in some cases.

The insulating layer 127 may be formed using a material absorbing visible light. When the insulating layer 127 absorbs light emitted from the light-emitting device, leakage of light (stray light) from the light-emitting device to an adjacent light-emitting device through the insulating layer 127 can be inhibited. Thus, the display quality of the display apparatus can be improved. Since no polarizing plate is required to improve the display quality of the display apparatus, the weight and thickness of the display apparatus can be reduced.

Examples of the material absorbing visible light include a material containing a pigment of black or any other color, a material containing a dye, a light-absorbing resin material (e.g., polyimide), and a resin material that can be used for color filters (a color filter material). It is particularly preferable to use a resin material obtained by stacking or mixing color filter materials of two or three or more colors to enhance the effect of blocking visible light. In particular, mixing color filter materials of three or more colors enables the formation of a black or nearly black resin layer.

For example, the insulating layer 127 can be formed by a wet film formation method such as spin coating, dipping, spray coating, ink-jetting, dispensing, screen printing, offset printing, a doctor knife method, slit coating, roll coating, curtain coating, or knife coating. Specifically, an organic insulating film that is to be the insulating layer 127 is preferably formed by spin coating.

The insulating layer 127 is formed at a temperature lower than the upper temperature limit of the EL layer. The typical substrate temperature in formation of the insulating layer 127 is lower than or equal to 200° C., preferably lower than or equal to 180° C., further preferably lower than or equal to 160° C., still further preferably lower than or equal to 150° C., yet still further preferably lower than or equal to 140° C.

Hereinafter, a structure of the insulating layer 127 and the like is described using the structure of the insulating layer 127 between the light-emitting device 130a and the light-emitting device 130b as an example. Note that the same can apply to the insulating layer 127 between the light-emitting device 130b and the light-emitting device 130c, the insulating layer 127 between the light-emitting device 130c and the light-emitting device 130a, and the like. In the description below, an end portion of the insulating layer 127 over the second layer 113b is used as an example in some cases, and the same can apply to an end portion of the insulating layer 127 over the first layer 113a, an end portion of the insulating layer 127 over the third layer 113c, and the like.

In a cross-sectional view of the display apparatus, the side surface of the insulating layer 127 which is positioned over the second layer 113b preferably has a tapered shape with a taper angle θ. Hereinafter, in this specification and the like, a side surface of a convex portion of the insulating layer 127 which is positioned above the flat portion of the first layer 113a, the second layer 113b, or the third layer 113c is referred to as the side surface of the insulating layer 127 in some cases. The taper angle θ is an angle formed by the side surface of the insulating layer 127 and a substrate surface. Note that the taper angle θ is not limited to the angle with the substrate surface, and may be an angle formed by the side surface of the insulating layer 127 and the top surface of the flat portion of the insulating layer 125, the top surface of the flat portion of the second layer 113b, the top surface of the flat portion of the pixel electrode 111b, or the like. When the side surface of the insulating layer 127 has a tapered shape, a side surface of the insulating layer 125 also have a tapered shape in some cases.

Note that in this specification and the like, a tapered shape refers to a shape such that at least part of a side surface of a component is inclined to a substrate surface. For example, a tapered shape preferably includes a region where the angle formed by the inclined side surface and the substrate surface (such an angle is also referred to as a taper angle) is less than 90°.

The taper angle θ of the insulating layer 127 is less than 90°, preferably less than or equal to 60°, and further preferably less than or equal to 45°. Such a forward tapered shape of the end portion of the side surface of the insulating layer 127 can prevent disconnection, local thinning, or the like from occurring in the common layer 114 and the common electrode 115 which are provided over the end portion of the side surface of the insulating layer 127, leading to formation with good coverage. The common layer 114 and the common electrode 115 can have improved in-plane uniformity in this manner, whereby the display apparatus can have improved display quality.

The top surface of the insulating layer 127 preferably has a convex shape in a cross-sectional view of the display apparatus. The top surface of the insulating layer 127 preferably has a convex shape that bulges gradually toward the center. The insulating layer 127 preferably has a shape such that the convex portion at the center portion of the top surface is connected smoothly to the tapered portion of the end portion of the side surface. When the insulating layer 127 has such a shape, the common layer 114 and the common electrode 115 can be formed with good coverage over the whole the insulating layer 127.

The insulating layer 127 is formed in a region between two EL layers (e.g., a region between the first layer 113a and the second layer 113b). In that case, at least part of the insulating layer 127 is provided at a position interposed between an end portion of a side surface of one of the EL layers (e.g., the first layer 113a) and an end portion of a side surface of the other of the EL layers (e.g., the second layer 113b).

It is preferable that one the end portion of the insulating layer 127 overlap with the pixel electrode 111a and that the other the end portion of the insulating layer 127 overlap with the pixel electrode 111b. With such a structure, the end portion of the insulating layer 127 can be formed over a substantially flat region of the first layer 113a (the second layer 113b). Thus, the tapered shape of the insulating layer 127 is relatively easy to form by processing as described above.

By providing the insulating layer 127 and the like as described above, a disconnected portion and a locally thinned portion can be prevented from being formed in the common layer 114 and the common electrode 115 from a substantially flat region in the first layer 113a to a substantially flat region in the second layer 113b. Thus, between the light-emitting devices, a connection defect caused by the disconnected portion and an increase in electric resistance caused by the locally thinned portion can be inhibited from occurring in the common layer 114 and the common electrode 115. Accordingly, the display quality of the display apparatus of one embodiment of the present invention can be improved.

In the display apparatus of this embodiment, the distance between the light-emitting devices can be short. Specifically, the distance between the light-emitting devices, the distance between the EL layers, or the distance between the pixel electrodes can be less than 10 mm, less than or equal to 8 mm, less than or equal to 5 mm, less than or equal to 3 mm, less than or equal to 2 mm, less than or equal to 1 mm, less than or equal to 500 nm, less than or equal to 200 nm, or less than or equal to 100 nm. In other words, the display apparatus of this embodiment includes a region where a distance between two adjacent island-shaped EL layers is less than or equal to 1 mm, preferably less than or equal to 0.5 mm (500 nm), further preferably less than or equal to 100 nm. The distance between the light-emitting devices is shortened in this manner, whereby a display apparatus with high resolution and a high aperture ratio can be provided.

Although the structure provided with the insulating layer 127 is described above, the present invention is not limited thereto. For example, a structure in which the insulating layer 127 is not provided as illustrated in FIG. 6C may be employed. In the case where the insulating layer 127 is not provided, the common layer 114 can be omitted as illustrated in FIG. 6C. Here, it is preferable that a functional layer (e.g., a carrier-injection layer) included in the common layer 114 in the structure illustrated in FIG. 1B also be stacked in the first layer 113a to the third layer 113c.

In the case where the insulating layer 127 is not provided, the common electrode 115 has a shape falling in a region interposed between the pixel electrodes. Here, as illustrated in FIG. 6C, part of the common electrode 115 is in contact with the fourth layer 113d in some cases. The common electrode 115 is preferably prevented from being disconnected in this manner. At this time, as illustrated in FIG. 6C, a gap is sometimes formed in a region interposed between the pixel electrode 111 and the common electrode 115 and between the first layer 113a (which may be the second layer 113b or the third layer 113c) and the fourth layer 113d.

The coloring layer 132a, the coloring layer 132b, and the coloring layer 132c are provided between the common electrode 115 and the substrate 102. For example, as illustrated in FIG. 1B, the structure where the coloring layer 132a, the coloring layer 132b, and the coloring layer 132c are provided over the resin layer 147 can be employed. With such a structure, the distance between the light-emitting device 130 and the coloring layer 132 can be reduced. Thus, light emitted from the light-emitting device 130 can be inhibited from leaking to an adjacent subpixel. For example, light emitted from the light-emitting device 130a overlapping with the coloring layer 132a can be inhibited from entering the coloring layer 132b. Accordingly, the contrast of images displayed on the display apparatus can be increased, and the display apparatus can have high display quality.

The coloring layer 132a includes a region overlapping with the light-emitting device 130a, the coloring layer 132b includes a region overlapping with the light-emitting device 130b, and the coloring layer 132c includes a region overlapping with the light-emitting device 130c. The coloring layer 132a, the coloring layer 132b, and the coloring layer 132c each include a region overlapping with at least the light-emitting layer included in the corresponding light-emitting device 130.

The coloring layer 132a, the coloring layer 132b, and the coloring layer 132c have functions of transmitting light of different wavelength ranges from one another. For example, a structure can be employed where the coloring layer 132a has a function of transmitting light with intensity in a red wavelength range, the coloring layer 132b has a function of transmitting light with intensity in a green wavelength range, and the coloring layer 132c has a function of transmitting light with intensity in a blue wavelength range. Thus, the display apparatus 100 can perform full-color display. Without limitation to this, the coloring layer 132 may have a function of transmitting light of any of cyan, magenta, and yellow.

Here, the adjacent coloring layers 132 preferably include an overlapping region. Specifically, a region not overlapping with the light-emitting device 130 preferably includes the region where the adjacent coloring layers 132 overlap with each other. For example, as illustrated in FIG. 1B, the coloring layer 132a is provided to overlap with part of the coloring layer 132b in a region interposed between the light-emitting device 130a and the light-emitting device 130b. In that case, a portion where the coloring layer 132a and the coloring layer 132b overlap with each other preferably overlaps with the insulating layer 127. Note that the same applies to the coloring layer 132a and the coloring layer 132c, and the coloring layer 132b and the coloring layer 132c.

In this manner, when the coloring layers 132 that transmit light of different colors overlap with each other, the coloring layers 132 in the region where the coloring layers 132 overlap with each other can function as light-blocking layers. Thus, light emitted from the light-emitting device 130 can be inhibited from leaking to an adjacent subpixel. Accordingly, the contrast of images displayed on the display apparatus can be increased, and the display apparatus can have high display quality.

As illustrated in FIG. 1B and the like, the coloring layer 132 is preferably provided in contact with the top surface of the resin layer 147 functioning as a planarization film. Thus, the coloring layer 132 can be formed on a surface with high planarity; hence, the coloring layer 132 can be inhibited from having projections and depressions caused by a formation surface where the coloring layer 132 is formed. Thus, diffused reflection of part of light emitted from the light-emitting device 130 at the unevenness of the coloring layer 132 can be reduced, so that display quality of the display apparatus can be improved. By providing the resin layer 147 over the protective layer 131, even the case where a defect such as a pinhole exists in the protective layer 131, for example, the defect can be filled with the resin layer 147 with high step coverage.

For the coloring layer 132, a light-transmitting chromatic-color resin layer can be used. For example, a metal material, a resin material, and a resin material containing a pigment or dye can be given.

The resin layer 147 preferably contains an organic insulating material. For example, an acrylic resin, a polyimide resin, an epoxy resin, a polyamide resin, a polyimide-amide resin, a siloxane resin, a benzocyclobutene-based resin, a phenol resin, and precursors of these resins can be given.

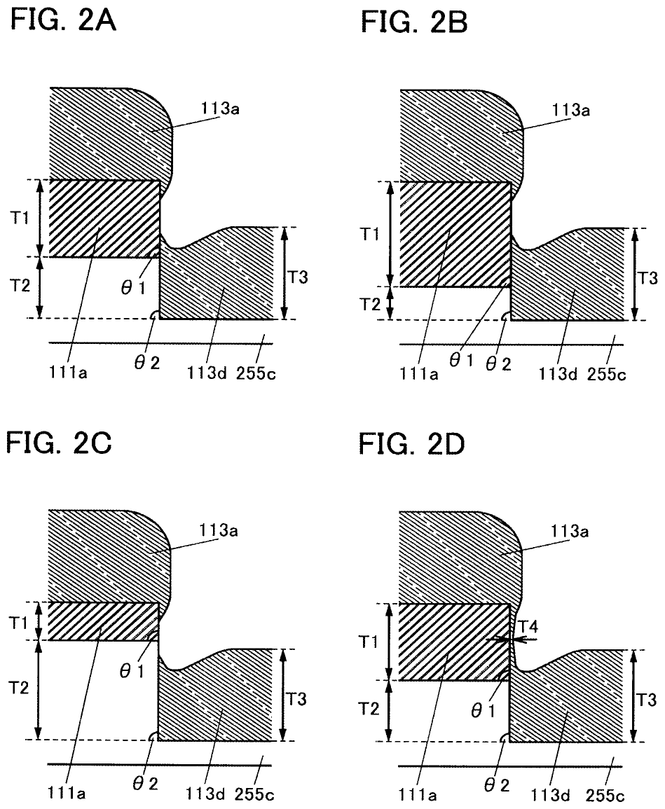

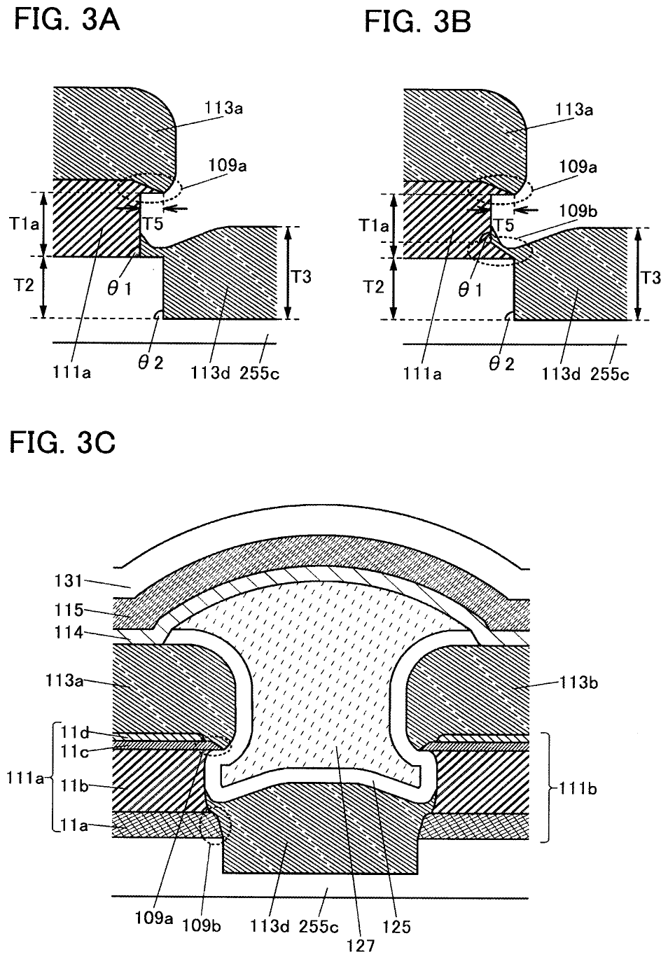

Next, a structure of a disconnected portion of the first layer 113a and the fourth layer 113d is described with reference to FIG. 2A to FIG. 3B. Note that in FIG. 2A to FIG. 3B, only the first layer 113a, the fourth layer 113d, the pixel electrode 111a, and the insulating layer 255c are illustrated to avoid complexity. The following description, which refers to the first layer 113a and the pixel electrode 111a as examples, also applies to the second layer 113b and the pixel electrode 111b, and the third layer 113c and the pixel electrode 111c.

As illustrated in FIG. 2A, the pixel electrode 111a is provided over the insulating layer 255c, the first layer 113a is provided over the pixel electrode 111a, and the fourth layer 113d is provided in the depressed portion of the insulating layer 255c. Here, a step formed by the pixel electrode 111a and the depressed portion of the insulating layer 255c needs to be sufficiently large in order to separate the first layer 113a and the fourth layer 113d in a self-aligned manner in the formation of the EL film.

Specifically, the step formed by the pixel electrode 111a and the depressed portion of the insulating layer 255c is preferably larger than or equal to the thickness of the fourth layer 113d. That is, as illustrated in FIG. 2A, the relation of T1+T2≥T3 is preferably satisfied, where T1 is the thickness of the pixel electrode 111a, T2 is the depth of the depressed portion of the insulating layer 255c, and T3 is the thickness of the fourth layer 113d.

The step formed by the pixel electrode 111a and the depressed portion of the insulating layer 255c preferably has a steep shape. As illustrated in FIG. 2A, an angle formed by the bottom surface and the side surface of the pixel electrode 111a is a taper angle θ1, and an angle formed by the side surface of the depressed portion of the insulating layer 255c and an extended surface of the bottom surface of the depressed portion of the insulating layer 255c is a taper angle θ2. Here, the taper angles θ1 and θ2 are each greater than or equal to 60° and less than or equal to 140°, preferably greater than or equal to 70° and less than or equal to 140°, further preferably greater than or equal to 80° and less than or equal to 140°.

When the insulating layer 255c and the pixel electrode 111a have the above structure, a sufficiently large step is formed; thus, the first layer 113a and the fourth layer 113d can be separated in a self-aligned manner in the formation of the EL film. By forming the EL layer in such a manner, a leakage current path between two adjacent light-emitting devices can be cut, whereby leakage current can be inhibited. Accordingly, a higher luminance, a higher contrast, higher display quality, higher power efficiency, or lower power consumption can be achieved.

Here, as illustrated in FIG. 2A, the first layer 113a is sometimes formed in contact with an upper end portion of the side surface of the pixel electrode 111a. In this case, the side surface of the first layer 113a is positioned outward from the side surface of the pixel electrode 111a. In addition, a side surface of the fourth layer 113d is in contact with part of the side surface of the pixel electrode 111a in some cases; however, the area where the fourth layer 113d and the pixel electrode 111a are in contact with each other is sufficiently small, so that leakage current can be inhibited or sufficiently reduced.

The level of a portion of the fourth layer 113d that is in contact with the side surface of the pixel electrode 111a is sometimes lower than the thickness T3. In that case, even when the sum of the thickness T1 and the depth T2 of the depressed portion is higher than or equal to 80% of the thickness T3 or higher than or equal to 90% of the thickness T3, the first layer 113a and the fourth layer 113d are sometimes separated from each other in a self-aligned manner.

As illustrated in FIG. 2B, the thickness T1 of the pixel electrode 111a may be larger than or equal to the thickness T3 of the fourth layer 113d. In that case, a structure in which T2=0 nm, i.e., the insulating layer 255c does not have a depressed portion, can be employed.

As illustrated in FIG. 2C, the depth T2 of the depressed portion of the insulating layer 255c may be larger than or equal to the thickness T3 of the fourth layer 113d. In that case, as illustrated in FIG. 2C, the fourth layer 113d is not in contact with the side surface of the pixel electrode 111a in some cases. When part of a side surface of the insulating layer 255c is exposed from the fourth layer 113d, the insulating layer 125 is sometimes in contact with the part of the side surface of the insulating layer 255c.

Although the first layer 113a and the fourth layer 113d are preferably separated as illustrated in FIG. 2A and the like, the present invention is not limited thereto. For example, as illustrated in FIG. 2D, the first layer 113a and the fourth layer 113d are sometimes connected with each other with an EL layer formed thinly on the side surface of the pixel electrode 111a. Here, a thickness T4 of the EL layer formed thinly on the side surface of the pixel electrode 111a is preferably sufficiently thin. The thickness T4 is smaller than or equal to half (50%), preferably smaller than or equal to 30%, further preferably smaller than or equal to 10% of the thickness T3 and larger than 0% of the thickness T3. Leakage current between adjacent light-emitting devices can be inhibited or sufficiently reduced by reducing the thickness T4.

Note that in some cases, the fourth layer 113d is separated from one of adjacent EL layers and connected with the other of the adjacent EL layers with an EL layer formed thinly. For example, the first layer 113a and the fourth layer 113d that is formed between the first layer 113a and the second layer 113b are separated from each other and the second layer 113b and the fourth layer 113d are connected with each other with an EL layer formed thinly on the side surface of the pixel electrode 111b in some cases.

Alternatively, as illustrated in FIG. 3A, part of the side surface of the pixel electrode 111a may recede. A side surface of a lower portion of the pixel electrode 111a recedes from the side surface of the depressed portion of the insulating layer 255c. A projecting portion 109a is formed on a side surface of a upper portion of the pixel electrode 111a and projects from the side surface of the lower portion of the pixel electrode 111a by a distance T5 (T5 is greater than 0 nm). When the projecting portion 109a is formed in the upper portion of the pixel electrode 111a in such manner, an EL film can be relatively easily disconnected at the projecting portion 109a in the formation of the EL film. Thus, the first layer 113a is preferably formed to cover the projecting portion 109a. Note that as illustrated in FIG. 3A, the projecting portion 109a may have a tapered shape.

As described above, in the structure illustrated in FIG. 3A, the formed EL film is preferably disconnected at the projecting portion 109a. Thus, the height of a step below the projecting portion of the pixel electrode 111a is preferably greater than or equal to the thickness of the fourth layer 113d. That is, as illustrated in FIG. 3A, the relation of T1a+T2≥3 is preferably satisfied, where T1a is the thickness of a portion of the pixel electrode 111a below the projecting portion 109a, T2 is the depth of the depressed portion of the insulating layer 255c, and T3 is the thickness of the fourth layer 113d.

As illustrated in FIG. 3A, the pixel electrode 111a is formed using, for example, two conductive layers with different materials (a first conductive layer and a second conductive layer over the first conductive layer). A material having a higher etching rate than that of the second conductive layer is used for the first conductive layer.

Alternatively, as illustrated in FIG. 3B, a structure may be employed in which the center portion of the side surface of the pixel electrode 111a recedes and a upper portion and a lower portion of the side surface of the pixel electrode 111a project. The structure illustrated in FIG. 3B can also be regarded as a structure in which a projecting portion 109b in the lower portion of the pixel electrode 111a is further added to the structure illustrated in FIG. 3A. In this case, the taper angle θ1 is measured at the side surface above the projecting portion 109b. Note that as illustrated in FIG. 3B, the projecting portion 109b may have a tapered shape.

The pixel electrode 111a illustrated in FIG. 3B is formed using, for example, three conductive layers with different materials (a first conductive layer, a second conductive layer over the first conductive layer, and a third conductive layer over the second conductive layer). For the second conductive layer, a material having a higher etching rate than that of the first conductive layer and the third conductive layer may be used.

FIG. 3C illustrates a specific example of the structure illustrated in FIG. 3B, in which the center portion of the side surface of the pixel electrode 111a recedes and the upper portion and the lower portion of the side surface of the pixel electrode 111a project. FIG. 3C is an enlarged cross-sectional view of the vicinity of the fourth layer 113d, the insulating layer 125, and the insulating layer 127 which are provided between the pixel electrode 111a and the pixel electrode 111b.

The structure illustrated in FIG. 3C is a structure where the pixel electrode 111 in the structure illustrated in FIG. 1B has a four-layer structure of a conductive layer 11a, a conductive layer 11b over the conductive layer 11a, a conductive layer 11c over the conductive layer 11b, and a conductive layer 11d over the conductive layer 11c.

The conductive layer 11a includes the projecting portion 109b and corresponds to the lower portion of the pixel electrode 111a illustrated in FIG. 3B. A side surface of the conductive layer 11b recedes from a side surface of the 11a and a side surface of the 11c, and the conductive layer 11b corresponds to the center portion of the pixel electrode 111a illustrated in FIG. 3B. Thus, the sum of the thickness of the conductive layer 11a and the thickness of the conductive layer 11b corresponds to the thickness T1a illustrated in FIG. 3B. The conductive layer 11c includes the projecting portion 109a and the conductive layer 11c and the conductive layer 11d correspond to the upper portion of the pixel electrode 111a illustrated in FIG. 3B.

In the case where the pixel electrode 111 has a four-layer structure of the conductive layer 11a to the conductive layer 11d as illustrated in FIG. 3C, a conductive film having a reflecting property with respect to visible light is used for the conductive layer 11b. For the conductive film having a reflecting property with respect to visible light, a metal material such as aluminum, gold, platinum, silver, nickel, magnesium, tungsten, chromium, titanium, tantalum, molybdenum, iron, cobalt, copper, or palladium or an alloy containing any of these metal materials can be used, for example. Copper is preferably used because of its high reflectance with respect to visible light. Aluminum is preferable because an aluminum electrode is easily etched and thus is easily processed, and aluminum has high reflectance with respect to visible light and near-infrared light. The use of a material having high reflectance in the whole wavelength range of visible light, such as silver or aluminum, for the conductive layer 11b as described above can increase color reproducibility as well as light extraction efficiency of the light-emitting device. Lanthanum, neodymium, germanium, or the like may be added to the above-described metal material or alloy. For example, an alloy containing aluminum (an aluminum alloy) such as an alloy of aluminum, nickel, and lanthanum (Al—Ni—La) may be used. Alternatively, an alloy containing silver, palladium, and copper (also referred to as Ag—Pd—Cu or APC) may be used. An alloy containing silver, palladium, magnesium, and copper may be used. An alloy containing silver and copper is preferable because of its high heat resistance. Alternatively, an alloy containing silver and magnesium may be used. A stack containing two or more of these materials may be used. Examples of such a stack include a structure of aluminum and APC over the aluminum.

For example, aluminum is used for the conductive layer 11b. When aluminum is used for the conductive layer 11b, the thickness of aluminum is preferably greater than or equal to 40 nm, further preferably greater than or equal to 70 nm, in which case the reflectance with respect to visible light or the like can be sufficiently increased.

A conductive film having a function of protecting a conductive film that reflects visible light may be provided in contact with the top surface and/or the bottom surface of the conductive film that reflects visible light (the conductive layer 11b). Such a structure can inhibit the conductive film that reflects visible light from being oxidized or corroded. When a metal film or a metal oxide film is stacked in contact with an aluminum film or an aluminum alloy film, for example, oxidization can be inhibited. Furthermore, generation of hillocks in the aluminum film or the aluminum alloy film can be inhibited. Examples of a material for the metal film or the metal oxide film include titanium and titanium oxide. In the case of employing the structure illustrated in FIG. 3C, for example, titanium is used for the conductive layer 11a and titanium oxide is used for the conductive layer 11c. The use of titanium oxide having a light-transmitting property for the conductive layer 11c can inhibit visible light reflected by the conductive layer 11b from attenuating in the conductive layer 11c.

In the case of using a conductive metal oxide having a light-transmitting property with respect to visible light, the metal oxide may be formed by oxidation of the surface of a conductive material. In the case of using titanium oxide, for example, the titanium oxide may be formed by forming titanium by a sputtering method or the like and oxidizing the surface of the titanium.

In the pixel electrode 111, a conductive film having a transmitting property with respect to visible light can be provided over the conductive film having a reflecting property with respect to visible light. When the conductive film having a transmitting property with respect to visible light is stacked over the conductive film having a reflecting property with respect to visible light in the pixel electrode 111, the conductive film having a transmitting property with respect to visible light can function as an optical adjustment layer. The conductive layer 11d can function as an optical adjustment layer. As a conductive material having a transmitting property with respect to visible light, an oxide containing one or more selected from indium, tin, zinc, gallium, titanium, aluminum, and silicon can be used. For example, it is preferable to use a conductive oxide containing one or more of indium oxide, an indium tin oxide, an indium zinc oxide, zinc oxide, zinc oxide containing gallium, titanium oxide, an indium zinc oxide containing gallium, an indium zinc oxide containing aluminum, an indium tin oxide containing silicon, an indium zinc oxide containing silicon, and the like. Provision of an oxide over the surface of the pixel electrode 111 can inhibit, for example, an oxidation reaction with the pixel electrode 111 in formation of the EL layer 113.

In the case where the pixel electrode 111 is an anode, a conductive film with a high work function (e.g., a work function of higher than or equal to 4.0 eV) is preferably used. For example, in the case of employing the structure illustrated in FIG. 3C, an indium tin oxide or an indium tin oxide containing silicon is used for the conductive layer 11d. Here, each of the conductive layer 11d and the conductive layer 11c having transmitting properties with respect to visible light preferably has a thickness smaller than the conductive layer 11b. Furthermore, the sum of the thicknesses of the conductive layer 11d and the conductive layer 11c is preferably smaller than the thickness of the conductive layer 11b.

Here, when the pixel electrode 111 includes an optical adjustment layer, an optical path length can be adjusted. The optical path length of each of the light-emitting device corresponds to, for example, the sum of the thickness of the optical adjustment layer and the thicknesses of a layer that is included in the EL layer 113 and that is provided below a film containing a light-emitting compound in the EL layer 113.

The optical path length is set different among the light-emitting devices using a microcavity structure, whereby light of a specific wavelength can be intensified. This can achieve a display apparatus having an increased color purity.

For example, the thickness of the EL layer 113 is set different among the light-emitting devices, whereby a microcavity structure can be achieved. For example, a structure where the light-emitting device emitting light with the longest wavelength (e.g., red light) includes the EL layer 113 with the largest thickness, and the light-emitting device emitting light with the shortest wavelength (e.g., blue light) includes the EL layer 113 with the smallest thickness can be employed. Note that without limitation to this, the thicknesses of the EL layers can be adjusted in consideration of the wavelengths of light emitted by the light-emitting devices, the optical characteristics of the layers included in the light-emitting devices, the electrical characteristics of the light-emitting devices, and the like.

Note that although an example in which the pixel electrode 111 is a stack of four layers, the conductive layer 11a to the conductive layer 11d, is illustrated in FIG. 3C, a structure of three or less layers or a structure of five or more layers may be employed. For example, in the case where the pixel electrode 111 has a three-layer structure of the conductive layer 11a to the conductive layer 11c, indium tin oxide or indium tin oxide containing silicon can be used for the conductive layer 11a and the conductive layer 11c, and an alloy containing silver (e.g., APC) can be used for the conductive layer 11b.

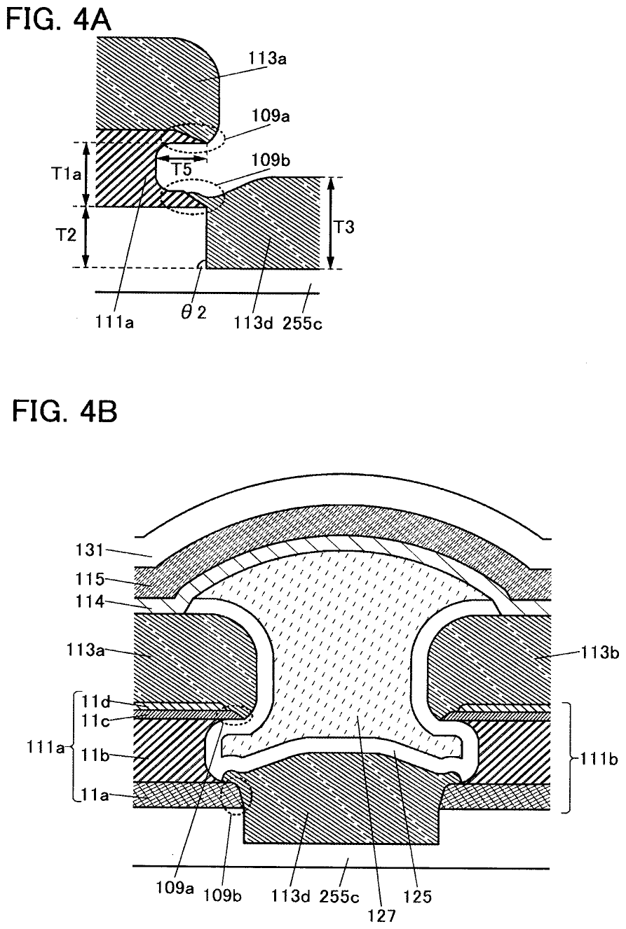

As illustrated in FIG. 4A, the side surface of the center portion of the pixel electrode 111 may recede largely by the isotropic etching. In this case, the side surface of the center portion of the pixel electrode 111a recedes more significantly than that in FIG. 3B and the like. In this manner, the projecting portion 109a can be relatively large. Thus, the first layer 113a and the fourth layer 113d can be relatively easily separated from each other. At this time, the projecting portion 109b becomes relatively large in some cases.

Note that the details of the isotropic etching described above will be described later.

FIG. 4B illustrates a structure where the pixel electrode 111 in the structure illustrated in FIG. 4A has a four-layer structure of the conductive layer 11a to the conductive layer 11d. As illustrated in FIG. 4B, the side surface of the conductive layer 11b recedes greatly by isotropic etching. Accordingly, the projecting portion 109a of the conductive layer 11c can be relatively large, so that the first layer 113a (including the second layer 113b or the third layer 113c) and the fourth layer 113d can be easily separated from each other in a self-aligned manner. At this time, the projecting portion 109b of the conductive layer 11a becomes relatively large in some cases.

For the substrate 101 and the substrate 102, glass, quartz, ceramic, sapphire, a resin, a metal, an alloy, a semiconductor, or the like can be used. The substrate on the side from which light from the light-emitting device is extracted is formed using a material that transmits the light. When the substrate 101 and the substrate 102 are formed using a flexible material, the flexibility of the display apparatus can be increased. Furthermore, a polarizing plate may be used as the substrate 101 and the substrate 102.

For each of the substrate 101 and the substrate 102, any of the following can be used, for example: polyester resins such as polyethylene terephthalate (PET) and polyethylene naphthalate (PEN), a polyacrylonitrile resin, an acrylic resin, a polyimide resin, a polymethyl methacrylate resin, a polycarbonate (PC) resin, a polyethersulfone (PES) resin, polyamide resins (e.g., nylon and aramid), a polysiloxane resin, a cycloolefin resin, a polystyrene resin, a polyamide-imide resin, a polyurethane resin, a polyvinyl chloride resin, a polyvinylidene chloride resin, a polypropylene resin, a polytetrafluoroethylene (PTFE) resin, an ABS resin, and cellulose nanofiber. Glass that is thin enough to have flexibility may be used for the substrate 101 and the substrate 102.

In the case where a circularly polarizing plate overlaps with the display apparatus, a highly optically isotropic substrate is preferably used as the substrate included in the display apparatus. A highly optically isotropic substrate has a low birefringence (in other words, a small amount of birefringence).

The absolute value of a retardation (phase difference) of a highly optically isotropic substrate is preferably less than or equal to 30 nm, further preferably less than or equal to 20 nm, still further preferably less than or equal to 10 nm.

Examples of the films having high optical isotropy include a triacetyl cellulose (TAC, also referred to as cellulose triacetate) film, a cycloolefin polymer (COP) film, a cycloolefin copolymer (COC) film, and an acrylic film.

In the case where a film is used for the substrate and the film absorbs water, the shape of a display apparatus might be changed, e.g., creases might be generated. Thus, for the substrate, a film with a low water absorption rate is preferably used. For example, a film with a water absorption rate lower than or equal to 1% is preferably used, a film with a water absorption rate lower than or equal to 0.1% is further preferably used, and a film with a water absorption rate lower than or equal to 0.01% is still further preferably used.

For the adhesive layer 107 bonding the substrate 101 and the substrate 102 each other, a variety of curable adhesives such as a photocurable adhesive like an ultraviolet curable adhesive, a reactive curable adhesive, a thermosetting adhesive, and an anaerobic adhesive can be used. Examples of these adhesives include an epoxy resin, an acrylic resin, a silicone resin, a phenol resin, a polyimide resin, an imide resin, a PVC (polyvinyl chloride) resin, a PVB (polyvinyl butyral) resin, and an EVA (ethylene vinyl acetate) resin. In particular, a material with low moisture permeability, such as an epoxy resin, is preferable. A two-component-mixture-type resin may be used. An adhesive sheet or the like may be used.

A light-blocking layer may be provided on the surface of the substrate 102 on the adhesive layer 107 side. Any of a variety of optical members can be arranged on the outer surface of the substrate 102. Examples of the optical members include a polarizing plate, a retardation plate, a light diffusion layer (e.g., a diffusion film), an anti-reflective layer, and a light-condensing film. Furthermore, an antistatic film inhibiting the attachment of dust, a water repellent film inhibiting the attachment of stain, a hard coat film inhibiting generation of a scratch caused by the use, an impact-absorbing layer, or the like may be provided as a surface protective layer on the outer surface of the substrate 102. For example, a glass layer or a silica layer (SiOₓ layer) is preferably provided as the surface protective layer to inhibit the surface contamination and generation of a scratch. The surface protective layer may be formed using DLC (diamond like carbon), aluminum oxide (AlOₓ), a polyester-based material, a polycarbonate-based material, or the like. Note that for the surface protective layer, a material having high visible light transmittance is preferably used. The surface protective layer is preferably formed using a material with high hardness.

### [Variation Example of Display Apparatus]

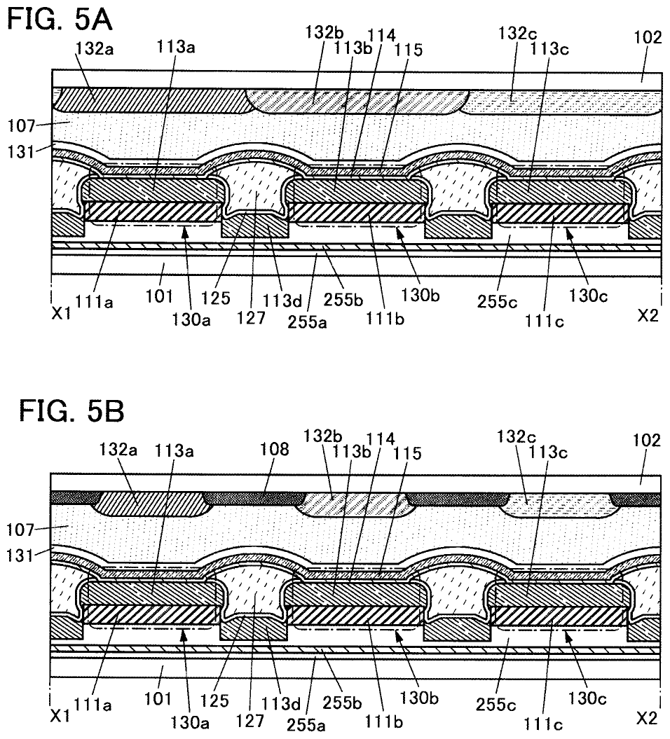

Next, variation examples of the display apparatus 100 where the structure of the coloring layer is changed are described with reference to FIG. 5A and FIG. 5B. Here, FIG. 5A and FIG. 5B each correspond to the cross-sectional view along the dashed-dotted line X1-X2 in FIG. 1A. Note that description of FIG. 1B and the like can be referred to for reference numerals in the structures illustrated in FIG. 5A and FIG. 5B which are the same as those in the structure illustrated in FIG. 1B.

Although FIG. 1B illustrates the structure in which the coloring layer 132 is provided in contact with the top surface of the resin layer 147, the present invention is not limited thereto. For example, as illustrated in FIG. 5A, the coloring layers 132a, 132b, and 132c can be provided in contact with the substrate 102. Here, the coloring layer 132 is provided in contact with the substrate 102 and the adhesive layer 107. Note that in the display apparatus illustrated in FIG. 5A, the resin layer 147 is not necessarily provided over the protective layer 131; thus, the manufacturing process of the display apparatus can be simplified.

FIG. 5B illustrates a structure in which the substrate 102 is provided with light-blocking layers 108 and the coloring layer 132 is provided between the light-blocking layers 108. In the display apparatus illustrated in FIG. 5B, the substrate 102 and the substrate 101 are bonded to each other with the adhesive layer 107. Thus, the adhesive layer 107 is in contact with the protective layer 131, the light-blocking layer 108, and the coloring layer 132. The coloring layer 132 is preferably provided to overlap with part of the light-blocking layer 108.

The light-blocking layer 108 is provided on a surface of the substrate 102 on the substrate 101 side. By providing the light-blocking layer 108, light emitted from the light-emitting device 130 can be inhibited from leaking to an adjacent subpixel. The light-blocking layer 108 has an opening at least in a position overlapping with the light-emitting device 130. The light-blocking layer 108 preferably includes a region overlapping with the insulating layer 127. In other words, at least part of the light-blocking layer 108 overlaps with a region interposed between two adjacent light-emitting devices or a region interposed between two adjacent EL layers. Providing the light-blocking layer 108 as described above can provide the light-blocking layer 108 without a reduction in the aperture ratio.

For the light-blocking layer 108, a material that blocks light emitted from the light-emitting devices can be used. The light-blocking layer 108 preferably absorbs visible light. For the light-blocking layer 108, a black matrix can be formed using a metal material or a resin material containing pigment (e.g., carbon black) or dye, for example. Alternatively, the light-blocking layer 108 may have a stacked-layer structure including two or more of a red color filter, a green color filter, and a blue color filter. Note that as illustrated in FIG. 5A and the like, a structure in which the light-blocking layer 108 is not provided may be employed.

### [Manufacturing Method Example of Display Apparatus]

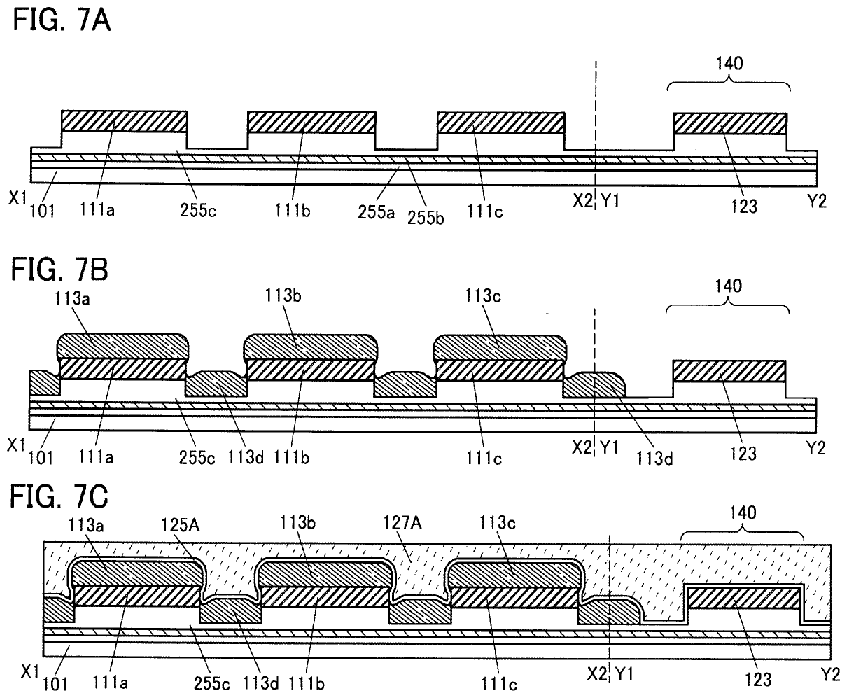

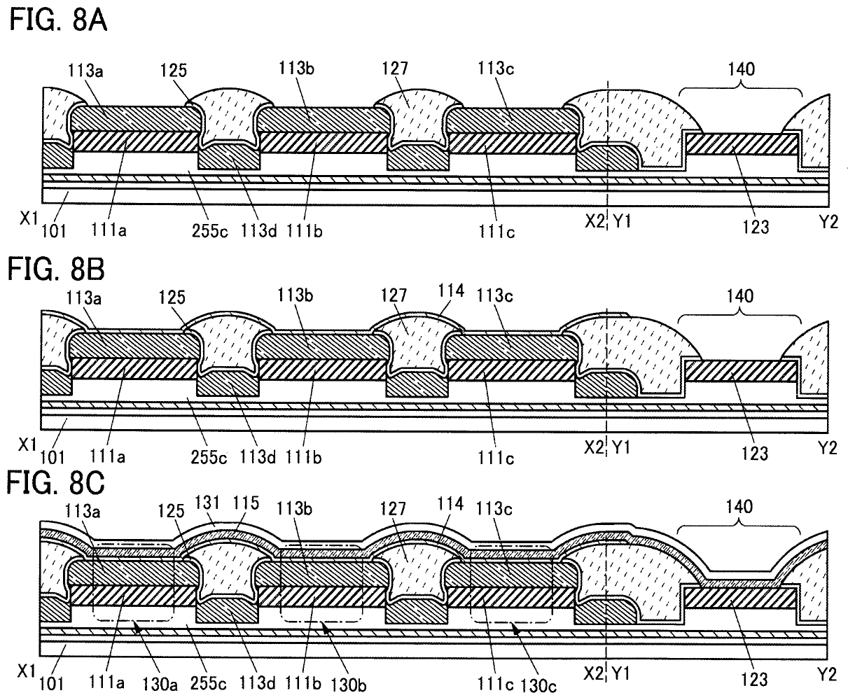

Next, an example of a manufacturing method of the display apparatus 100 illustrated in FIG. 1B and the like is described with reference to FIG. 7 to FIG. 9. FIG. 7A to FIG. 8C illustrate the cross section along the dashed-dotted line X1-X2 and the cross section along the dashed-dotted line Y1-Y2 in FIG. 1A side by side.

Thin films included in the display apparatus (e.g., insulating films, semiconductor films, and conductive films) can be formed by a sputtering method, a CVD method, a vacuum evaporation method, a PLD method, an ALD method, or the like. Examples of a CVD method include a plasma-enhanced chemical vapor deposition (PECVD: Plasma Enhanced CVD) method and a thermal CVD method. As an example of the thermal CVD method, a metal organic chemical vapor deposition (MOCVD: Metal Organic CVD) method can be given.

Alternatively, thin films included in the display device (e.g., insulating films, semiconductor films, and conductive films) can be formed by a method such as spin coating, dipping, spray coating, ink-jetting, dispensing, screen printing, offset printing, a doctor knife method, a slit coating, a roll coating, a curtain coating, or a knife coating.

Specifically, for manufacture of the light-emitting device, a vacuum process such as an evaporation method and a solution process such as a spin coating method or an inkjet method can be used. Examples of an evaporation method include physical vapor deposition methods (PVD methods) such as a sputtering method, an ion plating method, an ion beam evaporation method, a molecular beam evaporation method, and a vacuum evaporation method, and a chemical vapor deposition method (CVD method). Specifically, the functional layers (e.g., the hole-injection layer, the hole-transport layer, the light-emitting layer, the electron-transport layer, and the electron-injection layer) included in the EL layer can be formed by an evaporation method (e.g., a vacuum evaporation method), a coating method (e.g., a dip coating method, a die coating method, a bar coating method, a spin coating method, or a spray coating method), a printing method (e.g., an ink-jet method, a screen printing (stencil) method, an offset printing (planography) method, a flexography (relief printing) method, a gravure printing method, or a micro-contact printing method), or the like.

Thin films included in the display apparatus can be processed by a photolithography method or the like. Alternatively, thin films may be processed by a nanoimprinting method, a sandblasting method, a lift-off method, or the like. Alternatively, island-shaped thin films may be directly formed by a film formation method using a shielding mask such as a metal mask.

There are the following two typical examples of a photolithography method. In one of the methods, a resist mask is formed over a thin film that is to be processed, the thin film is processed by etching or the like, and then the resist mask is removed. In the other method, a photosensitive thin film is formed and then processed into a desired shape by light exposure and development.

As the light used for light exposure in the photolithography method, for example, an i-line (with a wavelength of 365 nm), a g-line (with a wavelength of 436 nm), an h-line (with a wavelength of 405 nm), or combined light of any of them can be used. Alternatively, ultraviolet rays, KrF laser light, ArF laser light, or the like can be used. In addition, light exposure may be performed by liquid immersion exposure technique. As the light used for the light exposure, extreme ultraviolet (EUV) light or X-rays may be used. Furthermore, instead of the light used for the light exposure, an electron beam can also be used. It is preferable to use extreme ultraviolet light, X-rays, or an electron beam because they can perform extremely fine processing. Note that in the case of performing light exposure by scanning of a beam such as an electron beam, a photomask is not necessarily used.

For etching of thin films, a dry etching method, a wet etching method, a sandblasting method, or the like can be used.

First, as illustrated in FIG. 7A, the insulating layer 255a, the insulating layer 255b, and the insulating layer 255c are formed in this order over the substrate 101. For the insulating layers 255a, 255b, and 255c, any of the structures that can be employed for the insulating layers 255a, 255b, and 255c described above can be employed.

Next, as illustrated in FIG. 7A, the pixel electrodes 111a, 111b, and 111c and the conductive layer 123 are formed over the insulating layer 255c, and a depressed portion is formed in a region of the insulating layer 255c that overlaps with none of the pixel electrodes 111a, 111b, and 111c and the conductive layer 123. The pixel electrodes 111a, 111b, and 111c and the depressed portion of the insulating layer 255c are preferably processed by anisotropic etching. For example, the pixel electrodes 111a, 111b, and 111c and the depressed portion of the insulating layer 255c can be processed by a dry etching method.

The above-described structure that can be employed for the pixel electrode can be employed for the pixel electrodes 111a, 111b, and 111c. The pixel electrodes 111a, 111b, and 111c can be formed by a sputtering method or a vacuum evaporation method, for example.

The steps formed by the pixel electrodes 111a, 111b, and 111c and the depressed portions of the insulating layer 255c are preferably so large that an EL film formed later is disconnected there.

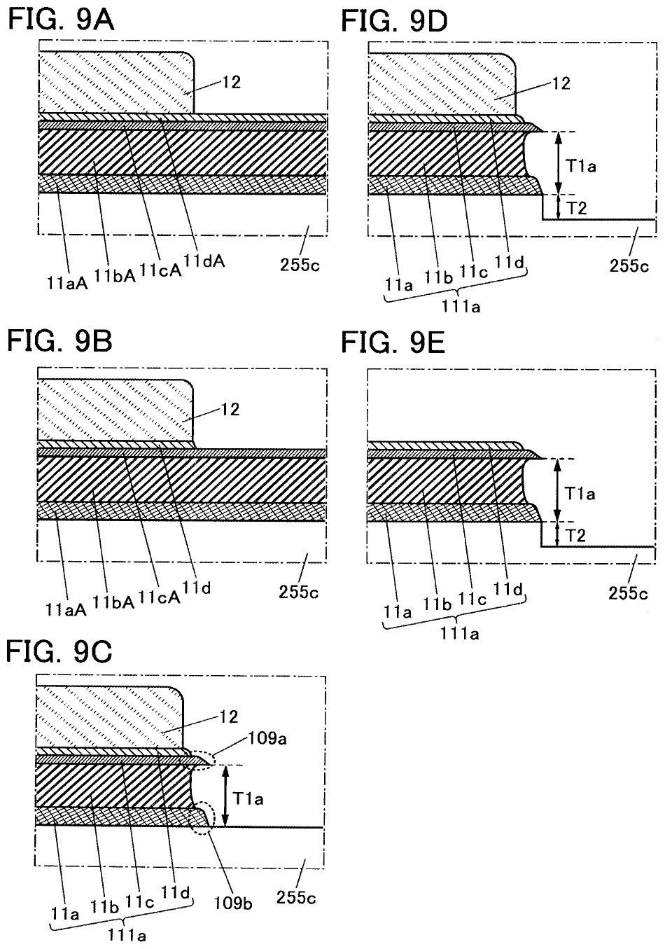

Here, an example of a method for fabricating the pixel electrode 111 that has the four-layer structure illustrated in FIG. 3B is described with reference to FIG. 9A to FIG. 9E. Although FIG. 9A to FIG. 9E illustrate an enlarged view of the vicinity of the pixel electrode 111a, the same illustration applies to the pixel electrode 111b and the pixel electrode 111c.

First, a conductive film 11aA, a conductive film 11bA, a conductive film 11cA, and a conductive film 11dA are formed in this order over the insulating layer 255c over the substrate 101 where a semiconductor circuit is formed. Here, the conductive film 11aA becomes the conductive layer 11a in a later step, the conductive film 11bA becomes the conductive layer 11b in a later step, the conductive film 11cA becomes the conductive layer 11c in a later step, and the conductive film 11dA becomes the conductive layer 11d in a later step.

The conductive film 11aA, the conductive film 11bA, the conductive film 11cA, and the conductive film 11dA are formed using the above-described conductive materials that can be used for the conductive layer 11a, the conductive layer 11b, the conductive layer 11c, and the conductive layer 11d. For example, titanium formed by a sputtering method can be used for the conductive film 11aA and the conductive film 11cA. Furthermore, for example, aluminum formed by a sputtering method can be used for the conductive film 11bA. Moreover, for example, an indium tin oxide containing silicon formed by a sputtering method can be used for the conductive film 11dA.

It is preferable that the conductive film 11aA, the conductive film 11bA, and the conductive film 11cA be successively formed without exposure to the air. In that case, the conductive film 11bA is formed without being oxidized. It is also preferable that heat treatment be performed after the formation of the conductive film 11cA, so that the conductive film 11cA is oxidized. In that case, the conductive film 11cA can contain titanium oxide having a high light-transmitting property.

Next, a resist mask 12 is formed over the conductive film 11dA (FIG. 9A). For the resist mask 12, a resist material containing a photosensitive resin such as a positive type resist material or a negative type resist material can be used.

Next, the conductive film 11dA is processed by etching treatment to form the conductive layer 11d (FIG. 9B). In the case where an indium tin oxide containing silicon is used for the conductive film 11dA, the etching treatment is preferably performed by a wet etching method. For example, organic acid containing citric acid, oxalic acid, or the like can be used. In that case, a side surface of the conductive layer 11d sometimes recedes from a side surface of the resist mask 12.

Then, the conductive film 11cA, the conductive film 11bA, and the conductive film 11aA are processed by etching treatment to form the conductive layer 11c, the conductive layer 11b, and the conductive layer 11a (FIG. 9C). Accordingly, the pixel electrode 111a in which the conductive layer 11a to the conductive layer 11d are stacked can be formed. Here, the sum of the thickness of the conductive layer 11a and the thickness of the conductive layer 11b corresponds to the thickness T1a illustrated in FIG. 3B.

Here, the deformation of the resist mask 12 during the etching of the conductive film 11cA, the conductive film 11bA, and the conductive film 11aA is preferably small. By performing the etching in such a manner, the side surface of the pixel electrode 111 can be inhibited from having a tapered shape. That is, the taper angle θ1 illustrated in FIG. 3B or the like can be greater than or equal to 60° and less than or equal to 140°, preferably greater than or equal to 70° and less than or equal to 140°, further preferably greater than or equal to 80° and less than or equal to 140°. In the above etching treatment, the etching rate of the conductive film 11bA is preferably higher than the etching rate of the conductive film 11cA. By performing the etching in such a manner, a shape such that a side surface of the conductive layer 11c projects from the side surface of the conductive layer 11b can be obtained. That is, the projecting portion 109a can be formed in the conductive layer 11c. In that case, the etching rate of the conductive film 11bA may be higher than the etching rate of the conductive film 11aA. By performing the etching in such a manner, a shape such that a side surface of the conductive layer 11a projects from the side surface of the conductive layer 11b can be obtained. That is, the projecting portion 109b can be formed in the conductive layer 11a.

In the case where titanium oxide is used for the conductive film 11cA, titanium is used for the conductive firm 11aA, and aluminum is used for the conductive film 11bA, the above etching treatment is preferably performed by a dry etching method. In that case, a chlorine-based gas is preferably used as an etching gas. The chlorine-based gas is a gas containing at least chlorine. As the chlorine-based gas, any of Cl₂, BCl₃, SiCl₄, CCl₄, and the like can be used alone or two or more of the gases can be mixed and used, for example. Moreover, an oxygen gas, a hydrogen gas, a helium gas, an argon gas, or the like or a mixture of two or more of the gases can be added to the chlorine-based gas as appropriate.

A dry etching apparatus including a high-density plasma source can be used as the dry etching apparatus. As the dry etching apparatus including a high-density plasma source, an inductively coupled plasma (ICP) etching apparatus or the like can be used, for example. Alternatively, a capacitively coupled plasma (CCP) etching apparatus including parallel plate electrodes can be used. The capacitively coupled plasma etching apparatus including parallel plate electrodes may have a structure where a high-frequency voltage is applied to one of the parallel plate electrodes. Alternatively, a structure may be employed in which different high-frequency voltages are applied to one of the parallel plate electrodes. Alternatively, a structure may be employed in which high-frequency voltages with the same frequency are applied to the parallel plate electrodes. Alternatively, a structure may be employed in which high-frequency voltages with different frequencies are applied to the parallel plate electrodes.

Next, etching treatment is performed to remove the vicinity of the surface of a region of the insulating layer 255c that does not overlap with the pixel electrode 111a, whereby a depressed portion with the depth T2 is formed in the insulating layer 255c (FIG. 9D). Here, in the above etching treatment, it is preferable to form the depressed portion with the depth T2 so as to satisfy the relation of T1a+T2≥T3, taking the thickness T3 of the fourth layer 113d formed later and the thickness T1a into account.

In the above etching treatment, the etching rate of the insulating layer 255c is preferably higher than the etching rate of at least part of the pixel electrode 111a. For example, in the case where silicon oxide or silicon oxynitride is used for the insulating layer 255c, the etching treatment is preferably performed by a dry etching method using a fluorine-based gas. Here, as the chlorine-based gas, CF₄, SF₆, NF₃, CHF₃, C₄F₆, C₅F₆, C₄F₈, C₅F₈, or the like can be used alone or two or more of the gases can be mixed and used. Moreover, an oxygen gas, a hydrogen gas, a helium gas, an argon gas, or the like or a mixture of two or more of the gases can be added as appropriate to the chlorine-based gas and the fluorine-based gas.

Furthermore, when the etching treatment is performed as described above, the side surface of the depressed portion of the insulating layer 255c can be inhibited from having a tapered shape. That is, the taper angle θ2 illustrated in FIG. 3B or the like can be greater than or equal to 60° and less than or equal to 140°, preferably greater than or equal to 70° and less than or equal to 140°, further preferably greater than or equal to 80° and less than or equal to 140°.

In the case where the insulating layer 255b functions as an etching protective film against the above etching treatment, the etching treatment may be performed until the insulating layer 255c is penetrated and the insulating layer 255b is exposed.

In this manner, the pixel electrode 111a and the depressed portion of the insulating layer 255c forming a sufficiently large step can be formed.

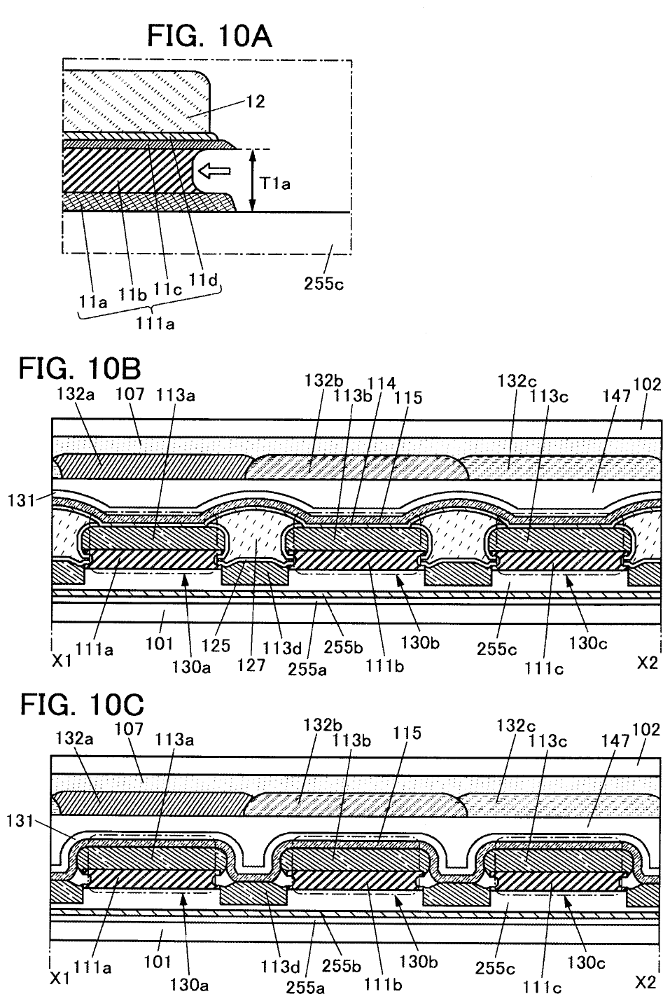

Note that in the above, isotropic etching may be performed before the formation of the depressed portion of the insulating layer 255c illustrated in FIG. 9D, so that the side surface of the conductive layer 11b further recedes (FIG. 10A). When the side surface of the conductive layer 11b further recedes, the pixel electrode 111 having the shape illustrated in FIG. 4B can be formed.

The isotropic etching can be performed by introducing an etching gas into a chamber of the above dry etching apparatus without application of a bias. In the case where titanium oxide is used for the conductive film 11cA, titanium is used for the conductive film 11aA, and aluminum is used for the conductive film 11bA, a chlorine-based gas is preferably used as the etching gas. The chlorine-based gas contains at least chlorine. As the chlorine-based gas, any of Cl₂, BCl₃, SiCl₄, CCl₄, and the like can be used alone or two or more of the gases can be mixed and used, for example.

By etching under the above conditions, the conductive layer 11b can be isotropically etched under the conditions where the etching rate of the conductive layer 11b is higher than that of the conductive layer 11c. Thus, the distance between the side surface of the conductive layer 11b and the side surface of the conductive layer 11c can be increased, and the projecting portion 109a can be relatively large. Thus, the EL film can be easily divided in a self-aligned manner in the formation of the EL film described later.

In this case, the etching rate of the conductive layer 11b is higher than that of the conductive layer 11a in some cases. Accordingly, the distance between the side surface of the conductive layer 11b and the side surface of the conductive layer 11a is increased and the projecting portion 109b becomes relatively large in some cases.

Next, the resist mask 12 is removed (FIG. 9E). The resist mask 12 can be removed by ashing using oxygen plasma, for example. Alternatively, an oxygen gas and any of CF₄, C₄F₈, SF₆, CHF₃, Cl₂, H₂O, BCl₃, and a noble gas (also referred to as rare gas) such as He may be used. Alternatively, the resist mask 12 may be removed by wet etching. Alternatively, the resist mask 12 may be removed by combining the ashing and the wet etching.

Here, hydrophobic treatment is preferably performed on the pixel electrodes 111a, 111b, and 111c. The hydrophobic treatment can change the hydrophilic properties of the subject surface to hydrophobic properties or increase the hydrophobic properties of the subject surface. By performing hydrophobic treatment on the pixel electrodes, adhesion between the pixel electrodes and the first layer 113a, the second layer 113b, and the third layer 113c formed later can be increased, so that film peeling can be inhibited. Note that the hydrophobic treatment is not necessarily performed.

The hydrophobic treatment can be performed by fluorine modification of the pixel electrode, for example. The fluorine modification can be performed by treatment using a gas containing fluorine, heat treatment, plasma treatment in a gas atmosphere containing fluorine, or the like. As the fluorine-containing gas, a fluorine gas such as a fluorocarbon gas can be used, for example. As the fluorocarbon gas, a low-molecular-weight carbon fluoride gas such as a carbon tetrafluoride (CF₄) gas, a C₄F₆ gas, a C₂F₆ gas, a C₄F₈ gas, or C₅F₈ can be used, for example. Alternatively, as the gas containing fluorine, an SF₆ gas, an NF₃ gas, a CHF₃ gas, or the like can be used, for example. Moreover, a helium gas, an argon gas, a hydrogen gas, or the like can be added to any of the above gases as appropriate.

Treatment using a silylating agent is performed on the surface of the pixel electrode after plasma treatment is performed in a gas atmosphere containing a Group 18 element such as argon, so that the surface of the pixel electrode can have a hydrophobic property. As the silylating agent, hexamethyldisilazane (HMDS), trimethylsilylimidazole (TMSI), or the like can be used. Alternatively, treatment using a silane coupling agent is performed on the surface of the pixel electrode after plasma treatment is performed in a gas atmosphere containing a Group 18 element such as argon, so that the surface of the pixel electrode can have a hydrophobic property.

Plasma treatment on the surface of the pixel electrode in a gas atmosphere containing a Group 18 element such as argon can apply damage to the surface of the pixel electrode. Accordingly, a methyl group included in the silylating agent such as HMDS is likely to bond to the surface of the pixel electrode. Moreover, silane coupling due to the silane coupling agent is likely to occur. As described above, treatment using a silylating agent or a silane coupling agent performed on the surface of the pixel electrode after plasma treatment in a gas atmosphere containing a Group 18 element such as argon enables the surface of the pixel electrode to have a hydrophobic property.

The treatment using a silylating agent, a silane coupling agent, or the like can be performed by application of the silylating agent, the silane coupling agent, or the like by a spin coating method, a dipping method, or the like. Alternatively, the treatment using a silylating agent, a silane coupling agent, or the like can be performed by forming a film containing the silylating agent, a film containing the silane coupling agent, or the like over the pixel electrode or the like by a gas phase method, for example. In a gas phase method, first, a material containing a silylating agent, a material containing a silane coupling agent, or the like is evaporated so that the silylating agent, the silane coupling agent, or the like is contained in an atmosphere. Next, a substrate where the pixel electrode and the like are formed is put in the atmosphere. Accordingly, a film containing the silylating agent, the silane coupling agent, or the like can be formed over the pixel electrode, so that the surface of the pixel electrode can have a hydrophobic property.

Next, the EL film is formed over the pixel electrodes 111a, 111b, and 111c. Here, the steps formed by the pixel electrodes 111a, 111b, and 111c and the insulating layer 255c are sufficiently large as described above; thus, the EL film is divided in a self-aligned manner at the end portions of the pixel electrodes. That is, as illustrated in FIG. 7B, the first layer 113a is formed over the pixel electrode 111a, the second layer 113b is formed over the pixel electrode 111b, the third layer 113c is formed over the pixel electrode 111c, and the fourth layer 113d is formed in the depressed portion between adjacent pixel electrodes 111.

The EL film is a film to be the first layer 113a, the second layer 113b, the third layer 113c, and the fourth layer 113d. Therefore, the EL film can employ the above-described structure applicable to the first layer 113a, the second layer 113b, the third layer 113c, and the fourth layer 113d. The EL film can be formed by an evaporation method (including a vacuum evaporation method), a transfer method, a printing method, an inkjet method, a coating method, or the like. The EL film is preferably formed by an evaporation method. A premix material may be used in the film formation by an evaporation method. Note that in this specification and the like, a premix material is a composite material in which a plurality of materials are combined or mixed in advance.

As illustrated in FIG. 7B, an end portion of the fourth layer 113d is positioned closer to the display portion than the connection portion 140 is in the cross-sectional view along Y1-Y2. That is, an EL film including the fourth layer 113d is not formed around the conductive layer 123 in the connection portion 140. For example, by using a mask for specifying a film formation area (also referred to as an area mask, a rough metal mask, or the like to be distinguished from a fine metal mask), the fourth layer 113d can be formed in different regions. With the combination of the area mask as described above, a light-emitting device can be manufactured in a relatively simple process.

Next, as illustrated in FIG. 7C, an insulating film 125A is formed to cover the first layer 113a, the second layer 113b, the third layer 113c, and the fourth layer 113d.

The insulating film 125A is a film to be the insulating layer 125 later. Thus, the insulating film 125A can be formed using a material that can be used for the insulating layer 125. As the insulating film 125A, an inorganic insulating film can be formed by an ALD method, an evaporation method, a sputtering method, a CVD method, or a PLD method, for example. The thickness of the insulating film 125A is preferably greater than or equal to 3 nm, greater than or equal to 5 nm, or greater than or equal to 10 nm and less than or equal to 200 nm, less than or equal to 150 nm, less than or equal to 100 nm, or less than or equal to 50 nm.

As the insulating film 125A, an aluminum oxide film is preferably formed by an ALD method, for example. The use of an ALD method is preferable, in which case damage by the deposition is reduced and a film with favorable coverage can be deposited.

As described later, an insulating layer 127A including a photosensitive organic resin is formed in contact with the top surface of the insulating film 125A. Therefore, the top surface of the insulating film 125A preferably has a high affinity with respect to a photosensitive organic resin used for the insulating layer 127A (e.g., a photosensitive resin composition containing an acrylic resin). To improve the affinity, the top surface of the insulating film 125A is preferably made to be hydrophobic (or more hydrophobic) by surface treatment. For example, the treatment is preferably performed using a silylating agent such as hexamethyldisilazane (HMDS). When the top surface of the insulating film 125A is made to be hydrophobic in this manner, the insulating layer 127A can be formed with favorable adhesiveness. Note that the above-described hydrophobic treatment may be performed as the surface treatment.

Next, as illustrated in FIG. 7C, the insulating layer 127A is applied onto the insulating film 125A.

The insulating layer 127A is a film to be the insulating layer 127 in a later step, and any of the above-described organic materials can be used for the insulating layer 127A. As the organic material, a photosensitive organic resin is preferably used; for example, a photosensitive resin composition containing an acrylic resin may be used. The viscosity of the material of the insulating layer 127A is greater than or equal to 1 cP and less than or equal to 1500 cP, and is preferably greater than or equal to 1 cP and less than or equal to 12 cP. By setting the viscosity of the material of the insulating layer 127A in the above range, the insulating layer 127 having a tapered shape as illustrated in FIG. 1B and the like can be formed relatively easily.

The insulating layer 127A is preferably formed using a resin composition containing a polymer, an acid-generating agent, and a solvent, for example. The polymer is formed using one or more kinds of monomers and has a structure in which one or more kinds of structural units (also referred to as building blocks) are repeated regularly or irregularly. As the acid-generating agent, one or both of a compound that generates an acid by light irradiation and a compound that generates an acid by heating can be used. The resin composition may also include one or more of a photosensitizing agent, a sensitizer, a catalyst, an adhesive aid, a surface-active agent, and an antioxidant.

There is no particular limitation on the method for forming the insulating layer 127A; for example, the insulating layer 127A can be formed by a wet film formation method such as spin coating, dipping, spray coating, ink-jetting, dispensing, screen printing, offset printing, a doctor knife method, slit coating, roll coating, curtain coating, or knife coating. Specifically, an organic insulating film that is to be the insulating layer 127A is preferably formed by spin coating.

Heat treatment is preferably performed after the application of the insulating layer 127A. The heat treatment is performed at a temperature lower than the heat resistance temperature of the EL layers. The heat treatment may be performed with a substrate temperature higher than or equal to 50° C. and lower than or equal to 200° C., preferably higher than or equal to 60° C. and lower than or equal to 150° C., further preferably higher than or equal to 70° C. and lower than or equal to 120° C. Accordingly, a solvent contained in the insulating layer 127A can be removed.

Then, part of the insulating layer 127A is exposed to visible light or ultraviolet rays. Furthermore, the region of the insulating layer 127A exposed to light is removed by development as illustrated in FIG. 8A, so that the insulating layer 127 is formed.

Here, when a barrier insulating layer against oxygen (e.g., an aluminum oxide film) is provided as the insulating film 125A, diffusion of oxygen into the EL layer can be reduced. In particular, when the EL layer is irradiated with light (visible light or ultraviolet rays), an organic compound contained in the EL layer is brought into an excited state and a reaction with oxygen contained in the atmosphere is promoted in some cases. Specifically, when the EL layer is irradiated with light (visible light or ultraviolet rays) in an atmosphere containing oxygen, oxygen might be bonded to the organic compound contained in the EL layer. When the insulating film 125A is provided over the EL layer, bonding of oxygen in the atmosphere to the organic compound contained in the EL layer can be reduced.

In the case where an acrylic resin is used for the insulating layer 127A, an alkaline solution is preferably used as a developer, and for example, a tetramethyl ammonium hydroxide (TMAH) aqueous solution is used. After the development, visible light or ultraviolet rays may be further irradiated. Performing such light exposure can improve the transparency of the insulating layer 127 in some cases.

In addition, heat treatment may be further performed after the development. The heat treatment enables the insulating layer 127 to have a tapered shape on the side surface as illustrated in FIG. 8A. By heat treatment, polymerization of the insulating layer 127 can be started and the insulating layer 127 can be cured. The heat treatment is performed at a temperature lower than the heat resistance temperature of the EL layers. The substrate temperature at the time of the heat treatment is higher than or equal to 50° C. and lower than or equal to 200° C., preferably higher than or equal to 60° C. and lower than or equal to 150° C., further preferably higher than or equal to 70° C. and lower than or equal to 130° C. The substrate temperature in the heat treatment of this step is preferably higher than that in the heat treatment after the application of the insulating layer 127. Accordingly, adhesion between the insulating layer 127 and the insulating film 125A can be improved, and corrosion resistance of the insulating layer 127 can also be increased.

Heat treatment may be further performed after the insulating layer 127 is processed into a tapered shape. Etching may be performed so that the surface level of the insulating layer 127 is adjusted. The insulating layer 127 may be processed by ashing using oxygen plasma, for example.

Although the step of providing the insulating layer 127 by forming the insulating layer 127A is described above, the present invention is not limited thereto. A structure where the insulating layer 127A is not formed and the insulating layer 127 is not provided can be employed.

Then, as illustrated in FIG. 8A, the insulating film 125A is removed at least partly to expose the first layer 113a, the second layer 113b, the third layer 113c, and the conductive layer 123.

As illustrated in FIG. 8A, a region of the insulating film 125A that overlaps with the insulating layer 127 remains as the insulating layer 125.

The insulating layer 125 (and the insulating layer 127) is (are) provided to cover the side surfaces and parts of the top surfaces of the pixel electrodes 111a, 111b, and 111c, the first layer 113a, the second layer 113b, and the third layer 113c. This inhibits the side surfaces of these layers from being in contact with a film to be formed later, thereby inhibiting a short circuit of the light-emitting device. In addition, damage to the first layer 113a, the second layer 113b, and the third layer 113c in later steps can be inhibited.

The insulating film 125A can be processed by a wet etching method or a dry etching method.

In processing of the insulating film 125A, damage to the EL layer can be less in the case of using a wet etching method than in the case of using a dry etching method. In the case of using a wet etching method, it is preferable to use a developer, a tetramethylammonium hydroxide (TMAH) aqueous solution, dilute hydrofluoric acid, oxalic acid, phosphoric acid, acetic acid, nitric acid, or a chemical solution containing a mixed solution of any of these acids, for example.

In the case of using a dry etching method, deterioration of the EL layer can be inhibited by not using a gas containing oxygen as the etching gas. In the case of using a dry etching method, it is preferable to use a gas containing CF₄, C₄F₈, SF₆, CHF₃, Cl₂, H₂O, or BCl₃ or a noble gas (also referred to as a rare gas) such as He as the etching gas, for example.

For example, when an aluminum oxide film formed by an ALD method is used as the insulating film 125A, the insulating film 125A can be processed by a dry etching method using CHF₃ and He.

Then, as illustrated in FIG. 8B, the common layer 114 is formed to cover the insulating layer 125, the insulating layer 127, the first layer 113a, the second layer 113b, and the third layer 113c.

In FIG. 8B, the cross-sectional view along Y1-Y2 illustrates the example where the common layer 114 is not provided in the connection portion 140. As illustrated in FIG. 8B, an end portion of the common layer 114 on the connection portion 140 side is preferably positioned inward from the connection portion 140. In forming the common layer 114, for example, a mask for specifying the film formation area (also referred to as an area mask or a rough metal mask) is preferably used.

The common layer 114 may be provided in the connection portion 140 depending on the level of the conductivity of the common layer 114. With such a structure, it is possible to form the connection portion 140 having the structure illustrated in FIG. 6A where the conductive layer 123 is electrically connected to the common electrode 115 through the common layer 114.

Materials that can be used for the common layer 114 are as described above. The common layer 114 can be formed by an evaporation method (including a vacuum evaporation method), a transfer method, a printing method, an inkjet method, a coating method, or the like. The common layer 114 may be formed using a premix material.

The common layer 114 is provided to cover the top surfaces of the first layer 113a, the second layer 113b, and the third layer 113c and the top surface and the side surface of the insulating layer 127. Here, in the case where the common layer 114 has high conductivity, a short circuit of the light-emitting device might be caused when the common layer 114 is in contact with any of the side surfaces of the pixel electrodes 111a, 111b, and 111c, the first layer 113a, the second layer 113b, and the third layer 113c. However, in the display apparatus of one embodiment of the present invention, the insulating layers 125 and 127 cover the side surfaces of the first layer 113a, the second layer 113b, the third layer 113c, the pixel electrode 111a, the pixel electrode 111b, and the pixel electrode 111c. This inhibits the common layer 114 having high conductivity from being in contact with the side surfaces of these layers, whereby a short circuit in the light-emitting device can be inhibited. Thus, the reliability of the light-emitting device can be increased.

Since the space between the first layer 113a and the second layer 113b and the space between the second layer 113b and the third layer 113c are filled with the insulating layers 125 and 127, the formation surface of the common layer 114 has a smaller step and higher flatness than the formation surface of the case where the insulating layers 125 and 127 are not provided. This can improve the coverage with the common layer 114.

Then, the common electrode 115 is formed over the common layer 114 and the conductive layer 123 as illustrated in FIG. 8C. Accordingly, the conductive layer 123 and the common electrode 115 are in direct contact with each other to be electrically connected to each other. With such a structure, it is possible to form the connection portion 140 having the structure illustrated in FIG. 6B where the top surface of the conductive layer 123 is in contact with the common electrode 115.

A mask for specifying a film formation area (also referred to as an area mask, a rough metal mask, or the like) may be used in the formation of the common electrode 115. Alternatively, the common electrode 115 may be formed without the use of the mask and may be processed with the use of a resist mask or the like after the common electrode 115 is formed.

Materials that can be used for the common electrode 115 are as described above. The common electrode 115 can be formed by a sputtering method or a vacuum evaporation method, for example. Alternatively, the common electrode 115 may be a stack of a film formed by an evaporation method and a film formed by a sputtering method.

Next, the protective layer 131 is formed over the common electrode 115 as illustrated in FIG. 8C. Materials and film formation methods that can be used for the protective layer 131 are as described above. Examples of methods for forming the protective layer 131 include a vacuum evaporation method, a sputtering method, a CVD method, and an ALD method. The protective layer 131 may have a single-layer structure or a stacked-layer structure.

Then, the resin layer 147 is formed over the protective layer 131, and the coloring layer 132 is formed over the resin layer 147. Furthermore, the substrate 102 is bonded onto the coloring layer 132 with the adhesive layer 107, whereby the display apparatus 100 illustrated in FIG. 1B can be manufactured. In the case where the step illustrated in FIG. 10A is performed, the display apparatus 100 illustrated in FIG. 10B, in which the pixel electrode 111 is shaped to have a receding side surface, can be manufactured.

In the case where the insulating layer 127 is not formed, the display apparatus 100 illustrated in FIG. 6C can be manufactured. Furthermore, in the case where the step illustrated in FIG. 10A is performed, the display apparatus 100 illustrated in FIG. 10C, in which the pixel electrode 111 is shaped to have a receding side surface, can be manufactured.

Through the above steps, the above-described the display apparatus 100 can be manufactured.

This embodiment can be combined with the other embodiments as appropriate.

### Embodiment 2

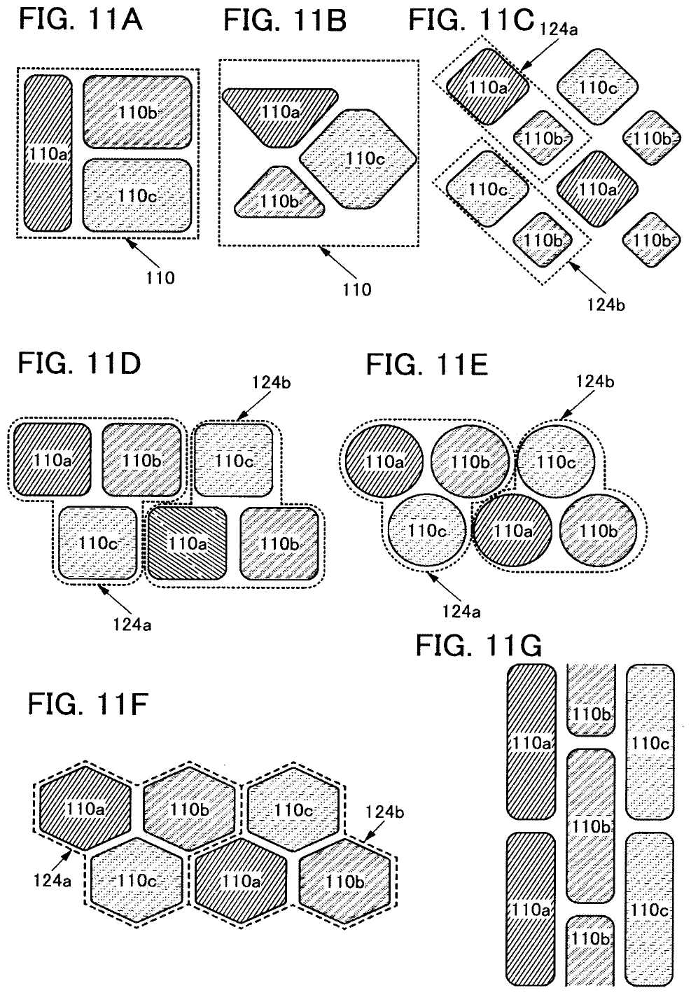

In this embodiment, a display apparatus of one embodiment of the present invention is described with reference to FIG. 11 to FIG. 13.

### [Pixel Layout]

In this embodiment, pixel layouts different from that in FIG. 1A are mainly described. There is no particular limitation on the arrangement of subpixels, and a variety of methods can be employed. Examples of the arrangement of subpixels include stripe arrangement, S-stripe arrangement, matrix arrangement, delta arrangement, Bayer arrangement, and PenTile arrangement.

Examples of a top surface shape of the subpixel include polygons such as a triangle, a tetragon (including a rectangle and a square), and a pentagon; polygons with rounded corners; an ellipse; and a circle. Here, the top surface shape of the subpixel corresponds to the top surface shape of a light-emitting region of the light-emitting device.

The range of the circuit layout for forming the subpixels is not limited to the range of the subpixels illustrated in a diagram and may be placed outside the subpixels.

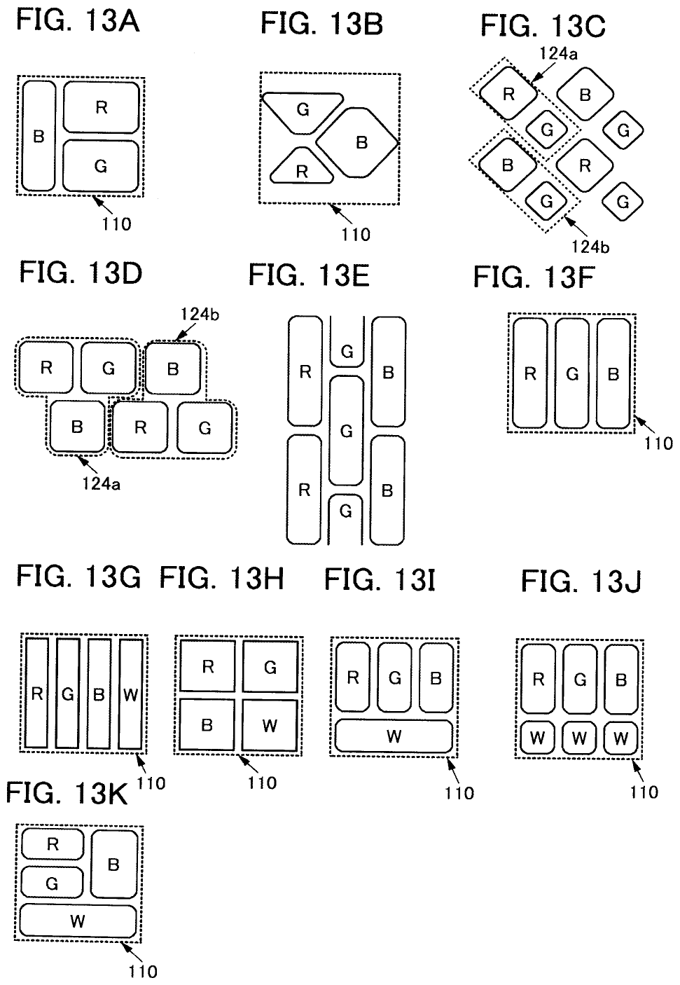

The pixel 110 illustrated in FIG. 11A employs S-stripe arrangement. The pixel 110 illustrated in FIG. 11A is composed of three subpixels 110a, 110b, and 110c. For example, as illustrated in FIG. 13A, the subpixel 110a may be a blue subpixel B, the subpixel 110b may be a red subpixel R, and the subpixel 110c may be a green subpixel G.

The pixel 110 illustrated in FIG. 11B includes the subpixel 110a whose top surface shape is a rough trapezoid with rounded corners, the subpixel 110b whose top surface shape is a rough triangle with rounded corners, and the subpixel 110c whose top surface shape is a rough tetragon or a rough hexagon with rounded corners. The subpixel 110a has a larger light-emitting area than the subpixel 110b. In this manner, the shapes and sizes of the subpixels can be determined independently. For example, the size of a subpixel including a light-emitting device with higher reliability can be smaller. For example, as illustrated in FIG. 13B, the subpixel 110a may be the green subpixel G, the subpixel 110b may be the red subpixel R, and the subpixel 110c may be the blue subpixel B.

Pixels 124a and 124b illustrated in FIG. 11C employ PenTile arrangement. FIG. 11C illustrates an example in which the pixels 124a each including the subpixel 110a and the subpixel 110b and the pixels 124b each including the subpixel 110b and the subpixel 110c are alternately arranged. For example, as illustrated in FIG. 13C, the subpixel 110a may be the red subpixel R, the subpixel 110b may be the green subpixel G, and the subpixel 110c may be the blue subpixel B.

The pixels 124a and 124b illustrated in FIG. 11D to FIG. 11F employ delta arrangement. The pixel 124a includes two subpixels (the subpixels 110a and 110b) in the upper row (first row) and one subpixel (the subpixel 110c) in the lower row (second row). The pixel 124b includes one subpixel (the subpixel 110c) in the upper row (first row) and two subpixels (the subpixels 110a and 110b) in the lower row (second row). For example, as illustrated in FIG. 13D, the subpixel 110a may be the red subpixel R, the subpixel 110b may be the green subpixel G, and the subpixel 110c may be the blue subpixel B.

FIG. 11D illustrates an example in which each subpixel has a rough tetragonal top surface shape with rounded corners, FIG. 11E illustrates an example in which each subpixel has a circular top surface shape, and FIG. 11F illustrates an example in which each subpixel has a rough hexagonal top surface shape with rounded corners.

In FIG. 11F, subpixels are placed inside respective hexagonal regions that are arranged densely. Focusing on one of the subpixels, the subpixel is placed so as to be surrounded by six subpixels. The subpixels are arranged such that subpixels that emit light of the same color are not adjacent to each other. For example, focusing on the subpixel 110a, three subpixels 110b and three subpixels 110c are arranged to surround the subpixel 110a, so that the subpixel 110a, the subpixel 110b, and the subpixel 110c are alternately arranged.

FIG. 11G illustrates an example in which subpixels of different colors are arranged in a zigzag manner. Specifically, the positions of the top sides of two subpixels arranged in the column direction (e.g., the subpixel 110a and the subpixel 110b or the subpixel 110b and the subpixel 110c) are not aligned in the top view. For example, as illustrated in FIG. 13E, the subpixel 110a may be the red subpixel R, the subpixel 110b may be the green subpixel G, and the subpixel 110c may be the blue subpixel B.

In a photolithography method, as a pattern to be formed by processing becomes finer, the influence of light diffraction becomes more difficult to ignore; accordingly, the fidelity in transferring a photomask pattern by light exposure is degraded, and it becomes difficult to process a resist mask into a desired shape. Thus, a pattern with rounded corners is likely to be formed even with a rectangular photomask pattern. Consequently, the top surface shape of the pixel electrode may be a polygon with rounded corners, an ellipse, a circle, or the like. In the display apparatus of one embodiment of the present invention, the top surface shape of the EL layer and the top surface shape of the light-emitting device may each be a polygon with rounded corners, an ellipse, a circle, or the like due to the influence of the top surface shape of the pixel electrode.

Note that to obtain a desired top surface shape of the pixel electrode, a technique of correcting a mask pattern in advance so that a transferred pattern agrees with a design pattern (an OPC (Optical Proximity Correction) technique) may be used. Specifically, with the OPC technique, a pattern for correction is added to a corner portion or the like of a figure on a mask pattern.

Also in the pixel 110 illustrated in FIG. 1A, which employs stripe arrangement, for example, the subpixel 110a can be the red subpixel R, the subpixel 110b can be the green subpixel G, and the subpixel 110c can be the blue subpixel B as illustrated in FIG. 13F.

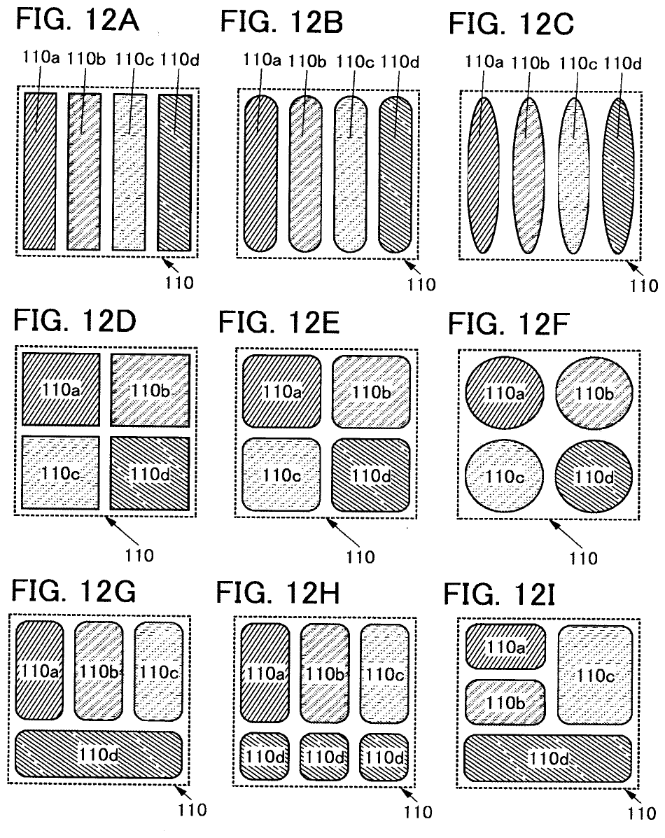

As illustrated in FIG. 12A to FIG. 12I, the pixel can include four types of subpixels.

The pixels 110 illustrated in FIG. 12A to FIG. 12C each employ stripe arrangement.

FIG. 12A illustrates an example in which each subpixel has a rectangular top surface shape, FIG. 12B illustrates an example in which each subpixel has a top surface shape formed by combining two half circles and a rectangle, and FIG. 12C illustrates an example in which each subpixel has an elliptical top surface shape.

The pixels 110 illustrated in FIG. 12D to FIG. 12F each employ matrix arrangement.

FIG. 12D illustrates an example in which each subpixel has a square top surface shape, FIG. 12E illustrates an example in which each subpixel has a rough square top surface shape with rounded corners, and FIG. 12F illustrates an example in which each subpixel has a circular top surface shape.

FIG. 12G and FIG. 12H each illustrate an example in which one pixel 110 is composed of two rows and three columns.

The pixel 110 illustrated in FIG. 12G includes three subpixels (the subpixels 110a, 110b, and 110c) in the upper row (first row) and one subpixel (a subpixel 110d) in the lower row (second row). In other words, the pixel 110 includes the subpixel 110a in the left column (first column), the subpixel 110b in the center column (second column), the subpixel 110c in the right column (third column), and the subpixel 110d across these three columns.

The pixel 110 illustrated in FIG. 12H includes three subpixels (the subpixels 110a, 110b, and 110c) in the upper row (first row) and three subpixels 110d in the lower row (second row). In other words, the pixel 110 includes the subpixel 110a and the subpixel 110d in the left column (first column), the subpixel 110b and another subpixel 110d in the center column (second column), and the subpixel 110c and another subpixel 110d in the right column (third column). Aligning the positions of the subpixels in the upper row and the lower row as illustrated in FIG. 12H enables dust and the like that would be produced in the manufacturing process to be removed efficiently. Thus, a display apparatus with high display quality can be provided.

FIG. 12I illustrates an example where one pixel 110 is composed of three rows and two columns.

The pixel 110 illustrated in FIG. 12I includes the subpixel 110a in the upper row (first row), the subpixel 110b in the center row (second row), the subpixel 110c across the first row and the second row, and one subpixel (the subpixel 110d) in the lower row (third row). In other words, the pixel 110 includes the subpixels 110a and 110b in the left column (first column), the subpixel 110c in the right column (second column), and the subpixel 110d across these two columns.

The pixels 110 illustrated in FIG. 12A to FIG. 12I are each composed of the four subpixels 110a, 110b, 110c, and 110d. The subpixels 110a, 110b, 110c, and 110d are subpixels that emit light of different colors. As the subpixels 110a, 110b, 110c, and 110d, subpixels of four colors of R, G, B, and white (W), subpixels of four colors of R, G, B, and Y, subpixels of R, G, B, and infrared light (IR), and the like can be given.

For example, as illustrated in FIG. 13G to FIG. 13K, the subpixel 110a can be the subpixel R emitting red light, the subpixel 110b can be the subpixel G emitting green light, the subpixel 110c can be the subpixel B emitting blue light, and the subpixel 110d can be a subpixel W emitting white light. In this case, the light-emitting device 130 and the coloring layer 132 are provided in each of the subpixels 110a, 110b, and 110c as the structure illustrated in FIG. 1B and the like. Meanwhile, in the subpixel 110d, although the light-emitting device 130 is provided in a similar manner, the coloring layer 132 is not provided. Thus, white light of the light-emitting device 130 is directly emitted from the subpixel 110d. Alternatively, the subpixel 110d can be a subpixel Y emitting yellow light or a subpixel IR emitting near-infrared light. In the above-described structure, stripe arrangement is employed as the layout of R, G, and B in the pixels 110 illustrated in FIG. 131 and FIG. 13J, leading to higher display quality. In addition, what is called S-stripe arrangement is employed as the layout of R, G, and B in the pixel 110 illustrated in FIG. 13K, leading to higher display quality. Note that the number of types of subpixels is not limited to four, and five or more types of subpixels may be used.

As described above, the pixel composed of the subpixels each including the light-emitting device can employ any of a variety of layouts in the display apparatus of one embodiment of the present invention.

This embodiment can be combined with the other embodiments as appropriate.

### Embodiment 3

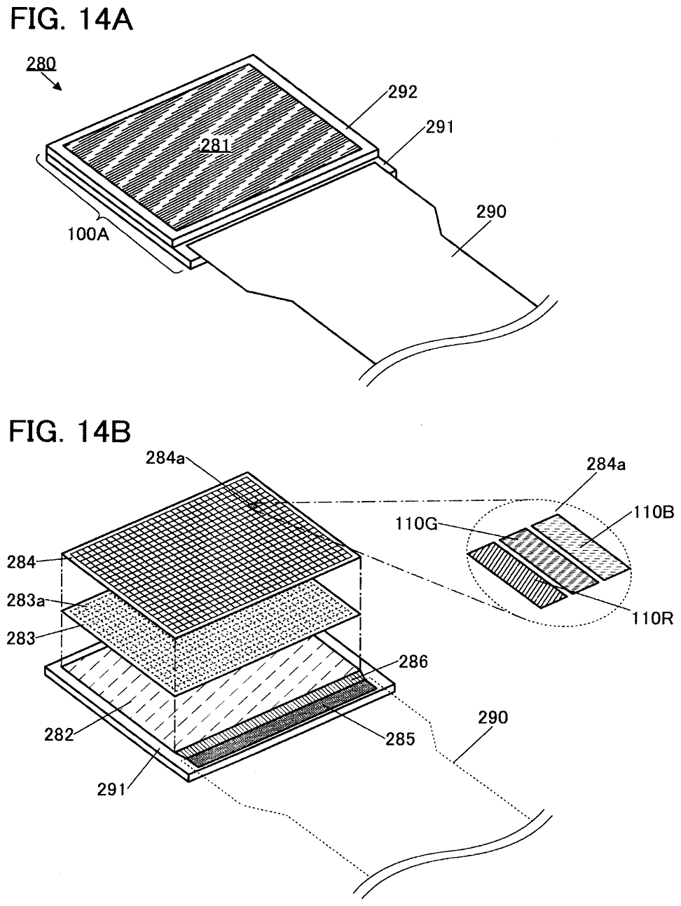

In this embodiment, display apparatuses of one embodiment of the present invention are described with reference to FIG. 14 to FIG. 29. The display apparatus of this embodiment uses some or all of the components of the display apparatuses described in the above embodiments, and similar components are denoted by the same reference numerals. The description in the above embodiments can be referred to for the components denoted by the same reference numerals.

The display apparatus of this embodiment can be a high-resolution display apparatus. Accordingly, the display apparatus of this embodiment can be used for display portions of information terminals (wearable devices) such as watch-type and bracelet-type information terminals and display portions of wearable devices that can be worn on a head, such as a VR device like a head-mounted display and a glasses-type AR device.

The display apparatus of this embodiment can be a high-definition display apparatus or a large-sized display apparatus. Accordingly, the display apparatus of this embodiment can be used for display portions of electronic devices such as a digital camera, a digital video camera, a digital photo frame, a mobile phone, a portable game console, a portable information terminal, and an audio reproducing device, in addition to display portions of electronic devices with a relatively large screen, such as a television device, a desktop or notebook personal computer, a monitor of a computer and the like, digital signage, and a large game machine such as a pachinko machine.

Since the EL layers of the respective light-emitting devices in the display apparatus of this embodiment are separated from each other, crosstalk generated between adjacent subpixels can be inhibited while the display apparatus has high resolution. Accordingly, the display apparatus can have high resolution and high display quality.

### [Display Module]

FIG. 14A is a perspective view of a display module 280. The display module 280 includes a display apparatus 100A and an FPC 290. Note that the display apparatus included in the display module 280 is not limited to the display apparatus 100A and may be any of a display apparatus 100B to a display apparatus 100F to be described later.

The display module 280 includes a substrate 291 and a substrate 292. The display module 280 includes a display portion 281. The display portion 281 is a region of the display module 280 where an image is displayed, and is a region where light from pixels provided in a pixel portion 284 to be described later can be seen.

FIG. 14B is a perspective view schematically illustrating a structure on the substrate 291 side. Over the substrate 291, a circuit portion 282, a pixel circuit portion 283 over the circuit portion 282, and the pixel portion 284 over the pixel circuit portion 283 are stacked. A terminal portion 285 to be connected to the FPC 290 is provided in a portion over the substrate 291 which does not overlap with the pixel portion 284. The terminal portion 285 and the circuit portion 282 are electrically connected to each other through a wiring portion 286 formed of a plurality of wirings.

The pixel portion 284 includes a plurality of pixels 284a arranged periodically. An enlarged view of one pixel 284a is illustrated on the right side of FIG. 14B. The pixel 284a includes the subpixel 110R emitting red light, the subpixel 110G emitting green light, and the subpixel 110B emitting blue light. Here, each of the subpixel 110R, the subpixel 110G, and the subpixel 110B corresponds to any of the subpixel 110a, the subpixel 110b, and the subpixel 110c illustrated in FIG. 1B and the like.

The pixel circuit portion 283 includes a plurality of pixel circuits 283a arranged periodically.

One pixel circuit 283a is a circuit controlling light emission of three light-emitting devices included in one pixel 284a. One pixel circuit 283a may be provided with three circuits each of which controls light emission of one light-emitting device. For example, the pixel circuit 283a can include at least one selection transistor, one current control transistor (driving transistor), and a capacitor for one light-emitting device. In this case, a gate signal is input to the gate of the selection transistor, and a source signal is input to the source thereof. With such a structure, an active-matrix display apparatus is achieved.

The circuit portion 282 includes a circuit for driving the pixel circuits 283a in the pixel circuit portion 283. For example, one or both of a gate line driver circuit and a source line driver circuit are preferably included. In addition, at least one of an arithmetic circuit, a memory circuit, a power supply circuit, and the like may be included.

The FPC 290 functions as a wiring for supplying a video signal, a power supply potential, or the like to the circuit portion 282 from the outside. An IC may be mounted on the FPC 290.

The display module 280 can have a structure in which one or both of the pixel circuit portion 283 and the circuit portion 282 are stacked below the pixel portion 284; thus, the aperture ratio (the effective display area ratio) of the display portion 281 can be significantly high. For example, the aperture ratio of the display portion 281 can be higher than or equal to 40% and lower than 100%, preferably higher than or equal to 50% and lower than or equal to 95%, further preferably higher than or equal to 60% and lower than or equal to 95%. Furthermore, the pixels 284a can be arranged extremely densely and thus the display portion 281 can have an extremely high resolution. For example, the pixels 284a are preferably arranged in the display portion 281 with a resolution higher than or equal to 2000 ppi, preferably higher than or equal to 3000 ppi, further preferably higher than or equal to 5000 ppi, still further preferably higher than or equal to 6000 ppi, and lower than or equal to 20000 ppi or lower than or equal to 30000 ppi.

Such a display module 280 has an extremely high resolution, and thus can be suitably used for a VR device such as a head-mounted display or a glasses-type AR device. For example, even with a structure where the display portion of the display module 280 is seen through a lens, pixels of the extremely-high-resolution display portion 281 included in the display module 280 are prevented from being perceived when the display portion is enlarged by the lens, so that display providing a high sense of immersion can be performed. Without being limited thereto, the display module 280 can be suitably used for electronic devices including a relatively small display portion. For example, the display module 280 can be favorably used for a display portion of a wearable electronic device, such as a wrist watch.

### [Display Apparatus 100A]

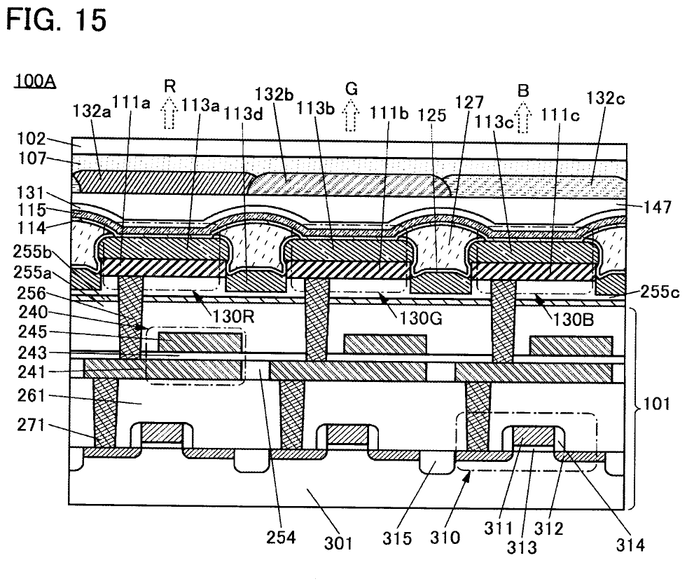

The display apparatus 100A illustrated in FIG. 15 includes a substrate 301, light-emitting devices 130R, 130G and 130B, the coloring layer 132a, 132b, 132c, a capacitor 240, and a transistor 310. The subpixel 110R illustrated in FIG. 14B includes the light-emitting device 130R and the coloring layer 132a that transmits red light. The subpixel 110G illustrated in FIG. 14B includes the light-emitting device 130G and the coloring layer 132b that transmits green light. The subpixel 110B illustrated in FIG. 14B includes the light-emitting device 130B and the coloring layer 132c that transmits blue light.

The substrate 301 corresponds to the substrate 291 in FIG. 14A and FIG. 14B. A stacked-layer structure from the substrate 301 to the insulating layer 255a corresponds to the substrate 101 including transistors in Embodiment 1.

The transistor 310 is a transistor including a channel formation region in the substrate 301. As the substrate 301, a semiconductor substrate such as a single crystal silicon substrate can be used, for example. The transistor 310 includes part of the substrate 301, a conductive layer 311, low-resistance regions 312, an insulating layer 313, and an insulating layer 314. The conductive layer 311 functions as a gate electrode. The insulating layer 313 is positioned between the substrate 301 and the conductive layer 311 and functions as a gate insulating layer. The low-resistance region 312 is a region where the substrate 301 is doped with an impurity, and functions as one of a source and a drain. The insulating layer 314 is provided to cover a side surface of the conductive layer 311 and functions as an insulating layer.

An element isolation layer 315 is provided between two adjacent transistors 310 to be embedded in the substrate 301.

An insulating layer 261 is provided to cover the transistor 310, and the capacitor 240 is provided over the insulating layer 261.

The capacitor 240 includes a conductive layer 241, a conductive layer 245, and an insulating layer 243 positioned therebetween. The conductive layer 241 functions as one electrode of the capacitor 240, the conductive layer 245 functions as the other electrode of the capacitor 240, and the insulating layer 243 functions as a dielectric of the capacitor 240.

The conductive layer 241 is provided over the insulating layer 261 and is embedded in an insulating layer 254. The conductive layer 241 is electrically connected to one of the source and the drain of the transistor 310 through a plug 271 embedded in the insulating layer 261. The insulating layer 243 is provided to cover the conductive layer 241. The conductive layer 245 is provided in a region overlapping with the conductive layer 241 with the insulating layer 243 therebetween.

The insulating layer 255a is provided to cover the capacitor 240, the insulating layer 255b is provided over the insulating layer 255a, and the insulating layer 255c is provided over the insulating layer 255b.

As each of the insulating layer 255a, the insulating layer 255b, and the insulating layer 255c, any of a variety of inorganic insulating films such as an oxide insulating film, a nitride insulating film, an oxynitride insulating film, and a nitride oxide insulating film can be suitably used. As each of the insulating layer 255a and the insulating layer 255c, an oxide insulating film or an oxynitride insulating film, such as a silicon oxide film, a silicon oxynitride film, or an aluminum oxide film, is preferably used. As the insulating layer 255b, a nitride insulating film or a nitride oxide insulating film, such as a silicon nitride film or a silicon nitride oxide film, is preferably used. Specifically, it is preferable that a silicon oxide film be used as each of the insulating layer 255a and the insulating layer 255c and a silicon nitride film be used as the insulating layer 255b. The insulating layer 255b preferably has a function of an etching protective film. Although this embodiment describes an example in which a depressed portion is provided in the insulating layer 255c, a depressed portion is not necessarily provided in the insulating layer 255c.

The light-emitting device 130R, the light-emitting device 130G, and the light-emitting device 130B are provided over the insulating layer 255c. FIG. 15 illustrates an example where the light-emitting device 130R, the light-emitting device 130G, and the light-emitting device 130B each have the stacked-layer structure illustrated in FIG. 1B.

Since the first layer 113a, the second layer 113b, and the third layer 113c are separated and apart from each other in the display apparatus 100A, generation of crosstalk between adjacent subpixels can be inhibited even when the display apparatus has high resolution. Accordingly, the display apparatus can have high resolution and high display quality.

The fourth layer 113d and an insulator is provided in a region between adjacent light-emitting devices. In FIG. 15 and the like, the fourth layer 113d, the insulating layer 125 over the fourth layer 113d, and the insulating layer 127 over the insulating layer 125 are provided in this region.

The pixel electrode 111a, the pixel electrode 111b, and the pixel electrode 111c of the light-emitting device are each electrically connected to one of the source and the drain of the transistor 310 through a plug 256 embedded in the insulating layer 255a, the insulating layer 255b, and the insulating layer 255c, the conductive layer 241 embedded in the insulating layer 254, and the plug 271 embedded in the insulating layer 261. The top surface of the insulating layer 255c and the top surface of the plug 256 are level or substantially level with each other. A variety of conductive materials can be used for the plugs.

Here, like the pixel electrode 111 illustrated in FIG. 1B and the like, the pixel electrode 111a, the pixel electrode 111b, and the pixel electrode 111c each preferably have a sufficiently large level difference from the depressed portion provided in the insulating layer 255c. With such a structure, the first layer 113a, the second layer 113b, the third layer 113c, and the fourth layer 113d can be separated from each other in a self-aligned manner in the formation of the EL film.

The protective layer 131 is provided over the light-emitting device 130R, the light-emitting device 130G, and the light-emitting device 130B. The resin layer 147, the coloring layer 132a, the coloring layer 132b, and the coloring layer 132c are provided over the protective layer 131. Here, light R emitted from the light-emitting device 130R passes through the coloring layer 132a and is emitted toward the substrate 102 side. Light G emitted from the light-emitting device 130G passes through the coloring layer 132b and is emitted toward the substrate 102 side. Light B emitted from the light-emitting device 130B passes through the coloring layer 132c and is emitted toward the substrate 102 side. The substrate 102 is bonded to the coloring layer 132 with the adhesive layer 107. Embodiment 1 can be referred to for the details of the light-emitting devices and the components thereover up to the substrate 102. The substrate 102 corresponds to the substrate 292 in FIG. 14A.

An insulating layer covering the end portion of the top surface of the pixel electrode 111a is not provided between the pixel electrode 111a and the first layer 113a. An insulating layer covering the end portion of the top surface of the pixel electrode 111b is not provided between the pixel electrode 111b and the second layer 113b. Thus, the distance between adjacent light-emitting devices can be extremely shortened. Accordingly, the display apparatus can have high resolution or high definition.

### [Display Apparatus 100B]

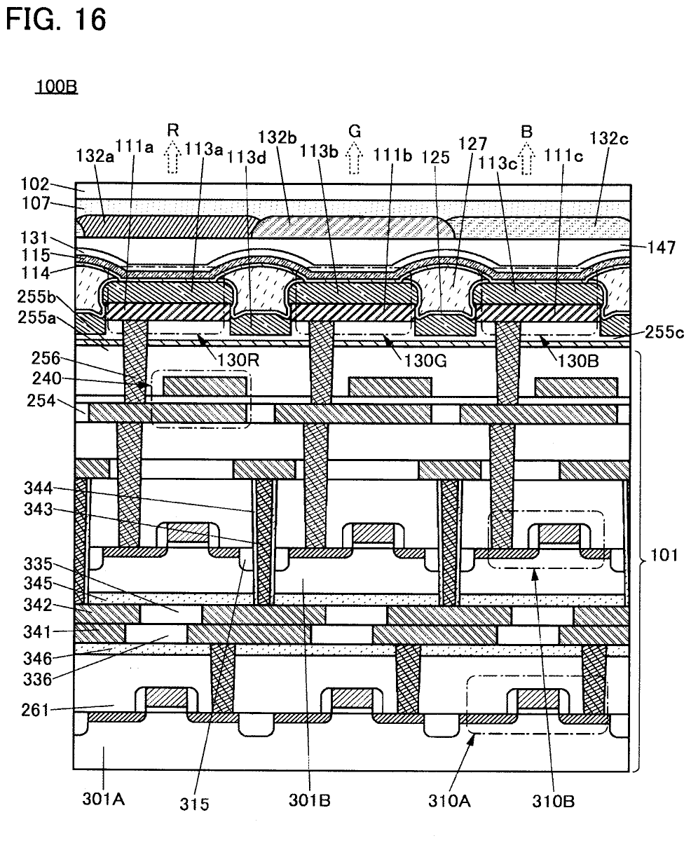

The display apparatus 100B illustrated in FIG. 16 has a structure where a transistor 310A and a transistor 310B in each of which a channel is formed in a semiconductor substrate are stacked. Note that in the description of the display apparatus below, portions similar to those of the above-described display apparatus are not described in some cases.

In the display apparatus 100B, a substrate 301B provided with the transistor 310B, the capacitor 240, and the light-emitting devices is bonded to a substrate 301A provided with the transistor 310A.

Here, an insulating layer 345 is preferably provided on the bottom surface of the substrate 301B. An insulating layer 346 is preferably provided over the insulating layer 261 provided over the substrate 301A. The insulating layers 345 and 346 are insulating layers functioning as protective layers and can inhibit diffusion of impurities into the substrate 301B and the substrate 301A. For the insulating layers 345 and 346, an inorganic insulating film that can be used for the protective layer 131 or an insulating layer 332 can be used.

The substrate 301B is provided with a plug 343 that penetrates the substrate 301B and the insulating layer 345. An insulating layer 344 is preferably provided to cover a side surface of the plug 343. The insulating layer 344 is an insulating layer functioning as a protective layer and can inhibit diffusion of impurities into the substrate 301B. For the insulating layer 344, an inorganic insulating film that can be used for the protective layer 131 can be used.

A conductive layer 342 is provided under the insulating layer 345 on the rear surface of the substrate 301B (the surface opposite to the substrate 102). The conductive layer 342 is preferably provided to be embedded in an insulating layer 335. The bottom surfaces of the conductive layer 342 and the insulating layer 335 are preferably planarized. Here, the conductive layer 342 is electrically connected to the plug 343.

Over the substrate 301A, a conductive layer 341 is provided over the insulating layer 346. The conductive layer 341 is preferably provided to be embedded in an insulating layer 336. The top surfaces of the conductive layer 341 and the insulating layer 336 are preferably planarized.

The conductive layer 341 and the conductive layer 342 are bonded to each other, whereby the substrate 301A and the substrate 301B are electrically connected to each other. Here, improving the flatness of a plane formed by the conductive layer 342 and the insulating layer 335 and a plane formed by the conductive layer 341 and the insulating layer 336 allows the conductive layer 341 and the conductive layer 342 to be bonded to each other favorably.

The conductive layer 341 and the conductive layer 342 are preferably formed using the same conductive material. For example, a metal film containing an element selected from Al, Cr, Cu, Ta, Ti, Mo, and W, a metal nitride film containing the above element as a component (a titanium nitride film, a molybdenum nitride film, or a tungsten nitride film), or the like can be used. Copper is particularly preferably used for the conductive layer 341 and the conductive layer 342. In that case, it is possible to employ Cu-to-Cu (copper-to-copper) direct bonding technique (a technique for achieving electrical continuity by connecting Cu (copper) pads).

### [Display Apparatus 100C]

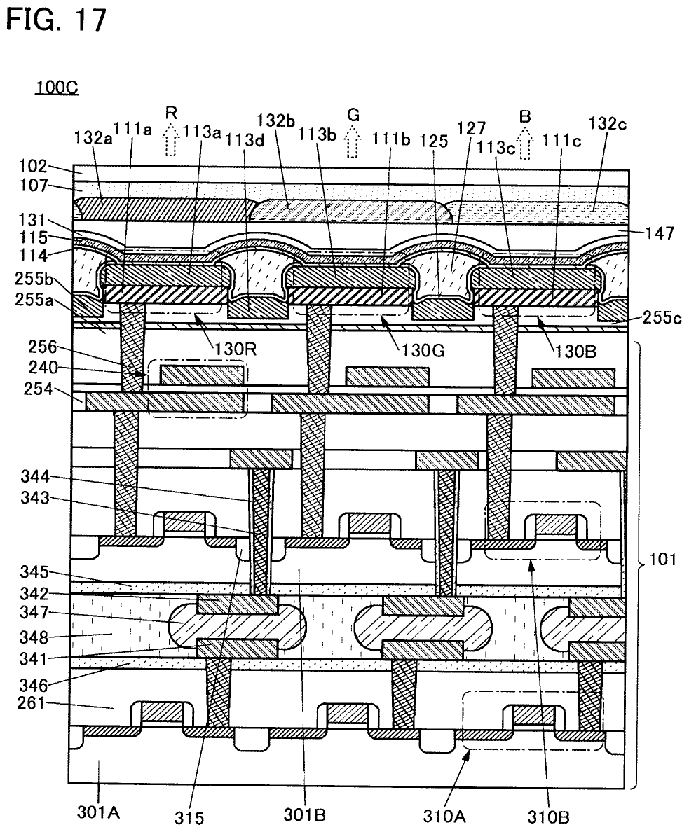

The display apparatus 100C illustrated in FIG. 17 has a structure where the conductive layer 341 and the conductive layer 342 are bonded to each other through a bump 347.

As illustrated in FIG. 17, providing the bump 347 between the conductive layer 341 and the conductive layer 342 enables the conductive layer 341 and the conductive layer 342 to be electrically connected to each other. The bump 347 can be formed using a conductive material containing gold (Au), nickel (Ni), indium (In), tin (Sn), or the like, for example. As another example, solder may be used for the bump 347. An adhesive layer 348 may be provided between the insulating layer 345 and the insulating layer 346. In the case where the bump 347 is provided, the insulating layer 345 and the insulating layer 346 may be omitted.

### [Display Apparatus 100D]

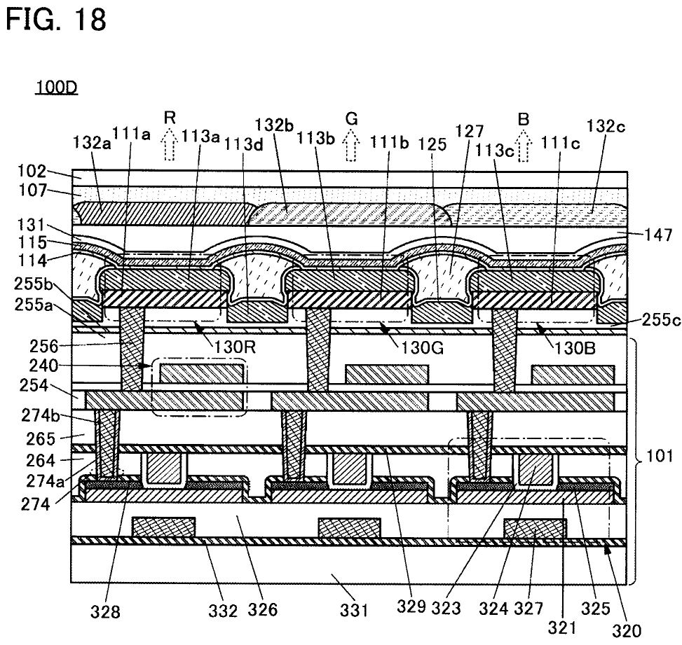

The display apparatus 100D illustrated in FIG. 18 differs from the display apparatus 100A mainly in a structure of a transistor.

A transistor 320 is a transistor that contains a metal oxide (also referred to as an oxide semiconductor) in a semiconductor layer where a channel is formed (i.e., an OS transistor).

The transistor 320 includes a semiconductor layer 321, an insulating layer 323, a conductive layer 324, a pair of conductive layers 325, an insulating layer 326, and a conductive layer 327.

A substrate 331 corresponds to the substrate 291 in FIG. 14A and FIG. 14B. A stacked-layer structure from the substrate 331 to the insulating layer 255b corresponds to the substrate 101 including transistors in Embodiment 1. As the substrate 331, an insulating substrate or a semiconductor substrate can be used.

The insulating layer 332 is provided over the substrate 331. The insulating layer 332 functions as a barrier layer that prevents diffusion of impurities such as water and hydrogen from the substrate 331 into the transistor 320 and release of oxygen from the semiconductor layer 321 to the insulating layer 332 side. As the insulating layer 332, for example, a film in which hydrogen or oxygen is less likely to diffuse than in a silicon oxide film, such as an aluminum oxide film, a hafnium oxide film, or a silicon nitride film, can be used.

The conductive layer 327 is provided over the insulating layer 332, and the insulating layer 326 is provided to cover the conductive layer 327. The conductive layer 327 functions as a first gate electrode of the transistor 320, and part of the insulating layer 326 functions as a first gate insulating layer. An oxide insulating film such as a silicon oxide film is preferably used as at least part of the insulating layer 326 that is in contact with the semiconductor layer 321. The top surface of the insulating layer 326 is preferably planarized.

The semiconductor layer 321 is provided over the insulating layer 326. The semiconductor layer 321 preferably includes a metal oxide (also referred to as an oxide semiconductor) film having semiconductor characteristics. The pair of conductive layers 325 are provided over and in contact with the semiconductor layer 321 and function as a source electrode and a drain electrode.

An insulating layer 328 is provided to cover the top and side surfaces of the pair of conductive layers 325, a side surface of the semiconductor layer 321, and the like, and an insulating layer 264 is provided over the insulating layer 328. The insulating layer 328 functions as a barrier layer that prevents diffusion of impurities such as water and hydrogen from the insulating layer 264 and the like into the semiconductor layer 321 and release of oxygen from the semiconductor layer 321. As the insulating layer 328, an insulating film similar to the insulating layer 332 can be used.

An opening reaching the semiconductor layer 321 is provided in the insulating layer 328 and the insulating layer 264. The insulating layer 323 that is in contact with the side surfaces of the insulating layer 264, the insulating layer 328, and the conductive layer 325, and the top surface of the semiconductor layer 321, and the conductive layer 324 are embedded in the opening. The conductive layer 324 functions as a second gate electrode, and the insulating layer 323 functions as a second gate insulating layer.

The top surface of the conductive layer 324, the top surface of the insulating layer 323, and the top surface of the insulating layer 264 are subjected to planarization treatment to be level or substantially level with each other, and an insulating layer 329 and an insulating layer 265 are provided to cover these layers.

The insulating layer 264 and the insulating layer 265 each function as an interlayer insulating layer. The insulating layer 329 functions as a barrier layer that prevents diffusion of impurities such as water and hydrogen from the insulating layer 265 and the like into the transistor 320. As the insulating layer 329, an insulating film similar to the insulating layer 328 and the insulating layer 332 can be used.

A plug 274 electrically connected to one of the pair of conductive layers 325 is provided so as to be embedded in the insulating layer 265, the insulating layer 329, and the insulating layer 264. Here, the plug 274 preferably includes a conductive layer 274a that covers the side surface of an opening in the insulating layer 265, the insulating layer 329, the insulating layer 264, and the insulating layer 328 and part of the top surface of the conductive layer 325, and a conductive layer 274b in contact with the top surface of the conductive layer 274a. In this case, a conductive material in which hydrogen and oxygen are less likely to diffuse is preferably used for the conductive layer 274a.

### [Display Apparatus 100E]

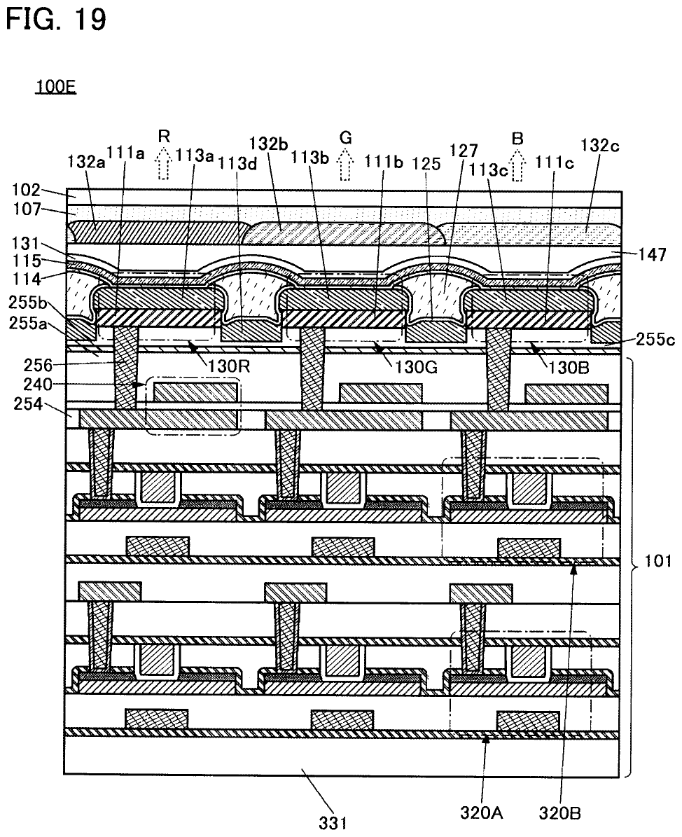

The display apparatus 100E illustrated in FIG. 19 has a structure in which a transistor 320A and a transistor 320B each including an oxide semiconductor in a semiconductor where a channel is formed are stacked.

The display apparatus 100D can be referred to for the transistor 320A, the transistor 320B, and the components around them.

Although the structure where two transistors each including an oxide semiconductor are stacked is described, the present invention is not limited thereto. For example, three or more transistors may be stacked.

### [Display Apparatus 100F]

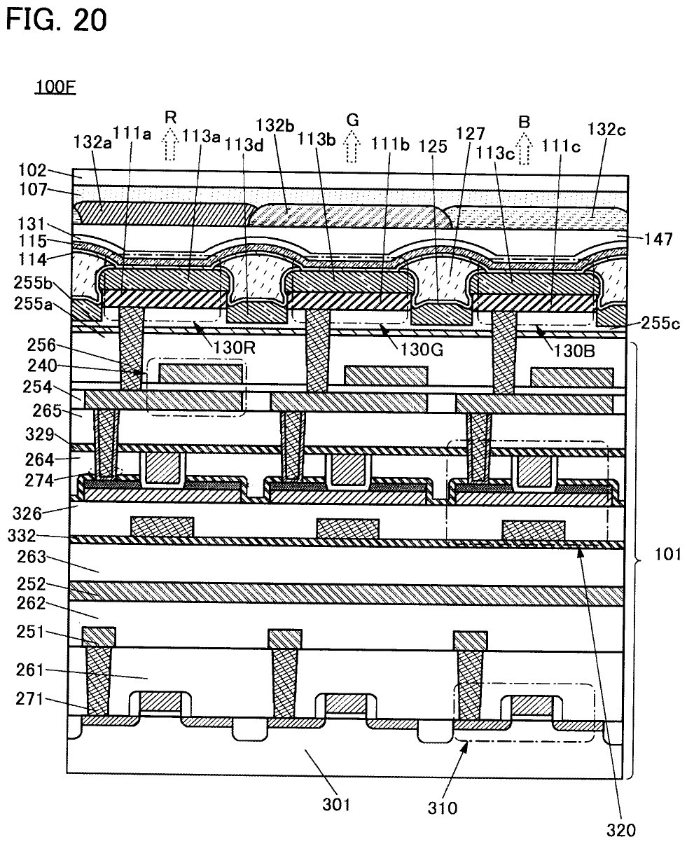

The display apparatus 100F illustrated in FIG. 20 has a structure in which the transistor 310 whose channel is formed in the substrate 301 and the transistor 320 including a metal oxide in the semiconductor layer where the channel is formed are stacked.

The insulating layer 261 is provided to cover the transistor 310, and a conductive layer 251 is provided over the insulating layer 261. An insulating layer 262 is provided to cover the conductive layer 251, and a conductive layer 252 is provided over the insulating layer 262. The conductive layer 251 and the conductive layer 252 each function as a wiring. An insulating layer 263 and the insulating layer 332 are provided to cover the conductive layer 252, and the transistor 320 is provided over the insulating layer 332. The insulating layer 265 is provided to cover the transistor 320, and the capacitor 240 is provided over the insulating layer 265. The capacitor 240 and the transistor 320 are electrically connected to each other through the plug 274.

The transistor 320 can be used as a transistor included in the pixel circuit. The transistor 310 can be used as a transistor included in the pixel circuit or a transistor included in a driver circuit (a gate line driver circuit or a source line driver circuit) for driving the pixel circuit. The transistor 310 and the transistor 320 can also be used as transistors included in a variety of circuits such as an arithmetic circuit and a memory circuit.

With such a structure, not only the pixel circuit but also the driver circuit and the like can be formed directly under the light-emitting devices; thus, the display apparatus can be downsized as compared with the case where a driver circuit is provided around a display region.

### [Display Apparatus 100G]

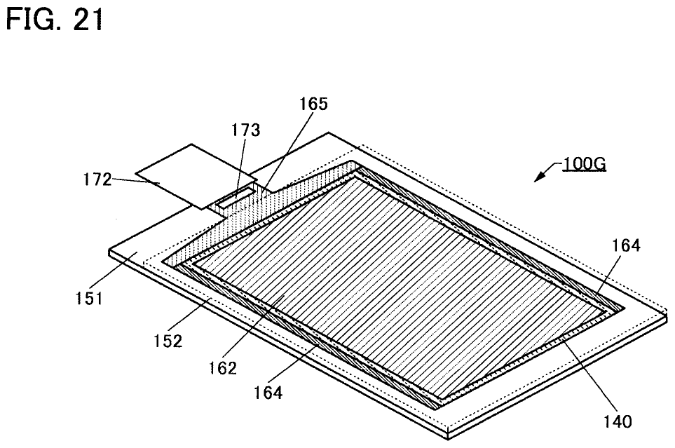

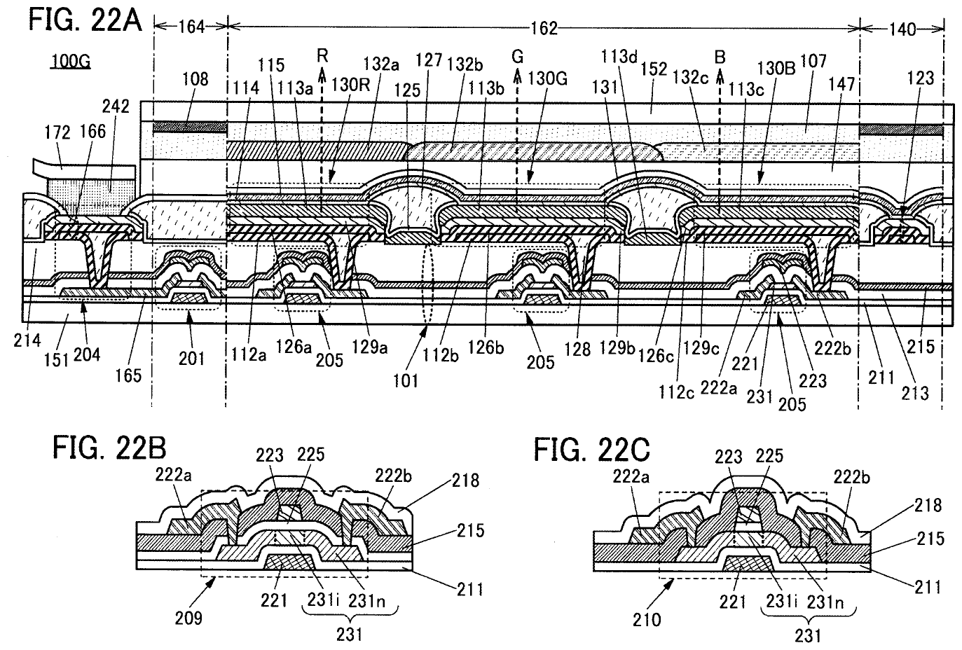

FIG. 21 is a perspective view of the display apparatus 100G, and FIG. 22A is a cross-sectional view of the display apparatus 100G.

In the display apparatus 100G, a substrate 152 and a substrate 151 are bonded to each other. In FIG. 21, the substrate 152 is denoted by a dashed line

The display apparatus 100G includes a display portion 162, the connection portion 140, a circuit 164, a wiring 165, and the like. FIG. 21 illustrates an example where an IC 173 and an FPC 172 are mounted on the display apparatus 100G. Thus, the structure illustrated in FIG. 21 can be regarded as a display module including the display apparatus 100G, the IC (integrated circuit), and the FPC.

The connection portion 140 is provided outside the display portion 162. The connection portion 140 can be provided along one or more sides of the display portion 162. The number of connection portions 140 can be one or more. FIG. 21 illustrates an example where the connection portion 140 is provided to surround the four sides of the display portion. A common electrode of a light-emitting device is electrically connected to a conductive layer in the connection portion 140, so that a potential can be supplied to the common electrode.

As the circuit 164, a scan line driver circuit can be used, for example.

The wiring 165 has a function of supplying a signal and power to the display portion 162 and the circuits 164. The signal and power are input to the wiring 165 from the outside through the FPC 172 or input to the wiring 165 from the IC 173.

FIG. 21 illustrates an example where the IC 173 is provided over the substrate 151 by a COG (Chip On Glass) method, a COF (Chip On Film) method, or the like. An IC including a scan line driver circuit, a signal line driver circuit, or the like can be used as the IC 173, for example. Note that the display apparatus 100G and the display module are not necessarily provided with an IC. The IC may be mounted on the FPC by a COF method or the like.

FIG. 22A illustrates an example of cross sections of part of a region including the FPC 172, part of the circuit 164, part of the display portion 162, part of the connection portion 140, and part of a region including an end portion of the display apparatus 100G.

The display apparatus 100G illustrated in FIG. 22A includes a transistor 201, a transistor 205, the light-emitting device 130R, the light-emitting device 130G, the light-emitting device 130B, the coloring layer 132a transmitting red light, the coloring layer 132b transmitting green light, the coloring layer 132c transmitting blue light, and the like between the substrate 151 and the substrate 152.

The stacked-layer structure of each of the light-emitting devices 130R, 130G, and 130B is the same as that illustrated in FIG. 1B except for the structure of the pixel electrode. Embodiment 1 and the like can be referred to for the details of the light-emitting devices. For example, the light-emitting device 130R, the light-emitting device 130G, and the light-emitting device 130B correspond to the light-emitting device 130a, the light-emitting device 130b, and the light-emitting device 130c, respectively, illustrated in FIG. 1B.

Since the first layer 113a, the second layer 113b, and the third layer 113c are separated and apart from each other in the display apparatus 100G, generation of crosstalk between adjacent subpixels can be inhibited even when the display apparatus 100G has high resolution. Accordingly, the display apparatus can have high resolution and high display quality.

The light-emitting device 130R includes a conductive layer 112a provided over at least part of an insulating layer 214, a conductive layer 126a over the conductive layer 112a, and a conductive layer 129a over the conductive layer 126a. Here, the insulating layer 214 corresponds to the insulating layer 255c illustrated in FIG. 1B and the like. All of the conductive layers 112a, 126a, and 129a can be referred to as pixel electrodes, or one or two of them can be referred to as pixel electrodes. Like the pixel electrode 111 illustrated in FIG. 1B and the like, the pixel electrode preferably has a sufficiently large level difference from a depressed portion provided in an upper portion of the insulating layer 214.

The light-emitting device 130G includes a conductive layer 112b provided over at least part of the insulating layer 214, a conductive layer 126b over the conductive layer 112b, and a conductive layer 129b over the conductive layer 126b.

The light-emitting device 130B includes a conductive layer 112c provided over at least part of the insulating layer 214, a conductive layer 126c over the conductive layer 112c, and a conductive layer 129c over the conductive layer 126c.

The conductive layer 112a is connected to a conductive layer 222b included in the transistor 205 through an opening provided in the insulating layer 214. An end portion of the conductive layer 126a is positioned outward from an end portion of the conductive layer 112a. The end portion of the conductive layer 126a and an end portion of the conductive layer 129a are aligned or substantially aligned with each other. For example, a conductive layer functioning as a reflective electrode can be used as the conductive layer 112a and the conductive layer 126a, and a conductive layer functioning as a transparent electrode can be used as the conductive layer 129a.

Detailed description of the conductive layers 112b, 126b, and 129b of the light-emitting device 130G and the conductive layers 112c, 126c, and 129c of the light-emitting device 130B is omitted because these conductive layers are similar to the conductive layers 112a, 126a, and 129a of the light-emitting device 130R.

Depressed portions are formed in the conductive layers 112a, 112b, and 112c to cover the openings provided in the insulating layer 214. A layer 128 is embedded in the depressed portions.

The layer 128 has a planarization function for the depressed portions of the conductive layers 112a, 112b, and 112c. The conductive layers 126a, 126b, and 126c electrically connected to the conductive layers 112a, 112b, and 112c, respectively, are provided over the conductive layers 112a, 112b, and 112c and the layer 128. Thus, regions overlapping with the depressed portions of the conductive layers 112a, 112b, and 112c can also be used as the light-emitting regions, increasing the aperture ratio of the pixels.

The layer 128 may be an insulating layer or a conductive layer. Any of a variety of inorganic insulating materials, organic insulating materials, and conductive materials can be used for the layer 128 as appropriate. In particular, the layer 128 is preferably formed using an insulating material.

An insulating layer containing an organic material can be suitably used for the layer 128. For example, an acrylic resin, a polyimide resin, an epoxy resin, a polyamide resin, a polyimide-amide resin, a siloxane resin, a benzocyclobutene-based resin, a phenol resin, a precursor of any of these resins, or the like can be used for the layer 128. A photosensitive resin can also be used for the layer 128. As the photosensitive resin, a positive photosensitive material or a negative photosensitive material can be used.

When a photosensitive resin is used, the layer 128 can be formed through only light exposure and development processes, reducing the influence of dry etching, wet etching, or the like on the surfaces of the conductive layers 112a, 112b, and 112c. When the layer 128 is formed using a negative photosensitive resin, the layer 128 can sometimes be formed using the same photomask (light exposure mask) as the photomask used for forming the opening in the insulating layer 214.

The top surface of the conductive layer 126a and the top surface of the conductive layer 129a are covered with the first layer 113a. Similarly, the top surface of the conductive layer 126b and the top surface of the conductive layer 129b are covered with the second layer 113b. Moreover, the top surface of the conductive layer 126c and the top surface of the conductive layer 129c are covered with the third layer 113c. Accordingly, regions provided with the conductive layers 126a, 126b, and 126c can be entirely used as the light-emitting regions of the light-emitting devices 130R, 130G, and 130B, increasing the aperture ratio of the pixels.

As in the display apparatus 100 illustrated in FIG. 1B, the fourth layer 113d is formed between adjacent light-emitting devices, and the insulating layer 125 and the insulating layer 127 are provided over the fourth layer 113d. When the depressed portion provided above the pixel electrode and the insulating layer 214 has a sufficiently large level difference, the first layer 113a, the second layer 113b, the third layer 113c, and the fourth layer 113d can be separated from each other in a self-aligned manner in the formation of the EL film.

The side surfaces of the first layer 113a, the second layer 113b, and the third layer 113c are covered with the insulating layers 125 and 127. The common layer 114 is provided over the first layer 113a, the second layer 113b, the third layer 113c, and the insulating layers 125 and 127. The common electrode 115 is provided over the common layer 114. The common layer 114 and the common electrode 115 are each one continuous film shared by the plurality of light-emitting devices.

The protective layer 131 is provided over each of the light-emitting devices 130R, 130G, and 130B. The protective layer 131 covering the light-emitting devices can inhibit an impurity such as water from entering the light-emitting devices, and increase the reliability of the light-emitting devices.

Like the display apparatus 100 illustrated in FIG. 1B, the display apparatus 100G includes the resin layer 147, the coloring layer 132a, the coloring layer 132b, and the coloring layer 132c over the protective layer 131. Here, the light R emitted from the light-emitting device 130R passes through the coloring layer 132a and is emitted toward the substrate 152 side. The light G emitted from the light-emitting device 130G passes through the coloring layer 132b and is emitted toward the substrate 152 side. The light B emitted from the light-emitting device 130B passes through the coloring layer 132c and is emitted toward the substrate 152 side.

The protective layer 131 and the substrate 152 are attached to each other with an adhesive layer 107. A solid sealing structure, a hollow sealing structure, or the like can be employed to seal the light-emitting devices. In FIG. 22A, a solid sealing structure is employed in which a space between the substrate 152 and the substrate 151 is filled with the adhesive layer 107. Alternatively, a hollow sealing structure in which the space is filled with an inert gas (e.g., nitrogen or argon) may be employed. Here, the adhesive layer 107 may be provided not to overlap with the light-emitting devices. The space may be filled with a resin other than the frame-shaped adhesive layer 107.

The conductive layer 123 is provided over the insulating layer 214 in the connection portion 140. An example is described in which the conductive layer 123 has a stacked-layer structure of a conductive film obtained by processing the same conductive film as the conductive layers 112a, 112b, and 112c; a conductive film obtained by processing the same conductive film as the conductive layers 126a, 126b, and 126c; and a conductive film obtained by processing the same conductive film as the conductive layers 129a, 129b, and 129c. An end portion of the conductive layer 123 is covered with the insulating layer 125 and the insulating layer 127. The common layer 114 is provided over the conductive layer 123, and the common electrode 115 is provided over the common layer 114. The conductive layer 123 and the common electrode 115 are electrically connected to each other through the common layer 114. Note that the common layer 114 is not necessarily formed in the connection portion 140. In this case, the conductive layer 123 and the common electrode 115 are directly in contact with each other to be electrically connected to each other.

The display apparatus 100G has a top-emission structure. Light emitted by the light-emitting device is emitted toward the substrate 152. For the substrate 152, a material having a high property of transmitting visible light is preferably used. The pixel electrode contains a material reflecting visible light, and a counter electrode (the common electrode 115) contains a material transmitting visible light.

A stacked-layer structure from the substrate 151 to the insulating layer 214 corresponds to the substrate 101 including transistors in Embodiment 1.

The transistor 201 and the transistor 205 are formed over the substrate 151. These transistors can be fabricated using the same material in the same step.

An insulating layer 211, an insulating layer 213, an insulating layer 215, and the insulating layer 214 are provided in this order over the substrate 151. Part of the insulating layer 211 functions as a gate insulating layer of each transistor. Part of the insulating layer 213 functions as a gate insulating layer of each transistor. The insulating layer 215 is provided to cover the transistors. The insulating layer 214 is provided to cover the transistors and has a function of a planarization layer. Note that the number of gate insulating layers and the number of insulating layers covering the transistors are not limited and may each be one or two or more.

A material in which impurities such as water and hydrogen are less likely to diffuse is preferably used for at least one of the insulating layers covering the transistors. This allows the insulating layer to function as a barrier layer. Such a structure can effectively inhibit diffusion of impurities into the transistors from the outside and increase the reliability of a display apparatus.

An inorganic insulating film is preferably used as each of the insulating layer 211, the insulating layer 213, and the insulating layer 215. As the inorganic insulating film, a silicon nitride film, a silicon oxynitride film, a silicon oxide film, a silicon nitride oxide film, an aluminum oxide film, or an aluminum nitride film can be used, for example. A hafnium oxide film, an yttrium oxide film, a zirconium oxide film, a gallium oxide film, a tantalum oxide film, a magnesium oxide film, a lanthanum oxide film, a cerium oxide film, a neodymium oxide film, or the like may be used. A stack including two or more of the above insulating films may also be used.

An organic insulating layer is suitable as the insulating layer 214 functioning as a planarization layer. Examples of materials that can be used for the organic insulating layer include an acrylic resin, a polyimide resin, an epoxy resin, a polyamide resin, a polyimide-amide resin, a siloxane resin, a benzocyclobutene-based resin, a phenol resin, and precursors of these resins. The insulating layer 214 may have a stacked-layer structure of an organic insulating layer and an inorganic insulating layer. The outermost layer of the insulating layer 214 preferably has a function of an etching protective layer. Accordingly, a depressed portion can be inhibited from being formed in the insulating layer 214 in processing the conductive layer 112a, the conductive layer 126a, the conductive layer 129a, or the like. Alternatively, a depressed portion may be provided in the insulating layer 214 in processing the conductive layer 112a, the conductive layer 126a, the conductive layer 129a, or the like.

Each of the transistor 201 and the transistor 205 includes a conductive layer 221 functioning as a gate, the insulating layer 211 functioning as a gate insulating layer, a conductive layer 222a and the conductive layer 222b functioning as a source and a drain, a semiconductor layer 231, the insulating layer 213 functioning as a gate insulating layer, and a conductive layer 223 functioning as a gate. Here, a plurality of layers obtained by processing the same conductive film are shown with the same hatching pattern. The insulating layer 211 is positioned between the conductive layer 221 and the semiconductor layer 231. The insulating layer 213 is positioned between the conductive layer 223 and the semiconductor layer 231.

There is no particular limitation on the structure of the transistors included in the display apparatus of this embodiment. For example, a planar transistor, a staggered transistor, an inverted staggered transistor, or the like can be used. A top-gate or a bottom-gate transistor structure may be employed. Alternatively, gates may be provided above and below the semiconductor layer where a channel is formed.

The structure where the semiconductor layer where a channel is formed is provided between two gates is used for the transistor 201 and the transistor 205. The two gates may be connected to each other and supplied with the same signal to drive the transistor. Alternatively, a potential for controlling the threshold voltage may be supplied to one of the two gates and a potential for driving may be supplied to the other to control the threshold voltage of the transistor.

There is no particular limitation on the crystallinity of a semiconductor material used for the transistors, and any of an amorphous semiconductor, a single crystal semiconductor, and a semiconductor having crystallinity other than single crystal (a microcrystalline semiconductor, a polycrystalline semiconductor, or a semiconductor partly including crystal regions) may be used. It is preferable to use a single crystal semiconductor or a semiconductor having crystallinity, in which case deterioration of the transistor characteristics can be inhibited.

The semiconductor layer of the transistor preferably includes a metal oxide (also referred to as an oxide semiconductor). That is, a transistor including a metal oxide in its channel formation region (hereinafter, also referred to as an OS transistor) is preferably used for the display apparatus of this embodiment.

As the oxide semiconductor having crystallinity, a CAAC (c-axis aligned crystalline)-OS, an nc (nanocrystalline)-OS, and the like can be given.

Alternatively, a transistor using silicon in its channel formation region (a Si transistor) may be used. As silicon, single crystal silicon, polycrystalline silicon, amorphous silicon, and the like can be given. In particular, a transistor containing low-temperature polysilicon (LTPS) in its semiconductor layer (hereinafter also referred to as an LTPS transistor) can be used. The LTPS transistor has high field-effect mobility and favorable frequency characteristics.

With the use of Si transistors such as LTPS transistors, a circuit required to be driven at a high frequency (e.g., a source driver circuit) can be formed on the same substrate as the display portion. Thus, external circuits mounted on the display apparatus can be simplified, whereby component cost and mounting cost can be reduced.

An OS transistor has extremely higher field-effect mobility than a transistor containing amorphous silicon. In addition, the OS transistor has extremely low leakage current between a source and a drain in an off state (hereinafter, also referred to as off-state current), and charge accumulated in a capacitor that is connected in series to the transistor can be retained for a long period. Furthermore, power consumption of the display apparatus can be reduced with the use of an OS transistor.

The off-state current value per micrometer of channel width of the OS transistor at room temperature can be lower than or equal to 1 aA (1×10⁻¹⁸ A), lower than or equal to 1 zA (1×10⁻²¹ A), or lower than or equal to 1 yA (1×10⁻²⁴ A). Note that the off-state current value per micrometer of channel width of a Si transistor at room temperature is higher than or equal to 1 fA (1×10⁻¹⁵ A) and lower than or equal to 1 pA (1×10⁻¹² A). In other words, the off-state current of an OS transistor is lower than that of a Si transistor by approximately ten orders of magnitude.

To increase the emission luminance of the light-emitting device included in the pixel circuit, the amount of current fed through the light-emitting device needs to be increased. For this, it is necessary to increase the source-drain voltage of a driving transistor included in the pixel circuit. Since an OS transistor has a higher withstand voltage between the source and the drain than a Si transistor, a high voltage can be applied between the source and the drain of the OS transistor. Accordingly, when an OS transistor is used as the driving transistor included in the pixel circuit, the amount of current flowing through the light-emitting device can be increased, so that the emission luminance of the light-emitting device can be increased.

When transistors operate in a saturation region, a change in source-drain current with respect to a change in gate-source voltage can be smaller in an OS transistor than in a Si transistor. Accordingly, when an OS transistor is used as the driving transistor in the pixel circuit, the amount of current flowing between the source and the drain can be set minutely by a change in gate-source voltage; hence, the amount of current flowing through the light-emitting device can be controlled. Accordingly, the number of gray levels in the pixel circuit can be increased.

Regarding saturation characteristics of current flowing when transistors operate in a saturation region, even in the case where the source-drain voltage of an OS transistor increases gradually, a more stable current (saturation current) can be fed through the OS transistor than through a Si transistor. Thus, by using an OS transistor as the driving transistor, a stable current can be fed through light-emitting devices even when the current-voltage characteristics of the EL devices vary, for example. In other words, when the OS transistor operates in the saturation region, the source-drain current hardly changes with an increase in the source-drain voltage; hence, the emission luminance of the light-emitting device can be stable.

As described above, with the use of an OS transistor as a driving transistor included in the pixel circuit, it is possible to achieve “inhibition of black floating”, “increase in emission luminance”, “increase in the number of gray levels”, “inhibition of variation in light-emitting devices”, and the like.

The semiconductor layer preferably contains indium, M (M is one or more selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, and magnesium), and zinc, for example. Specifically, M is preferably one or more selected from aluminum, gallium, yttrium, and tin.

It is particularly preferable that an oxide containing indium (In), gallium (Ga), and zinc (Zn) (also referred to as IGZO) be used for the semiconductor layer. Alternatively, it is preferable to use an oxide containing indium, tin, and zinc. Further alternatively, it is preferable to use an oxide containing indium, gallium, tin, and zinc. Alternatively, an oxide containing indium (In), aluminum (Al), and zinc (Zn) (also referred to as IAZO) is preferably used. Alternatively, an oxide containing indium (In), aluminum (Al), gallium (Ga), and zinc (Zn) (also referred to as IAGZO) is preferably used.

When the semiconductor layer is an In-M-Zn oxide, the atomic ratio of In is preferably higher than or equal to the atomic ratio of M in the In-M-Zn oxide. Examples of the atomic ratio of the metal elements in such an In-M-Zn oxide include In:M:Zn=1:1:1 or a composition in the neighborhood thereof, In:M:Zn=1:1:1.2 or a composition in the neighborhood thereof, In:M:Zn=1:3:2 or a composition in the neighborhood thereof, In:M:Zn=1:3:4 or a composition in the neighborhood thereof, In:M:Zn=2:1:3 or a composition in the neighborhood thereof, In:M:Zn=3:1:2 or a composition in the neighborhood thereof, In:M:Zn=4:2:3 or a composition in the neighborhood thereof, In:M:Zn=4:2:4.1 or a composition in the neighborhood thereof, In:M:Zn=5:1:3 or a composition in the neighborhood thereof, In:M:Zn=5:1:6 or a composition in the neighborhood thereof, In:M:Zn=5:1:7 or a composition in the neighborhood thereof, In:M:Zn=5:1:8 or a composition in the neighborhood thereof, In:M:Zn=6:1:6 or a composition in the neighborhood thereof, and In:M:Zn=5:2:5 or a composition in the neighborhood thereof. Note that a composition in the neighborhood includes the range of ±30% of an intended atomic ratio.

For example, when the atomic ratio is described as In:Ga:Zn=4:2:3 or a composition in the neighborhood thereof, the case is included where Ga is greater than or equal to 1 and less than or equal to 3 and Zn is greater than or equal to 2 and less than or equal to 4 with In being 4. When the atomic ratio is described as In:Ga:Zn=5:1:6 or a composition in the neighborhood thereof, the case is included where Ga is greater than 0.1 and less than or equal to 2 and Zn is greater than or equal to 5 and less than or equal to 7 with In being 5. When the atomic ratio is described as In:Ga:Zn=1:1:1 or a composition in the neighborhood thereof, the case is included where Ga is greater than 0.1 and less than or equal to 2 and Zn is greater than 0.1 and less than or equal to 2 with In being 1.

The transistor included in the circuit 164 and the transistor included in the display portion 162 may have the same structure or different structures. One structure or two or more types of structures may be employed for a plurality of transistors included in the circuit 164. Similarly, one structure or two or more types of structures may be employed for a plurality of transistors included in the display portion 162.

All of the transistors included in the display portion 162 may be OS transistors or all of the transistors included in the display portion 162 may be Si transistors; alternatively, some of the transistors included in the display portion 162 may be OS transistors and the others may be Si transistors.

For example, when both an LTPS transistor and an OS transistor are used in the display portion 162, the display apparatus can have low power consumption and high drive capability. Note that a structure where an LTPS transistor and an OS transistor are combined is referred to as LTPO in some cases. Note that as a more preferable example, a structure in which the OS transistor is used as a transistor functioning as a switch controlling conduction or non-conduction between wirings, and the LTPS transistor is used as a transistor controlling current, for example, is preferably employed.

For example, one of the transistors included in the display portion 162 functions as a transistor for controlling current flowing through the light-emitting device and can be referred to as a driving transistor. One of a source and a drain of the driving transistor is electrically connected to the pixel electrode of the light-emitting device. An LTPS transistor is preferably used as the driving transistor. Accordingly, the amount of current flowing through the light-emitting device can be increased in the pixel circuit.

Another transistor included in the display portion 162 functions as a switch for controlling selection and non-selection of the pixel and can be referred to as a selection transistor. A gate of the selection transistor is electrically connected to a gate line, and one of a source and a drain thereof is electrically connected to a source line (signal line). An OS transistor is preferably used as the selection transistor. Accordingly, the gray level of the pixel can be maintained even with an extremely low frame frequency (e.g., lower than or equal to 1 fps); thus, power consumption can be reduced by stopping the driver in displaying a still image.

As described above, the display apparatus of one embodiment of the present invention can have all of a high aperture ratio, high resolution, high display quality, and low power consumption.

Note that the display apparatus of one embodiment of the present invention has a structure including the OS transistor and the light-emitting device having an MML (metal maskless) structure. With this structure, the leakage current that might flow through the transistor and the leakage current that might flow between adjacent light-emitting devices (also referred to as lateral leakage current, side leakage current, or the like) can be extremely low. With the structure, a viewer can notice any one or more of the image crispness, the image sharpness, a high chroma, and a high contrast ratio in an image displayed on the display apparatus. When the leakage current that might flow through the transistor and the lateral leakage current that might flow between light-emitting devices are extremely low, display with little light leakage or the like that might occur in black display can be achieved.

The structure of the OS transistor is not limited to the structure illustrated in FIG. 22A. For example, the structure illustrated in FIG. 22B and FIG. 22C may be employed.

A transistor 209 and a transistor 210 each include the conductive layer 221 functioning as a gate, the insulating layer 211 functioning as a gate insulating layer, the semiconductor layer 231 including a channel formation region 231i and a pair of low-resistance regions 231n, the conductive layer 222a connected to one of the pair of low-resistance regions 231n, the conductive layer 222b connected to the other of the pair of the low-resistance regions 231n, an insulating layer 225 functioning as a gate insulating layer, the conductive layer 223 functioning as a gate, and the insulating layer 215 covering the conductive layer 223. The insulating layer 211 is positioned between the conductive layer 221 and the channel formation region 231i. The insulating layer 225 is positioned at least between the conductive layer 223 and the channel formation region 231i. Furthermore, an insulating layer 218 covering the transistor may be provided.

FIG. 22B illustrates an example of the transistor 209 in which the insulating layer 225 covers the top and side surfaces of the semiconductor layer 231. The conductive layer 222a and the conductive layer 222b are connected to the low-resistance regions 231n through openings provided in the insulating layer 225 and the insulating layer 215. One of the conductive layer 222a and the conductive layer 222b functions as a source, and the other functions as a drain.

Meanwhile, in the transistor 210 illustrated in FIG. 22C, the insulating layer 225 overlaps with the channel formation region 231i of the semiconductor layer 231 and does not overlap with the low-resistance regions 231n. The structure illustrated in FIG. 22C can be formed by processing the insulating layer 225 using the conductive layer 223 as a mask, for example. In FIG. 22C, the insulating layer 215 is provided to cover the insulating layer 225 and the conductive layer 223, and the conductive layer 222a and the conductive layer 222b are connected to the low-resistance regions 231n through the openings in the insulating layer 215.

A connection portion 204 is provided in a region of the substrate 151 where the substrate 152 does not overlap. In the connection portion 204, the wiring 165 is electrically connected to the FPC 172 through a conductive layer 166 and a connection layer 242. An example is illustrated in which the conductive layer 166 has a stacked-layer structure of a conductive film obtained by processing the same conductive film as the conductive layers 112a, 112b, and 112c, a conductive film obtained by processing the same conductive film as the conductive layers 126a, 126b, and 126c, and a conductive film obtained by processing the same conductive film as the conductive layers 129a, 129b, and 129c. The conductive layer 166 is exposed on the top surface of the connection portion 204. Thus, the connection portion 204 and the FPC 172 can be electrically connected to each other through the connection layer 242.

A structure where the light-blocking layer 108 is provided on a surface of the substrate 152 on the substrate 151 side may be employed. The light-blocking layer 108 can be provided between adjacent light-emitting devices, in the connection portion 140, and in the circuit 164, for example. A variety of optical members can be arranged on the outer surface of the substrate 152.

The material that can be used for the substrate 101 and the substrate 102 can be used for each of the substrate 151 and the substrate 152.

As the connection layer 242, an anisotropic conductive film (ACF), an anisotropic conductive paste (ACP), or the like can be used.

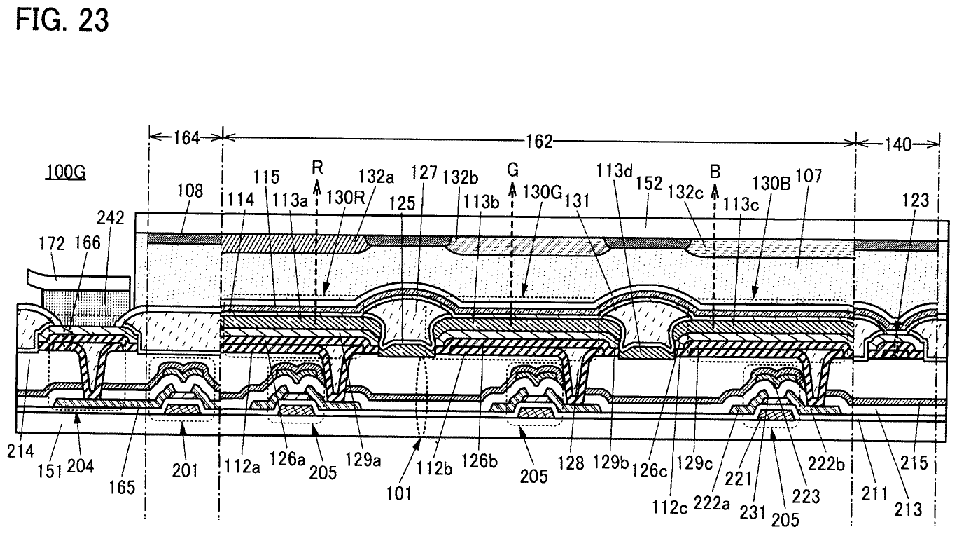

In FIG. 22, the coloring layers 132 are arranged in a manner similar to that in the structure illustrated in FIG. 1B; however, the present invention is not limited thereto, and arrangement of the coloring layers 132 described in the above embodiments can be used as appropriate. For example, as illustrated in FIG. 23, the arrangement of the coloring layers 132 may be similar to the structure illustrated in FIG. 5B. In the display apparatus 100G illustrated in FIG. 23, as in the structure illustrated in FIG. 5B, the light-blocking layer 108, the coloring layer 132a, the coloring layer 132b, and the coloring layer 132c may be provided on the surface of the substrate 152 on the substrate 151 side. Here, end portions of the coloring layers 132a, 132b, and 132c are preferably provided to overlap with the light-blocking layer 108. In this case, the adhesive layer 107 is in contact with the light-blocking layer 108, the coloring layer 132a, the coloring layer 132b, the coloring layer 132c, and the protective layer 131.

### [Display Apparatus 100H]

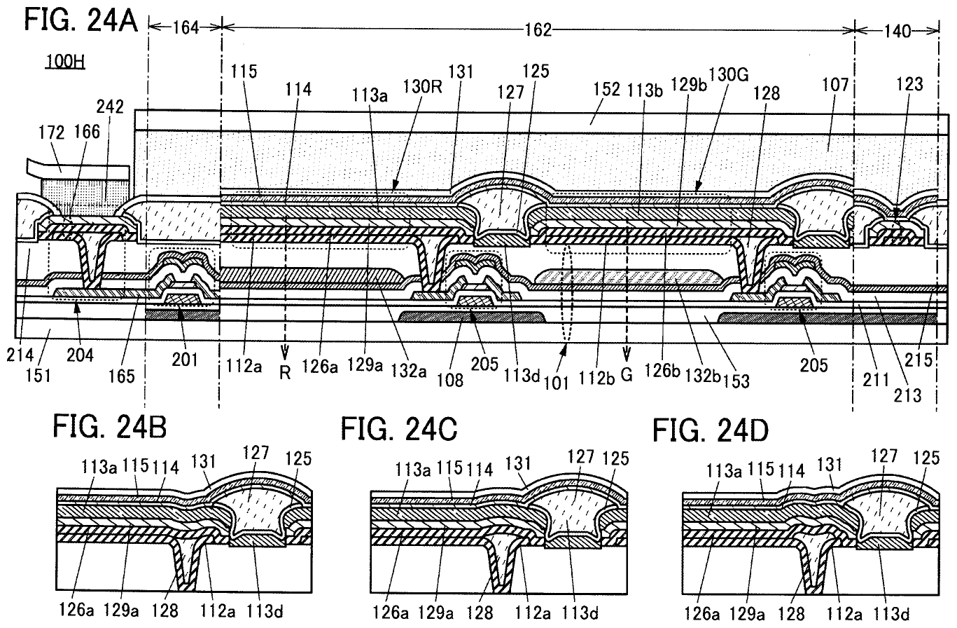

A display apparatus 100H illustrated in FIG. 24A differs from the display apparatus 100G mainly in being a bottom-emission display apparatus. Note that portions similar to those in the display apparatus 100G in FIG. 24A are not described.

Light emitted by the light-emitting device is emitted toward the substrate 151 side. For the substrate 151, a material having a high property of transmitting visible light is preferably used. In contrast, there is no limitation on the light-transmitting property of a material used for the substrate 152.

The light-blocking layer 108 is preferably formed between the substrate 151 and the transistor 201 and between the substrate 151 and the transistor 205. FIG. 24A illustrates an example in which the light-blocking layer 108 is provided over the substrate 151, an insulating layer 153 is provided over the light-blocking layer 108, and the transistors 201 and 205 and the like are provided over the insulating layer 153.

The coloring layer 132 is provided between the insulating layer 215 and the insulating layer 214. The end portion of the coloring layer 132 preferably overlaps with the light-blocking layer 108. The coloring layer 132a is provided to overlap with the light-emitting device 130R, and the coloring layer 132b is provided to overlap with the light-emitting device 130G. Note that although the light-emitting device 130B and the coloring layer 132c are omitted in FIG. 24A, the light-emitting device 130B and the coloring layer 132c can be provided in a manner similar to that of the light-emitting device 130R and the coloring layer 132a, and the like.

The light-emitting device 130R includes the conductive layer 112a, the conductive layer 126a over the conductive layer 112a, and the conductive layer 129a over the conductive layer 126a.

The light-emitting device 130G includes the conductive layer 112b, the conductive layer 126b over the conductive layer 112b, and the conductive layer 129b over the conductive layer 126b.

A material having a high property of transmitting visible light is used for each of the conductive layers 112a, 112b, 112c, 126a, 126b, 126c, 129a, 129b, and 129c. A material reflecting visible light is preferably used for the common electrode 115.

Although FIG. 22A, FIG. 24A, and the like illustrate an example where the top surface of the layer 128 includes a flat portion, the shape of the layer 128 is not particularly limited. FIG. 24B to FIG. 24D illustrate variation examples of the layer 128.

As illustrated in FIG. 24B and FIG. 24D, the top surface of the layer 128 can have a shape such that its center and the vicinity thereof are depressed, i.e., a shape including a concave surface, in a cross-sectional view.

As illustrated in FIG. 24C, the top surface of the layer 128 can have a shape such that its center and the vicinity thereof bulge, i.e., a shape including a convex surface, in a cross-sectional view.

The top surface of the layer 128 may include one or both of a convex surface and a concave surface. The number of convex surfaces and the number of concave surfaces included in the top surface of the layer 128 are not limited and can each be one or more.

The level of the top surface of the layer 128 and the level of the top surface of the conductive layer 112a may be equal to or substantially equal to each other, or may be different from each other. For example, the level of the top surface of the layer 128 may be either lower or higher than the level of the top surface of the conductive layer 112a.

FIG. 24B can be regarded as illustrating an example where the layer 128 fits in the depressed portion formed in the conductive layer 112a. By contrast, as illustrated in FIG. 24D, the layer 128 may exist also outside the depressed portion formed in the conductive layer 112a, that is, the layer 128 may be formed to have a top surface wider than the depressed portion.

This embodiment can be combined with the other embodiments as appropriate.

### Embodiment 4

In this embodiment, a structure example of a transistor that can be used in the display apparatus of one embodiment of the present invention is described. Specifically, the case of using a transistor containing silicon as a semiconductor where a channel is formed is described.

One embodiment of the present invention is a display apparatus including a light-emitting device and a pixel circuit. For example, three kinds of light-emitting devices emitting light of red (R), green (G), and blue (B) are included in the display apparatus, whereby a full-color display apparatus can be achieved.

Transistors containing silicon in their semiconductor layers where channels are formed are preferably used as all transistors included in the pixel circuit for driving the light-emitting device. As silicon, single crystal silicon, polycrystalline silicon, amorphous silicon, and the like can be given. In particular, a transistor containing low-temperature polysilicon (LTPS) in its semiconductor layer (hereinafter also referred to as an LTPS transistor) is preferably used. The LTPS transistor has high field-effect mobility and favorable frequency characteristics.

With the use of transistors containing silicon, such as LTPS transistors, a circuit required to be driven at a high frequency (e.g., a source driver circuit) can be formed on the same substrate as the display portion. Thus, external circuits mounted on the display apparatus can be simplified, whereby component cost and mounting cost can be reduced.

It is preferable to use transistors including a metal oxide (hereinafter also referred to as an oxide semiconductor) in their semiconductors where channels are formed (such transistors are hereinafter also referred to as OS transistors) as at least one of the transistors included in the pixel circuit. An OS transistor has extremely higher field-effect mobility than a transistor containing amorphous silicon. In addition, the OS transistor has an extremely low leakage current between a source and a drain in an off state (hereinafter, also referred to as off-state current), and charge accumulated in a capacitor that is connected in series to the transistor can be retained for a long period. Furthermore, power consumption of the display apparatus can be reduced with the use of an OS transistor.

When an LTPS transistor is used as one or more of the transistors included in the pixel circuit and an OS transistor is used as the rest, a display apparatus with low power consumption and high driving capability can be achieved. As a more preferable example, it is preferable to use an OS transistor as, for example, a transistor functioning as a switch for controlling electrical continuity between wirings and an LTPS transistor as, for example, a transistor for controlling current.

For example, one of the transistors provided in the pixel circuit functions as a transistor for controlling current flowing through the light-emitting device and can be referred to as a driving transistor. One of a source and a drain of the driving transistor is electrically connected to the pixel electrode of the light-emitting device. An LTPS transistor is preferably used as the driving transistor. Accordingly, the amount of current flowing through the light-emitting device can be increased in the pixel circuit.

Another transistor provided in the pixel circuit functions as a switch for controlling selection and non-selection of the pixel and can be referred to as a selection transistor. A gate of the selection transistor is electrically connected to a gate line, and one of a source and a drain thereof is electrically connected to a source line (signal line). An OS transistor is preferably used as the selection transistor. Accordingly, the gray level of the pixel can be maintained even with an extremely low frame frequency (e.g., lower than or equal to 1 fps); thus, power consumption can be reduced by stopping the driver in displaying a still image.

More specific structure examples are described below with reference to drawings.

### [Structure Example 2 of Display Apparatus]

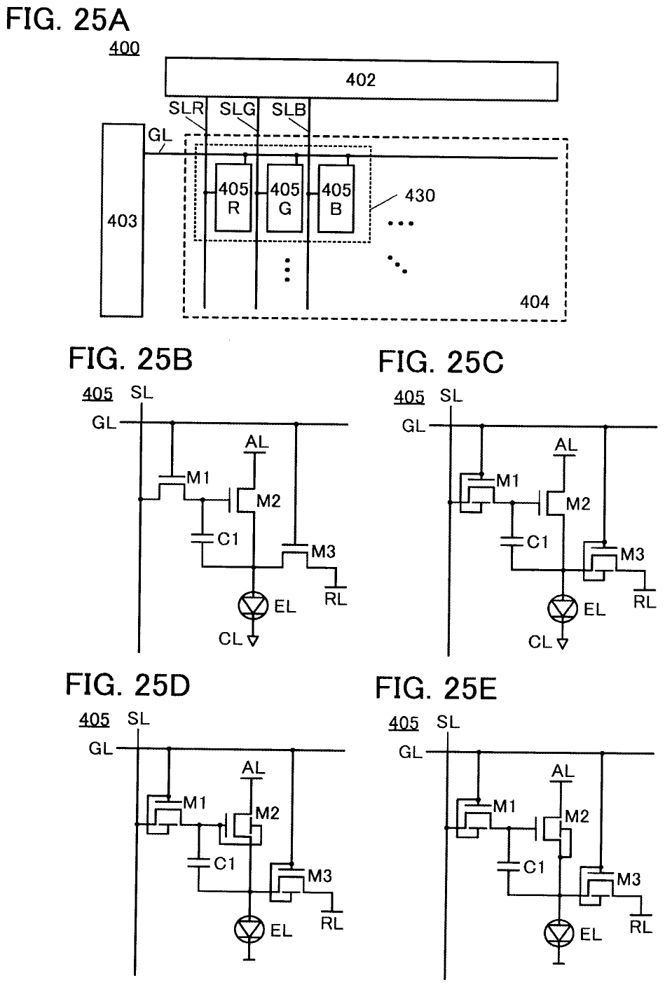

FIG. 25A illustrates a block diagram of a display apparatus 400. The display apparatus 400 includes a display portion 404, a driver circuit portion 402, a driver circuit portion 403, and the like.

The display portion 404 includes a plurality of pixels 430 arranged in a matrix. The pixels 430 each include a subpixel 405R, a subpixel 405G, and a subpixel 405B. The subpixel 405R, the subpixel 405G, and the subpixel 405B each include a light-emitting device functioning as a display device.

The pixel 430 is electrically connected to a wiring GL, a wiring SLR, a wiring SLG, and a wiring SLB. The wiring SLR, the wiring SLG, and the wiring SLB are each electrically connected to the driver circuit portion 402. The wiring GL is electrically connected to the driver circuit portion 403. The driver circuit portion 402 functions as a source line driver circuit (also referred to as a source driver), and the driver circuit portion 403 functions as a gate line driver circuit (also referred to as a gate driver). The wiring GL functions as a gate line, and the wiring SLR, the wiring SLG, and the wiring SLB each function as a source line.

The subpixel 405R includes a light-emitting device emitting red light. The subpixel 405G includes a light-emitting device emitting green light. The subpixel 405B includes a light-emitting device emitting blue light. Thus, the display apparatus 400 can perform full-color display. Note that the pixel 430 may include a subpixel including a light-emitting device emitting light of another color. For example, the pixel 430 may include, in addition to the three subpixels, a subpixel including a light-emitting device emitting white light, a subpixel including a light-emitting device emitting yellow light, or the like.

The wiring GL is electrically connected to the subpixel 405R, the subpixel 405G, and the subpixel 405B arranged in a row direction (an extending direction of the wiring GL). The wiring SLR, the wiring SLG, and the wiring SLB are electrically connected to the subpixels 405R, the subpixels 405G, and the subpixels 405B (not illustrated) arranged in a column direction (an extending direction of the wiring SLR and the like), respectively.

### [Structure Example of Pixel Circuit]

FIG. 25B illustrates an example of a circuit diagram of a pixel 405 that can be used as the subpixel 405R, the subpixel 405G, and the subpixel 405B. The pixel 405 includes a transistor M1, a transistor M2, a transistor M3, a capacitor C1, and a light-emitting device EL. The wiring GL and a wiring SL are electrically connected to the pixel 405. The wiring SL corresponds to any of the wiring SLR, the wiring SLG, and the wiring SLB illustrated in FIG. 25A.

A gate of the transistor M1 is electrically connected to the wiring GL, one of a source and a drain of the transistor M1 is electrically connected to the wiring SL, and the other thereof is electrically connected to one electrode of the capacitor C1 and a gate of the transistor M2. One of a source and a drain of the transistor M2 is electrically connected to a wiring AL, and the other of the source and the drain of the transistor M2 is electrically connected to one electrode of the light-emitting device EL, the other electrode of the capacitor C1, and one of a source and a drain of the transistor M3. A gate of the transistor M3 is electrically connected to the wiring GL, and the other of the source and the drain of the transistor M3 is electrically connected to a wiring RL. The other electrode of the light-emitting device EL is electrically connected to a wiring CL.

A data potential is supplied to the wiring SL. A selection signal is supplied to the wiring GL. The selection signal includes a potential for bringing a transistor into a conducting state and a potential for bringing a transistor into a non-conducting state.

A reset potential is supplied to the wiring RL. An anode potential is supplied to the wiring AL. A cathode potential is supplied to the wiring CL. In the pixel 405, the anode potential is a potential higher than the cathode potential. The reset potential supplied to the wiring RL can be a potential such that a potential difference between the reset potential and the cathode potential is lower than the threshold voltage of the light-emitting device EL. The reset potential can be a potential higher than the cathode potential, a potential equal to the cathode potential, or a potential lower than the cathode potential.

The transistor M1 and the transistor M3 each function as a switch. The transistor M2 functions as a transistor for controlling current flowing through the light-emitting device EL. For example, it can be said that the transistor M1 functions as a selection transistor and the transistor M2 functions as a driving transistor.

Here, it is preferable to use LTPS transistors as all of the transistor M1 to the transistor M3. Alternatively, it is preferable to use OS transistors as the transistor M1 and the transistor M3 and to use an LTPS transistor as the transistor M2.

Alternatively, OS transistors may be used as all of the transistor M1 to the transistor M3. In this case, an LTPS transistor can be used as at least one of a plurality of transistors included in the driver circuit portion 402 and a plurality of transistors included in the driver circuit portion 403, and OS transistors can be used as the other transistors. For example, OS transistors can be used as the transistors provided in the display portion 404, and LTPS transistors can be used as the transistors provided in the driver circuit portion 402 and the driver circuit portion 403.

As the OS transistor, a transistor including an oxide semiconductor in its semiconductor layer where a channel is formed can be used. The semiconductor layer preferably contains indium, M (M is one or more selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, and magnesium), and zinc, for example. Specifically, M is preferably one or more selected from aluminum, gallium, yttrium, and tin. It is particularly preferable to use an oxide containing indium, gallium, and zinc for the semiconductor layer of the OS transistor. Alternatively, it is preferable to use an oxide containing indium, tin, and zinc. Further alternatively, it is preferable to use an oxide containing indium, gallium, tin, and zinc.

A transistor using an oxide semiconductor having a wider band gap and smaller carrier density than silicon can achieve extremely low off-state current. Therefore, owing to the low off-state current, charge accumulated in a capacitor that is connected in series to the transistor can be retained for a long time. Therefore, it is particularly preferable to use a transistor including an oxide semiconductor as each of the transistor M1 and the transistor M3 each of which is connected to the capacitor C1 in series. The use of the transistor including an oxide semiconductor as each of the transistor M1 and the transistor M3 can prevent leakage of charge retained in the capacitor C1 through the transistor M1 or the transistor M3. Furthermore, since charge retained in the capacitor C1 can be retained for a long time, a still image can be displayed for a long time without rewriting data in the pixel 405.

Note that although the transistor is illustrated as an n-channel transistor in FIG. 25B, a p-channel transistor can also be used.

The transistors included in the pixel 405 are preferably formed to be arranged over the same substrate.

Transistors each including a pair of gates overlapping with each other with a semiconductor layer therebetween can be used as the transistors included in the pixel 405.

In the transistor including a pair of gates, the same potential is supplied to the pair of gates electrically connected to each other, which brings advantage that the transistor can have a higher on-state current and improved saturation characteristics. A potential for controlling the threshold voltage of the transistor may be supplied to one of the pair of gates. Furthermore, when a constant potential is supplied to one of the pair of gates, the stability of the electrical characteristics of the transistor can be improved. For example, one of the gates of the transistor may be electrically connected to a wiring to which a constant potential is supplied or may be electrically connected to a source or a drain of the transistor.

The pixel 405 illustrated in FIG. 25C is an example of a case where a transistor including a pair of gates is used as each of the transistor M1 and the transistor M3. In each of the transistor M1 and the transistor M3, the pair of gates are electrically connected to each other. Such a structure can shorten the period in which data is written to the pixel 405.

The pixel 405 illustrated in FIG. 25D is an example of a case where a transistor including a pair of gates (hereinafter referred to as a first gate and a second gate in some cases) is used as the transistor M2 in addition to the transistor M1 and the transistor M3. A pair of gates of the transistor M2 are electrically connected to each other. When such a transistor is used as the transistor M2, the saturation characteristics are improved, whereby emission luminance of the light-emitting device EL can be controlled easily and the display quality can be increased.

FIG. 25D illustrates a case where the first gate and the second gate of the transistor M2 are electrically connected to each other, but the present invention is not limited thereto. As illustrated in FIG. 25E, the first gate of the transistor M2 may be electrically connected to the other of the source and the drain of the transistor M1 and one electrode of the capacitor C1, and the second gate of the transistor M2 may be electrically connected to the other of the source and the drain of the transistor M2, one of the source and the drain of the transistor M3, the other electrode of the capacitor C1, and one electrode of the light-emitting device EL.

### [Structure Example of Transistor]

Cross-sectional structure examples of a transistor that can be used in the above display apparatus are described below.

### [Structure Example 1]

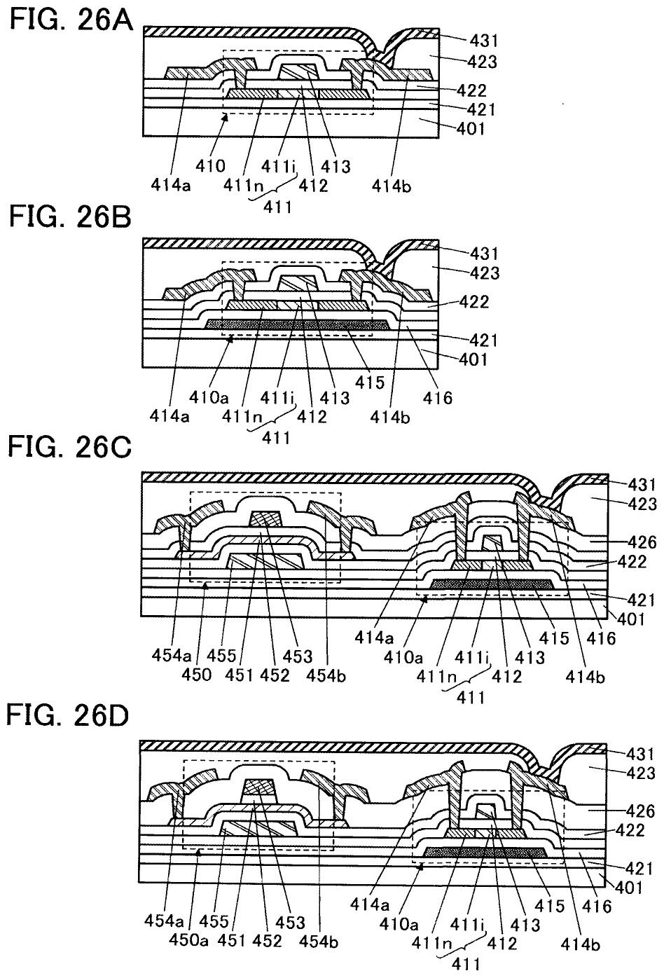

FIG. 26A is a cross-sectional view including a transistor 410.

The transistor 410 is provided over a substrate 401 and contains polycrystalline silicon in its semiconductor layer. For example, the transistor 410 corresponds to the transistor M2 in the pixel 405. In other words, FIG. 26A illustrates an example in which one of a source and a drain of the transistor 410 is electrically connected to a conductive layer 431 of the light-emitting device.

The transistor 410 includes a semiconductor layer 411, an insulating layer 412, a conductive layer 413, and the like. The semiconductor layer 411 includes a channel formation region 411i and low-resistance regions 411n. The semiconductor layer 411 contains silicon. The semiconductor layer 411 preferably contains polycrystalline silicon. Part of the insulating layer 412 functions as a gate insulating layer. Part of the conductive layer 413 functions as a gate electrode.

Note that the semiconductor layer 411 can contain a metal oxide exhibiting semiconductor characteristics (also referred to as an oxide semiconductor). In this case, the transistor 410 can be referred to as an OS transistor.

The low-resistance region 411n is a region containing an impurity element. For example, in the case where the transistor 410 is an n-channel transistor, phosphorus, arsenic, or the like is added to the low-resistance region 411n. Meanwhile, in the case where the transistor 410 is a p-channel transistor, boron, aluminum, or the like is added to the low-resistance region 411n. In addition, in order to control the threshold voltage of the transistor 410, the above-described impurity may be added to the channel formation region 411i.

An insulating layer 421 is provided over the substrate 401. The semiconductor layer 411 is provided over the insulating layer 421. The insulating layer 412 is provided to cover the semiconductor layer 411 and the insulating layer 421. The conductive layer 413 is provided at a position that is over the insulating layer 412 and overlaps with the semiconductor layer 411.

An insulating layer 422 is provided to cover the conductive layer 413 and the insulating layer 412. A conductive layer 414a and a conductive layer 414b are provided over the insulating layer 422. The conductive layer 414a and the conductive layer 414b are each electrically connected to the low-resistance region 411n in the opening portion provided in the insulating layer 422 and the insulating layer 412. Part of the conductive layer 414a functions as one of a source electrode and a drain electrode and part of the conductive layer 414b functions as the other of the source electrode and the drain electrode. An insulating layer 423 is provided to cover the conductive layer 414a, the conductive layer 414b, and the insulating layer 422.

The conductive layer 431 functioning as a pixel electrode is provided over the insulating layer 423. The conductive layer 431 is provided over the insulating layer 423 and is electrically connected to the conductive layer 414b through an opening provided in the insulating layer 423. Although not illustrated here, an EL layer and a common electrode can be stacked over the conductive layer 431.

### [Structure Example 2]

FIG. 26B illustrates a transistor 410a including a pair of gate electrodes. The transistor 410a illustrated in FIG. 26B is different from FIG. 26A mainly in including a conductive layer 415 and an insulating layer 416.

The conductive layer 415 is provided over the insulating layer 421. The insulating layer 416 is provided to cover the conductive layer 415 and the insulating layer 421. The semiconductor layer 411 is provided such that at least the channel formation region 411i overlaps with the conductive layer 415 with the insulating layer 416 therebetween.

In the transistor 410a illustrated in FIG. 26B, part of the conductive layer 413 functions as a first gate electrode, and part of the conductive layer 415 functions as a second gate electrode. At this time, part of the insulating layer 412 functions as a first gate insulating layer, and part of the insulating layer 416 functions as a second gate insulating layer.

Here, to electrically connect the first gate electrode to the second gate electrode, the conductive layer 413 is electrically connected to the conductive layer 415 through an opening portion provided in the insulating layer 412 and the insulating layer 416 in a region not illustrated. To electrically connect the second gate electrode to a source or a drain, the conductive layer 415 is electrically connected to the conductive layer 414a or the conductive layer 414b through an opening portion provided in the insulating layer 422, the insulating layer 412, and the insulating layer 416 in a region not illustrated.

In the case where LTPS transistors are used as all of the transistors included in the pixel 405, the transistor 410 illustrated in FIG. 26A as an example or the transistor 410a illustrated in FIG. 26B as an example can be used. In this case, the transistors 410a may be used as all of the transistors included in the pixels 405, the transistors 410 may be used as all of the transistors, or the transistors 410a and the transistors 410 may be used in combination.

### [Structure Example 3]

Described below is an example of a structure including both a transistor containing silicon in its semiconductor layer and a transistor containing a metal oxide in its semiconductor layer.

FIG. 26C illustrates a schematic cross-sectional view including the transistor 410a and a transistor 450.

Structure example 1 described above can be referred to for the structure of the transistor 410a. Although an example using the transistor 410a is illustrated here, a structure including the transistor 410 and the transistor 450 or a structure including all the transistor 410, the transistor 410a, and the transistor 450 may alternatively be employed.

The transistor 450 is a transistor containing a metal oxide in its semiconductor layer. The structure illustrated in FIG. 26C is an example in which the transistor 450 and the transistor 410a respectively correspond to the transistor M1 and the transistor M2, in the pixel 405, for example. That is, FIG. 26C illustrates an example in which one of a source and a drain of the transistor 410a is electrically connected to the conductive layer 431.

Moreover, FIG. 26C illustrates an example in which the transistor 450 includes a pair of gates.

The transistor 450 includes a conductive layer 455, the insulating layer 422, a semiconductor layer 451, an insulating layer 452, a conductive layer 453, and the like. Part of the conductive layer 453 functions as a first gate of the transistor 450, and part of the conductive layer 455 functions as a second gate of the transistor 450. In this case, part of the insulating layer 452 functions as a first gate insulating layer of the transistor 450, and part of the insulating layer 422 functions as a second gate insulating layer of the transistor 450.

The conductive layer 455 is provided over the insulating layer 412. The insulating layer 422 is provided to cover the conductive layer 455. The semiconductor layer 451 is provided over the insulating layer 422. The insulating layer 452 is provided to cover the semiconductor layer 451 and the insulating layer 422. The conductive layer 453 is provided over the insulating layer 452 and includes a region overlapping with the semiconductor layer 451 and the conductive layer 455.

An insulating layer 426 is provided to cover the insulating layer 452 and the conductive layer 453. A conductive layer 454a and a conductive layer 454b are provided over the insulating layer 426. The conductive layer 454a and the conductive layer 454b are electrically connected to the semiconductor layer 451 in openings provided in the insulating layer 426 and the insulating layer 452. Part of the conductive layer 454a functions as one of a source electrode and a drain electrode and part of the conductive layer 454b functions as the other of the source electrode and the drain electrode. The insulating layer 423 is provided to cover the conductive layer 454a, the conductive layer 454b, and the insulating layer 426.

Here, the conductive layer 414a and the conductive layer 414b electrically connected to the transistor 410a are preferably formed by processing the same conductive film as the conductive layer 454a and the conductive layer 454b, respectively. FIG. 26C illustrates a structure where the conductive layer 414a, the conductive layer 414b, the conductive layer 454a, and the conductive layer 454b are formed on the same plane (i.e., in contact with the top surface of the insulating layer 426) and contain the same metal element. In this case, the conductive layer 414a and the conductive layer 414b are electrically connected to the low-resistance regions 411n through openings provided in the insulating layer 426, the insulating layer 452, the insulating layer 422, and the insulating layer 412. This is preferable because the manufacturing process can be simplified.

Moreover, the conductive layer 413 functioning as the first gate electrode of the transistor 410a and the conductive layer 455 functioning as the second gate electrode of the transistor 450 are preferably formed by processing the same conductive film. FIG. 26C illustrates a structure where the conductive layer 413 and the conductive layer 455 are formed on the same plane (i.e., in contact with the top surface of the insulating layer 412) and contain the same metal element. This is preferable because the manufacturing process can be simplified.

In the structure in FIG. 26C, the insulating layer 452 functioning as the first gate insulating layer of the transistor 450 covers an end portion of the semiconductor layer 451; however, the insulating layer 452 may be processed to have the same or substantially the same top surface shape as the conductive layer 453 as in a transistor 450a illustrated in FIG. 26D.

Note that in this specification and the like, the expression “top surface shapes are substantially the same” means that at least outlines of stacked layers partly overlap with each other. For example, the case of processing the upper layer and the lower layer with the use of the same mask pattern or mask patterns that are partly the same is included. However, in some cases, the outlines do not completely overlap with each other and the upper layer is positioned inward from the lower layer or the upper layer is positioned outward from the lower layer; such cases are also represented by the expression “top surface shapes are substantially the same”.

Although the example in which the transistor 410a corresponds to the transistor M2 and is electrically connected to the pixel electrode is shown here, one embodiment of the present invention is not limited thereto. For example, a structure in which the transistor 450 or the transistor 450a corresponds to the transistor M2 may be employed. In that case, the transistor 410a corresponds to the transistor M1, the transistor M3, or another transistor.

This embodiment can be combined with the other embodiments as appropriate.

### Embodiment 5

In this embodiment, light-emitting devices that can be used for the display apparatus of one embodiment of the present invention will be described.

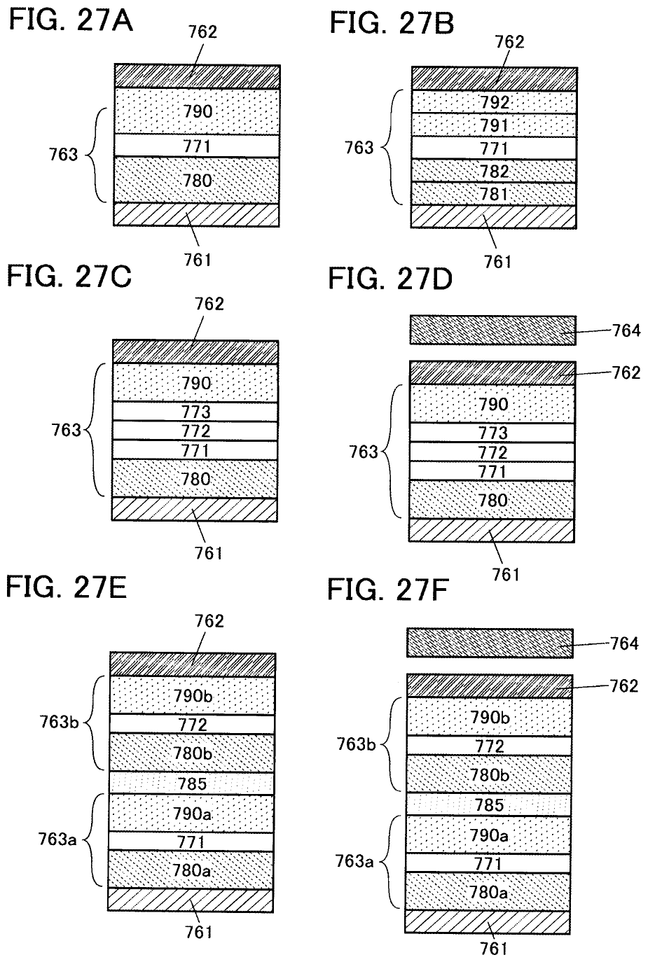

As illustrated in FIG. 27A, the light-emitting device includes an EL layer 763 between a pair of electrodes (a lower electrode 761 and an upper electrode 762). The EL layer 763 can be formed of a plurality of layers such as a layer 780, a light-emitting layer 771, and a layer 790.

The light-emitting layer 771 contains at least a light-emitting substance (also referred to as a light-emitting material).

In the case where the lower electrode 761 is an anode and the upper electrode 762 is a cathode, the layer 780 includes one or more of a layer containing a substance with a high hole-injection property (a hole-injection layer), a layer containing a substance with a high hole-transport property (a hole-transport layer), and a layer containing a substance with a high electron-blocking property (an electron-blocking layer). Furthermore, the layer 790 includes one or more of a layer containing a substance with a high electron-injection property (an electron-injection layer), a layer containing a substance with a high electron-transport property (an electron-transport layer), and a layer containing a substance with a high hole-blocking property (a hole-blocking layer). In the case where the lower electrode 761 is a cathode and the upper electrode 762 is an anode, the above structures of the layer 780 and the layer 790 are replaced with each other.

The structure including the layer 780, the light-emitting layer 771, and the layer 790, which is provided between a pair of electrodes, can function as a single light-emitting unit, and the structure in FIG. 27A is referred to as a single structure in this specification.

FIG. 27B is a variation example of the EL layer 763 included in the light-emitting device illustrated in FIG. 27A. Specifically, the light-emitting device illustrated in FIG. 27B includes a layer 781 over the lower electrode 761, a layer 782 over the layer 781, the light-emitting layer 771 over the layer 782, a layer 791 over the light-emitting layer 771, a layer 792 over the layer 791, and the upper electrode 762 over the layer 792.

In the case where the lower electrode 761 is an anode and the upper electrode 762 is a cathode, the layer 781 can be a hole-injection layer, the layer 782 can be a hole-transport layer, the layer 791 can be an electron-transport layer, and the layer 792 can be an electron-injection layer, for example. In the case where the lower electrode 761 is a cathode and the upper electrode 762 is an anode, the layer 781 can be an electron-injection layer, the layer 782 can be an electron-transport layer, the layer 791 can be a hole-transport layer, and the layer 792 can be a hole-injection layer. With such a layer structure, carriers can be efficiently injected to the light-emitting layer 771, and the efficiency of the recombination of carriers in the light-emitting layer 771 can be increased.

Note that structures in which a plurality of light-emitting layers (light-emitting layers 771, 772, and 773) are provided between the layer 780 and the layer 790 as illustrated in FIG. 27C and FIG. 27D are variations of the single structure. Although FIG. 27C and FIG. 27D illustrate the examples where three light-emitting layers are included, the light-emitting device having a single structure may include two or four or more light-emitting layers. In addition, the light-emitting device having a single structure may include a buffer layer between two light-emitting layers.

A structure where a plurality of light-emitting units (a light-emitting unit 763a and a light-emitting unit 763b) are connected in series with a charge-generation layer 785 (also referred to as an intermediate layer) therebetween as illustrated in FIG. 27E and FIG. 27F is referred to as a tandem structure in this specification. Note that the tandem structure may be referred to as a stack structure. The tandem structure enables a light-emitting device capable of high-luminance light emission. Furthermore, the tandem structure reduces the amount of current needed for obtaining the same luminance as compared with a single structure, and thus can improve the reliability.

Note that FIG. 27D and FIG. 27F illustrate examples where the display apparatus includes a layer 764 overlapping with the light-emitting device. FIG. 27D illustrates an example where the layer 764 overlaps with the light-emitting device illustrated in FIG. 27C, and FIG. 27F illustrates an example where the layer 764 overlaps with the light-emitting device illustrated in FIG. 27E. In FIG. 27D and FIG. 27F, a conductive film transmitting visible light is used for the upper electrode 762 to extract light to the upper electrode 762 side.

One or both of a color conversion layer and a color filter (a coloring layer) can be used as the layer 764.

In FIG. 27C and FIG. 27D, light-emitting substances that emit light of the same color, or moreover, the same light-emitting substance may be used for the light-emitting layer 771, the light-emitting layer 772, and the light-emitting layer 773. For example, a light-emitting substance emitting blue light may be used for the light-emitting layer 771, the light-emitting layer 772, and the light-emitting layer 773. In a subpixel that emits blue light, blue light emitted from the light-emitting device can be extracted. In a subpixel that emits red light and a subpixel that emits green light, by providing a color conversion layer as the layer 764 illustrated in FIG. 27D, blue light emitted from the light-emitting device can be converted into light with a longer wavelength, and red light or green light can be extracted. As the layer 764, both a color conversion layer and a coloring layer are preferably used. In some cases, part of light emitted from the light-emitting device is transmitted through the color conversion layer without being converted. When light transmitted through the color conversion layer is extracted through the coloring layer, light other than light of the intended color can be absorbed by the coloring layer, and color purity of light exhibited by a subpixel can be improved. Note that the above structure may be employed in the light-emitting devices illustrated in FIG. 27A and FIG. 27B. In this case, a light-emitting substance that emits blue light is used for the light-emitting layers 771 of the light-emitting devices illustrated in FIG. 27A and FIG. 27B.

Alternatively, in FIG. 27C and FIG. 27D, light-emitting substances emitting light of different colors may be used for the light-emitting layer 771, the light-emitting layer 772, and the light-emitting layer 773. White light emission can be obtained when the light-emitting layer 771, the light-emitting layer 772, and the light-emitting layer 773 emit light of complementary colors. The light-emitting device having a single structure preferably includes a light-emitting layer containing a light-emitting substance emitting blue light and a light-emitting layer containing a light-emitting substance emitting visible light with a longer wavelength than blue light, for example.

A color filter may be provided as the layer 764 illustrated in FIG. 27D. When white light passes through the color filter, light of a desired color can be obtained.

In the case where the light-emitting device having a single structure includes three light-emitting layers, for example, a light-emitting layer containing a light-emitting substance emitting red (R) light, a light-emitting layer containing a light-emitting substance emitting green (G) light, and a light-emitting layer containing a light-emitting substance emitting blue (B) light are preferably included. The stacking order of the light-emitting layers can be RGB or RBG from an anode side, for example. In that case, a buffer layer may be provided between R and G or between R and B.

For example, in the case where the light-emitting device having a single structure includes two light-emitting layers, the light-emitting device preferably includes a light-emitting layer containing a light-emitting substance that emits blue (B) light and a light-emitting layer containing a light-emitting substance that emits yellow (Y) light. Such a structure may be referred to as a BY single structure.

The light-emitting device that emits white light preferably contains two or more kinds of light-emitting substances. To obtain white light emission, two or more kinds of light-emitting substances are selected such that they emit light of complementary colors. For example, when an emission color of a first light-emitting layer and an emission color of a second light-emitting layer are complementary colors, the light-emitting device can emit white light as a whole. The same applies to a light-emitting device including three or more light-emitting layers.

Also in FIG. 27C and FIG. 27D, the layer 780 and the layer 790 may each independently have a stacked-layer structure of two or more layers as illustrated in FIG. 27B.

In FIG. 27E and FIG. 27F, light-emitting substances that emit light of the same color, or moreover, the same light-emitting substance may be used for the light-emitting layer 771 and the light-emitting layer 772. For example, in light-emitting devices included in subpixels emitting light of different colors, a light-emitting substance that emits blue light can be used for each of the light-emitting layer 771 and the light-emitting layer 772. In a subpixel that emits blue light, blue light emitted from the light-emitting device can be extracted. In the subpixel that emits red light and the subpixel that emits green light, by providing a color conversion layer as the layer 764 illustrated in FIG. 27F, blue light emitted from the light-emitting device can be converted into light with a longer wavelength, and red light or green light can be extracted. As the layer 764, both a color conversion layer and a coloring layer are preferably used.

In FIG. 27E and FIG. 27F, light-emitting substances emitting light of different colors may be used for the light-emitting layer 771 and the light-emitting layer 772. White light emission can be obtained when the light-emitting layer 771 and the light-emitting layer 772 emit light of complementary colors. A color filter may be provided as the layer 764 illustrated in FIG. 27F. When white light passes through the color filter, light of a desired color can be obtained.

Although FIG. 27E and FIG. 27F illustrate examples where the light-emitting unit 763a includes one the light-emitting layer 771 and the light-emitting unit 763b includes one the light-emitting layer 772, one embodiment of the present invention is not limited thereto. Each of the light-emitting unit 763a and the light-emitting unit 763b may include two or more light-emitting layers.

In addition, although FIG. 27E and FIG. 27F illustrate the light-emitting device including two light-emitting units, one embodiment of the present invention is not limited thereto. The light-emitting device may include three or more light-emitting units. Note that a structure including two light-emitting units and a structure including three light-emitting units may be referred to as a two-unit tandem structure and a three-unit tandem structure, respectively.

In FIG. 27E and FIG. 27F, the light-emitting unit 763a includes a layer 780a, the light-emitting layer 771, and a layer 790a, and the light-emitting unit 763b includes a layer 780b, the light-emitting layer 772, and a layer 790b.

In the case where the lower electrode 761 is an anode and the upper electrode 762 is a cathode, the layer 780a and the layer 780b each include one or more of a hole-injection layer, a hole-transport layer, and an electron-blocking layer. The layer 790a and the layer 790b each include one or more of an electron-injection layer, an electron-transport layer, and a hole-blocking layer. In the case where the lower electrode 761 is a cathode and the upper electrode 762 is an anode, the structures of the layer 780a and the layer 790a are replaced with each other, and the structures of the layer 780b and the layer 790b are also replaced with each other.

In the case where the lower electrode 761 is an anode and the upper electrode 762 is a cathode, for example, the layer 780a includes a hole-injection layer and a hole-transport layer over the hole-injection layer, and may further include an electron-blocking layer over the hole-transport layer. The layer 790a includes an electron-transport layer, and may further include a hole-blocking layer between the light-emitting layer 771 and the electron-transport layer. The layer 780b includes a hole-transport layer, and may further include an electron-blocking layer over the hole-transport layer. The layer 790b includes an electron-transport layer and an electron-injection layer over the electron-transport layer, and may further include a hole-blocking layer between the light-emitting layer 771 and the electron-transport layer. In the case where the lower electrode 761 is a cathode and the upper electrode 762 is an anode, for example, the layer 780a includes an electron-injection layer and an electron-transport layer over the electron-injection layer, and may further include a hole-blocking layer over the electron-transport layer. The layer 790a includes a hole-transport layer, and may further include an electron-blocking layer between the light-emitting layer 771 and the hole-transport layer. The layer 780b includes an electron-transport layer, and may further include a hole-blocking layer over the electron-transport layer. The layer 790b includes a hole-transport layer and a hole-injection layer over the hole-transport layer, and may further include an electron-blocking layer between the light-emitting layer 771 and the hole-transport layer.

In the case of manufacturing a light-emitting device having a tandem structure, two light-emitting units are stacked with the charge-generation layer 785 therebetween. The charge-generation layer 785 includes at least a charge-generation region. The charge-generation layer 785 has a function of injecting electrons into one of the two light-emitting units and injecting holes into the other when voltage is applied between the pair of electrodes.

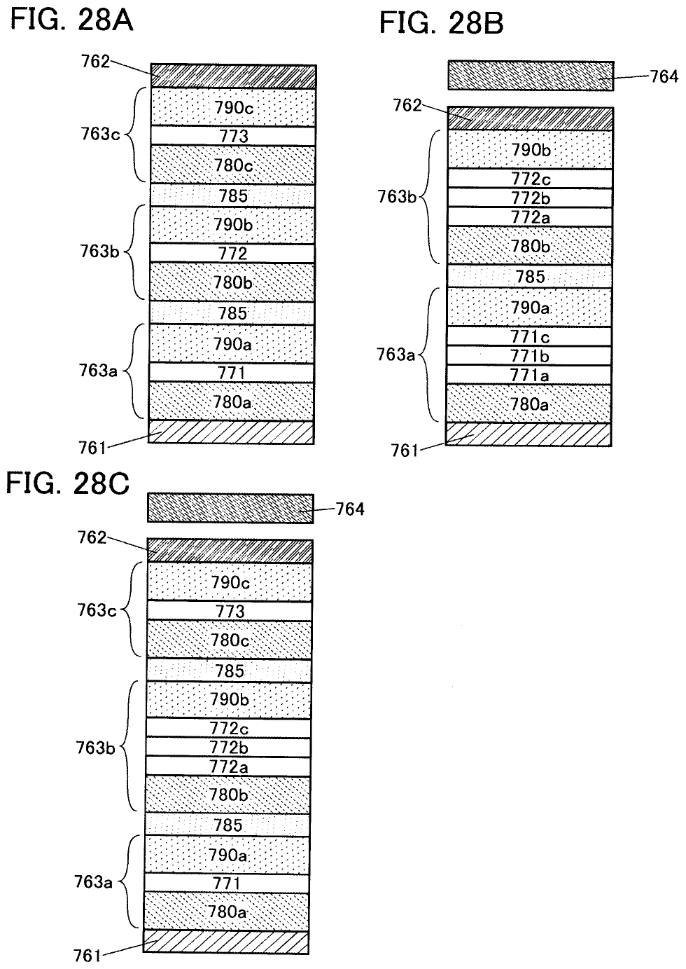

The structures illustrated in FIG. 28A to FIG. 28C can be given as examples of the light-emitting device having a tandem structure.

FIG. 28A illustrates a structure including three light-emitting units. In FIG. 28A, a plurality of light-emitting units (the light-emitting unit 763a, the light-emitting unit 763b, and a light-emitting unit 763c) are connected in series through the charge-generation layers 785. The light-emitting unit 763a includes the layer 780a, the light-emitting layer 771, and the layer 790a. The light-emitting unit 763b includes the layer 780b, the light-emitting layer 772, and the layer 790b. The light-emitting unit 763c includes a layer 780c, the light-emitting layer 773, and a layer 790c. Note that the layer 780c can have a structure applicable to the layer 780a and the layer 780b, and the layer 790c can have a structure applicable to the layer 790a and the layer 790b.

In FIG. 28A, the light-emitting layer 771, the light-emitting layer 772, and the light-emitting layer 773 preferably contain light-emitting substances that emit light of the same color. Specifically, a structure where the light-emitting layer 771, the light-emitting layer 772, and the light-emitting layer 773 each contain a blue (B) light-emitting substance (i.e., a three-unit tandem structure of B\B\B) can be employed. Alternatively, the layer 764 may be provided as appropriate as in the light-emitting device illustrated in FIG. 27F. As the layer 764, a color conversion layer or both a color conversion layer and a coloring layer is/are used. Note that “a\b” means that a light-emitting unit containing a light-emitting substance that emits light of b is provided over a light-emitting unit containing a light-emitting substance that emits light of a with a charge-generation layer therebetween, where a and b represent colors.

In FIG. 28A, light-emitting substances that emit light of different colors may be used for some or all of the light-emitting layer 771, the light-emitting layer 772, and the light-emitting layer 773. Examples of a combination of emission colors for the light-emitting layer 771, the light-emitting layer 772, and the light-emitting layer 773 include blue (B) for two of them and yellow (Y) for the other; and red (R) for one of them, green (G) for another, and blue (B) for the other. The layer 764 may be provided as appropriate as in the light-emitting device illustrated in FIG. 27F. As the layer 764, a color filter is used.

Note that the structure containing the light-emitting substances that emit light of the same color is not limited to the above structure. For example, a light-emitting device with a tandem structure may be employed in which light-emitting units each including a plurality of light-emitting layers are stacked as illustrated in FIG. 28B. FIG. 28B illustrates a structure in which two light-emitting units the light-emitting unit 763a and the light-emitting unit 763b) are connected in series with the charge-generation layer 785 therebetween. The light-emitting unit 763a includes the layer 780a, a light-emitting layer 771a, a light-emitting layer 771b, a light-emitting layer 771c, and the layer 790a. The light-emitting unit 763b includes the layer 780b, a light-emitting layer 772a, a light-emitting layer 772b, a light-emitting layer 772c, and the layer 790b.

In FIG. 28B, the light-emitting unit 763a is configured to emit white (W) light by selecting light-emitting substances for the light-emitting layer 771a, the light-emitting layer 771b, and the light-emitting layer 771c so that their emission colors are complementary colors. Furthermore, the light-emitting unit 763b is configured to emit white (W) light by selecting light-emitting substances for the light-emitting layer 772a, the light-emitting layer 772b, and the light-emitting layer 772c so that their emission colors are complementary colors. That is, the structure illustrated in FIG. 28B is a two-unit tandem structure of W\W. Note that there is no particular limitation on the stacking order of the light-emitting substances having complementary emission colors. The practitioner can select the optimal stacking order as appropriate. Although not illustrated, a three-unit tandem structure of W\W\W or a tandem structure with four or more units may be employed.

The following structure can be given: a B\Y or Y\B two-unit tandem structure including a light-emitting unit that emits yellow (Y) light and a light-emitting unit that emits blue (B) light; an R·G\B or B\R·G two-unit tandem structure including a light-emitting unit that emits red (R) light and green (G) light and a light-emitting unit that emits blue (B) light; a B\Y\B three-unit tandem structure including a light-emitting unit that emits blue (B) light, a light-emitting unit that emits yellow (Y) light, and a light-emitting unit that emits blue (B) light in this order; a B\YG\B three-unit tandem structure including a light-emitting unit that emits blue (B) light, a light-emitting unit that emits yellow green (YG) light, and a light-emitting unit that emits blue (B) light in this order; and a B\G\B three-unit tandem structure including a light-emitting unit that emits blue (B) light, a light-emitting unit that emits green (G) light, and a light-emitting unit that emits blue (B) light in this order. Note that “a\b” means that one light-emitting unit contains a light-emitting substance that emits light of a and a light-emitting substance that emits light of b.

As illustrated in FIG. 28C, a light-emitting unit including one light-emitting layer and a light-emitting unit including a plurality of light-emitting layers may be used in combination.

Specifically, in the structure illustrated in FIG. 28C, a plurality of light-emitting units (the light-emitting unit 763a, the light-emitting unit 763b, and the light-emitting unit 763c) are connected in series through the charge-generation layers 785. The light-emitting unit 763a includes the layer 780a, the light-emitting layer 771, and the layer 790a. The light-emitting unit 763b includes the layer 780b, the light-emitting layer 772a, the light-emitting layer 772b, the light-emitting layer 772c, and the layer 790b. The light-emitting unit 763c includes the layer 780c, the light-emitting layer 773, and the layer 790c.

As the structure illustrated in FIG. 28C, for example, a three-unit tandem structure of B\R·G·YG\B in which the light-emitting unit 763a is a light-emitting unit that emits blue (B) light, the light-emitting unit 763b is a light-emitting unit that emits red (R), green (G), and yellow green (YG) light, and the light-emitting unit 763c is a light-emitting unit that emits blue (B) light can be employed.

Examples of the number of stacked light-emitting units and the order of colors from the anode side include a two-unit structure of B and Y, a two-unit structure of B and a light-emitting unit X, a three-unit structure of B, Y, and B, and a three-unit structure of B, X, and B. Examples of the number of light-emitting layers stacked in the light-emitting unit X and the order of colors from an anode side include a two-layer structure of R and Y, a two-layer structure of R and G, a two-layer structure of G and R, a three-layer structure of G, R, and G, and a three-layer structure of R, G, and R. Another layer may be provided between two light-emitting layers.

Next, materials that can be used for the light-emitting device will be described.

A conductive film transmitting visible light is used as the electrode through which light is extracted, which is either the lower electrode 761 or the upper electrode 762. A conductive film reflecting visible light is preferably used as the electrode through which light is not extracted. In the case where a display apparatus includes a light-emitting device emitting infrared light, it is preferable that a conductive film transmitting visible light and infrared light be used as the electrode through which light is extracted, and a conductive film reflecting visible light and infrared light be used as the electrode through which light is not extracted.

A conductive film transmitting visible light may be used as the electrode through which light is not extracted. In that case, the electrode is preferably placed between a reflective layer and the EL layer 763. In other words, light emitted from the EL layer 763 may be reflected by the reflective layer to be extracted from the display apparatus.

As a material that forms the pair of electrodes of the light-emitting device, a metal, an alloy, an electrically conductive compound, a mixture thereof, or the like can be used as appropriate. Specific examples of the material include metals such as aluminum, magnesium, titanium, chromium, manganese, iron, cobalt, nickel, copper, gallium, zinc, indium, tin, molybdenum, tantalum, tungsten, palladium, gold, platinum, silver, yttrium, and neodymium, and an alloy containing any of these metals in appropriate combination. Other examples of the material include indium tin oxide (also referred to as In—Sn oxide or ITO), In—Si—Sn oxide (also referred to as ITSO), indium zinc oxide (In—Zn oxide), and In—W—Zn oxide. Other examples of the material include an alloy containing aluminum (aluminum alloy), such as an alloy of aluminum, nickel, and lanthanum (Al—Ni—La), and an alloy containing silver, such as an alloy of silver and magnesium and an alloy of silver, palladium, and copper (also referred to as Ag—Pd—Cu or APC). Alternatively, as the material, an element belonging to Group 1 or Group 2 of the periodic table, which is not described above as an example (e.g., lithium, cesium, calcium, or strontium), a rare earth metal such as europium or ytterbium, an alloy containing an appropriate combination of any of these, graphene, or the like can be given.

The light-emitting devices preferably employ a microcavity structure. Thus, one of the pair of electrodes included in the light-emitting device is preferably an electrode having properties of transmitting and reflecting visible light (a transflective electrode), and the other is preferably an electrode having a property of reflecting visible light (a reflective electrode). When the light-emitting device has a microcavity structure, light obtained from the light-emitting layer can be resonated between the electrodes, whereby light emitted from the light-emitting device can be intensified.

The transflective electrode can also have a stacked-layer structure of a conductive layer that can be used as a reflective electrode and a conductive layer that can be used as an electrode having a visible-light-transmitting property (also referred to as a transparent electrode).

The light transmittance of the transparent electrode is higher than or equal to 40%. For example, an electrode having a visible light (light at wavelengths greater than or equal to 400 nm and less than 750 nm) transmittance higher than or equal to 40% is preferably used as the transparent electrode of the light-emitting device. The transflective electrode has a visible light reflectance higher than or equal to 10% and lower than or equal to 95%, preferably higher than or equal to 30% and lower than or equal to 80%. The reflective electrode has a visible light reflectance higher than or equal to 40% and lower than or equal to 100%, preferably higher than or equal to 70% and lower than or equal to 100%. These electrodes preferably have a resistivity less than or equal to 1×10⁻² Ωcm.

The light-emitting device includes at least the light-emitting layer. The light-emitting device may further include, as a layer other than the light-emitting layer, a layer containing a substance with a high hole-injection property, a substance with a high hole-transport property, a hole-blocking material, a substance with a high electron-transport property, an electron-blocking material, a substance with a high electron-injection property, a substance with a bipolar property (a substance with a high electron-transport property and a high hole-transport property), or the like. For example, the light-emitting device can include one or more of a hole-injection layer, a hole-transport layer, a hole-blocking layer, a charge-generation layer, an electron-blocking layer, an electron-transport layer, and an electron-injection layer in addition to the light-emitting layer.

Either a low molecular compound or a high molecular compound can be used in the light-emitting device, and an inorganic compound may be included. Each layer included in the light-emitting device can be formed by any of the following methods: an evaporation method (including a vacuum evaporation method), a transfer method, a printing method, an ink-jet method, a coating method, and the like.

The light-emitting layer contains one or more kinds of light-emitting substances. As the light-emitting substance, a substance that exhibits an emission color of blue, violet, blue violet, green, yellow green, yellow, orange, red, or the like is appropriately used. Alternatively, as the light-emitting substance, a substance emitting near-infrared light can be used.

Examples of the light-emitting substance include a fluorescent material, a phosphorescent material, a TADF material, and a quantum dot material.

Examples of a fluorescent material include a pyrene derivative, an anthracene derivative, a triphenylene derivative, a fluorene derivative, a carbazole derivative, a dibenzothiophene derivative, a dibenzofuran derivative, a dibenzoquinoxaline derivative, a quinoxaline derivative, a pyridine derivative, a pyrimidine derivative, a phenanthrene derivative, and a naphthalene derivative.

Examples of a phosphorescent material include an organometallic complex (particularly an iridium complex) having a 4H-triazole skeleton, a 1H-triazole skeleton, an imidazole skeleton, a pyrimidine skeleton, a pyrazine skeleton, or a pyridine skeleton; an organometallic complex (particularly an iridium complex) having a phenylpyridine derivative including an electron-withdrawing group as a ligand; a platinum complex; and a rare earth metal complex.

The light-emitting layer may contain one or more kinds of organic compounds (e.g., a host material and an assist material) in addition to the light-emitting substance (a guest material). As one or more kinds of organic compounds, one or both of a substance with a high hole-transport property (a hole-transport material) and a substance with a high electron-transport property (an electron-transport material) can be used. As the hole-transport material, it is possible to use a material having a high hole-transport property which can be used for the hole-transport layer and will be described later. As the electron-transport material, it is possible to use a material having a high electron-transport property which can be used for the electron-transport layer and will be described later. Alternatively, as one or more kinds of organic compounds, a bipolar material or a TADF material may be used.

The light-emitting layer preferably contains a phosphorescent material and a combination of a hole-transport material and an electron-transport material that easily forms an exciplex, for example. Such a structure makes it possible to efficiently obtain light emission using ExTET (Exciplex-Triplet Energy Transfer), which is energy transfer from an exciplex to a light-emitting substance (a phosphorescent material). When a combination of materials is selected to form an exciplex that exhibits light emission whose wavelength overlaps with the wavelength of the lowest-energy-side absorption band of the light-emitting substance, energy can be transferred smoothly and light emission can be obtained efficiently. With this structure, high efficiency, low-voltage driving, and a long lifetime of the light-emitting device can be achieved at the same time.

The hole-injection layer injects holes from the anode to the hole-transport layer and contains a material with a high hole-injection property. Examples of a material with a high hole-injection property include an aromatic amine compound and a composite material containing a hole-transport material and an acceptor material (electron-accepting material).

As the hole-transport material, it is possible to use a material having a high hole-transport property which can be used for the hole-transport layer and will be described later.

As the acceptor material, an oxide of a metal belonging to Group 4 to Group 8 of the periodic table can be used, for example. Specific examples include molybdenum oxide, vanadium oxide, niobium oxide, tantalum oxide, chromium oxide, tungsten oxide, manganese oxide, and rhenium oxide. Among these, molybdenum oxide is particularly preferable since it is stable in the air, has a low hygroscopic property, and is easy to handle. An organic acceptor material containing fluorine can be used. An organic acceptor material such as a quinodimethane derivative, a chloranil derivative, or a hexaazatriphenylene derivative can be used.

For example, a hole-transport material and a material containing an oxide of a metal belonging to Group 4 to Group 8 of the periodic table (typically, molybdenum oxide) may be used as the material having a high hole-injection property.

The hole-transport layer transports holes injected from the anode by the hole-injection layer, to the light-emitting layer. The hole-transport layer contains a hole-transport material. As the hole-transport material, a substance having a hole mobility higher than or equal to 1×10⁻⁶ cm²/Vs is preferable. Note that other substances can also be used as long as the substances have a hole-transport property higher than an electron-transport property. As the hole-transport material, a material with a high hole-transport property, such as a π-electron rich heteroaromatic compound (e.g., a carbazole derivative, a thiophene derivative, and a furan derivative) and an aromatic amine (a compound having an aromatic amine skeleton), is preferable.

The electron-blocking layer is provided in contact with the light-emitting layer. The electron-blocking layer has a hole-transport property and contains a material capable of blocking electrons. Any of the materials having an electron-blocking property among the above hole-transport materials can be used for the electron-blocking layer.

The electron-blocking layer has a hole-transport property, and thus can also be referred to as a hole-transport layer. A layer having an electron-blocking property among the hole-transport layers can also be referred to as an electron-blocking layer.

The electron-transport layer transports electrons injected from the cathode by the electron-injection layer, to the light-emitting layer. The electron-transport layer contains an electron-transport material. As the electron-transport material, a substance having an electron mobility higher than or equal to 1×10⁻⁶ cm²/Vs is preferable. Note that other substances can also be used as long as the substances have an electron-transport property higher than a hole-transport property. As the electron-transport material, any of the following materials with a high electron-transport property can be used, for example: a metal complex having a quinoline skeleton, a metal complex having a benzoquinoline skeleton, a metal complex having an oxazole skeleton, a metal complex having a thiazole skeleton, an oxadiazole derivative, a triazole derivative, an imidazole derivative, an oxazole derivative, a thiazole derivative, a phenanthroline derivative, a quinoline derivative having a quinoline ligand, a benzoquinoline derivative, a quinoxaline derivative, a dibenzoquinoxaline derivative, a pyridine derivative, a bipyridine derivative, a pyrimidine derivative, and a T-electron deficient heteroaromatic compound such as a nitrogen-containing heteroaromatic compound.

The hole-blocking layer is provided in contact with the light-emitting layer. The hole-blocking layer has an electron-transport property and contains a material capable of blocking holes. Any of the materials having a hole-blocking property among the above electron-transport materials can be used for the hole-blocking layer.

The hole-blocking layer has an electron-transport property, and thus can also be referred to as an electron-transport layer. A layer having a hole-blocking property among the electron-transport layers can also be referred to as a hole-blocking layer.

The electron-injection layer injects electrons from the cathode to the electron-transport layer and contains a material with a high electron-injection property. As the material with a high electron-injection property, an alkali metal, an alkaline earth metal, or a compound thereof can be used. As the material with a high electron-injection property, a composite material containing an electron-transport material and a donor material (electron-donating material) can also be used.

A difference between the LUMO level of the material with a high electron-injection property and the work function value of the material used for a cathode is preferably small (specifically, smaller than or equal to 0.5 eV).

The electron-injection layer can be formed using, for example, an alkali metal, an alkaline earth metal, or a compound thereof, such as lithium, cesium, ytterbium, lithium fluoride (LiF), cesium fluoride (CsF), calcium fluoride (CaFₓ, where X is a given number), 8-(quinolinolato) lithium (abbreviation: Liq), 2-(2-pyridyl) phenolatolithium (abbreviation: LiPP), 2-(2-pyridyl)-3-pyridinolatolithium (abbreviation: LiPPy), 4-phenyl-2-(2-pyridyl) phenolatolithium (abbreviation: LiPPP), lithium oxide (LiOₓ), or cesium carbonate. The electron-injection layer may have a stacked-layer structure of two or more layers. The stacked-layer structure can be, for example, a structure where lithium fluoride is used for the first layer and ytterbium is used for the second layer.

The electron-injection layer may contain an electron-transport material. For example, a compound having an unshared electron pair and an electron deficient heteroaromatic ring can be used as the electron-transport material. Specifically, a compound having at least one of a pyridine ring, a diazine ring (a pyrimidine ring, a pyrazine ring, or a pyridazine ring), and a triazine ring can be used.

Note that the lowest unoccupied molecular orbital (LUMO) level of the organic compound having an unshared electron pair is preferably higher than or equal to −3.6 eV and lower than or equal to −2.3 eV. In general, the highest occupied molecular orbital (HOMO) level and the LUMO level of an organic compound can be estimated by CV (cyclic voltammetry), photoelectron spectroscopy, optical absorption spectroscopy, inverse photoelectron spectroscopy, or the like.

For example, 4,7-diphenyl-1,10-phenanthroline (abbreviation: BPhen), 2,9-di(naphthalen-2-yl)-4,7-diphenyl-1,10-phenanthroline (abbreviation: NBPhen), diquinoxalino[2,3-a:2′,3′-c]phenazine (abbreviation: HATNA), 2,4,6-tris[3′-(pyridin-3-yl) biphenyl-3-yl]-1,3,5-triazine (abbreviation: TmPPPyTz), or the like can be used for the organic compound having an unshared electron pair. Note that NBPhen has a higher glass transition temperature (Tg) than BPhen and thus has high heat resistance.

As described above, the charge-generation layer includes at least a charge-generation region. The charge-generation region preferably contains an acceptor material, and for example, preferably contains a hole-transport material and an acceptor material which can be used for the hole-injection layer.

The charge-generation layer preferably includes a layer containing a material having a high electron-injection property. The layer can also be referred to as an electron-injection buffer layer. The electron-injection buffer layer is preferably provided between the charge-generation region and the electron-transport layer. By provision of the electron-injection buffer layer, an injection barrier between the charge-generation region and the electron-transport layer can be lowered; thus, electrons generated in the charge-generation region can be easily injected into the electron-transport layer.

The electron-injection buffer layer preferably contains an alkali metal or an alkaline earth metal, and for example, can contain an alkali metal compound or an alkaline earth metal compound. Specifically, the electron-injection buffer layer preferably contains an inorganic compound containing an alkali metal and oxygen or an inorganic compound containing an alkaline earth metal and oxygen, further preferably contains an inorganic compound containing lithium and oxygen (lithium oxide (Li₂O) or the like). Alternatively, a material that can be used for the electron-injection layer can be suitably used for the electron-injection buffer layer.

The charge-generation layer preferably includes a layer containing a material having a high electron-transport property. The layer can also be referred to as an electron-relay layer. The electron-relay layer is preferably provided between the charge-generation region and the electron-injection buffer layer. In the case where the charge-generation layer does not include an electron-injection buffer layer, the electron-relay layer is preferably provided between the charge-generation region and the electron-transport layer. The electron-relay layer has a function of preventing interaction between the charge-generation region and the electron-injection buffer layer (or the electron-transport layer) and smoothly transferring electrons.

A phthalocyanine-based material such as copper (II) phthalocyanine (abbreviation: CuPc) or a metal complex having a metal-oxygen bond and an aromatic ligand is preferably used for the electron-relay layer.

Note that the charge-generation region, the electron-injection buffer layer, and the electron-relay layer cannot be clearly distinguished from each other in some cases on the basis of the cross-sectional shapes, the characteristics, or the like.

Note that the charge-generation layer may contain a donor material instead of an acceptor material. For example, the charge-generation layer may include a layer containing an electron-transport material and a donor material, which can be used for the electron-injection layer.

When the light-emitting units are stacked, provision of a charge-generation layer between two light-emitting units can inhibit an increase in driving voltage.

This embodiment can be combined with the other embodiments as appropriate.

### Embodiment 6

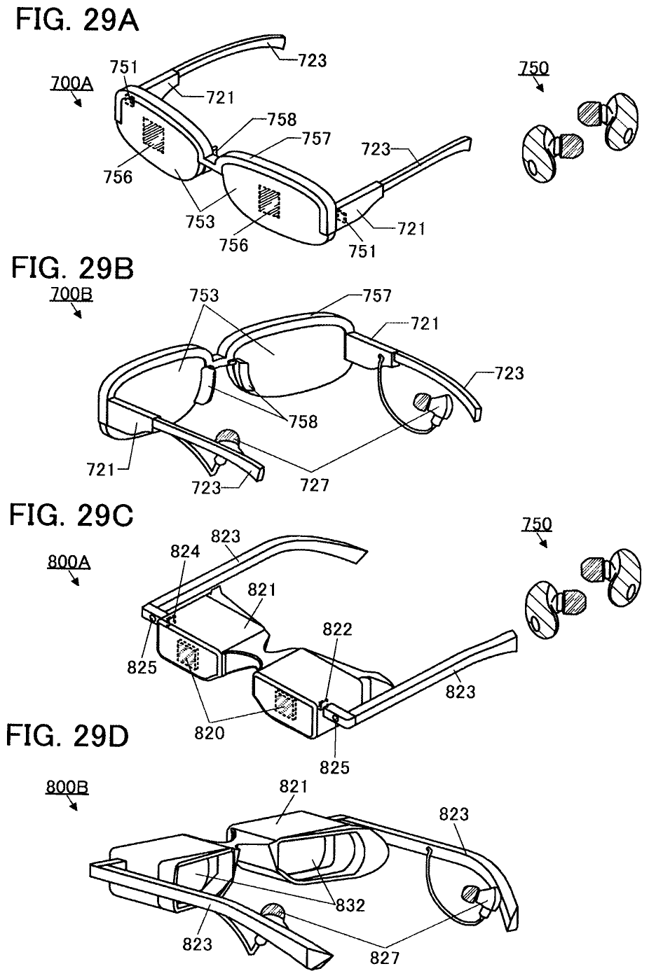

In this embodiment, electronic devices of one embodiment of the present invention are described with reference to FIG. 29 to FIG. 31.

Electronic devices of this embodiment each include the display apparatus of one embodiment of the present invention in a display portion. The display apparatus of one embodiment of the present invention can be easily increased in resolution and definition and can achieve high display quality. Thus, the display apparatus of one embodiment of the present invention can be used for a display portion of a variety of electronic devices.

Examples of electronic devices include electronic devices with a relatively large screen, such as a television device, a desktop or laptop personal computer, a monitor of a computer or the like, digital signage, and a large game machine such as a pachinko machine; a digital camera; a digital video camera; a digital photo frame; a mobile phone; a portable game machine; a portable information terminal; and an audio reproducing device.

In particular, the display apparatus of one embodiment of the present invention can have a high resolution, and thus can be suitably used for an electronic device having a relatively small display portion. Examples of such an electronic device include a watch-type or a bracelet-type information terminal (wearable device), and a wearable device that can be worn on a head, such as a device for VR like a head-mounted display, a glasses-type device for AR, and a device for MR (Mixed Reality).

The definition of the display apparatus of one embodiment of the present invention is preferably as high as HD (number of pixels: 1280×720), FHD (number of pixels: 1920×1080), WQHD (number of pixels: 2560×1440), WQXGA (number of pixels: 2560× 1600), 4K (number of pixels: 3840× 2160), or 8K (number of pixels: 7680× 4320). In particular, a definition of 4K, 8K, or higher is preferable. The pixel density (resolution) of the display apparatus of one embodiment of the present invention is preferably higher than or equal to 100 ppi, further preferably higher than or equal to 300 ppi, further preferably higher than or equal to 500 ppi, further preferably higher than or equal to 1000 ppi, still further preferably higher than or equal to 2000 ppi, still further preferably higher than or equal to 3000 ppi, still further preferably higher than or equal to 5000 ppi, yet further preferably higher than or equal to 7000 ppi. With the use of such a display apparatus having one or both of high definition and high resolution, the electronic device can provide higher realistic sensation, sense of depth, and the like in personal use such as portable use and home use. There is no particular limitation on the screen ratio (aspect ratio) of the display apparatus of one embodiment of the present invention. For example, the display apparatus is compatible with a variety of screen ratios such as 1:1 (a square), 4:3, 16:9, and 16:10.

The electronic device in this embodiment may include a sensor (a sensor having a function of sensing, detecting, or measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays).

The electronic device in this embodiment can have a variety of functions. For example, the electronic device can have a function of displaying a variety of information (a still image, a moving image, a text image, and the like) on the display portion, a touch panel function, a function of displaying a calendar, date, time, and the like, a function of executing a variety of software (programs), a wireless communication function, and a function of reading out a program or data stored in a recording medium.

Examples of a wearable device that can be worn on a head are described with reference to FIG. 29A to FIG. 29D. These wearable devices have one or both of a function of displaying AR contents and a function of displaying VR contents. Note that these wearable devices may have a function of displaying SR (Substitutional Reality) or MR contents, in addition to AR and VR contents. The electronic device having a function of displaying contents of at least one of AR, VR, SR, MR, and the like enables the user to reach a higher level of immersion.

An electronic device 700A illustrated in FIG. 29A and an electronic device 700B illustrated in FIG. 29B each include a pair of display panels 751, a pair of housings 721, a communication portion (not illustrated), a pair of wearing portions 723, a control portion (not illustrated), an image capturing portion (not illustrated), a pair of optical members 753, a frame 757, and a pair of nose pads 758.

The display apparatus of one embodiment of the present invention can be used for the display panels 751. Thus, the electronic devices are capable of performing ultrahigh-resolution display.

The electronic device 700A and the electronic device 700B can each project images displayed on the display panels 751 onto display regions 756 of the optical members 753. Since the optical members 753 have a light-transmitting property, a user can see images displayed on the display regions, which are superimposed on transmission images seen through the optical members 753. Accordingly, the electronic device 700A and the electronic device 700B are electronic devices capable of AR display.

In the electronic device 700A and the electronic device 700B, a camera capable of capturing images of the front side may be provided as the image capturing portion. Furthermore, when the electronic device 700A and the electronic device 700B are provided with an acceleration sensor such as a gyroscope sensor, the orientation of the user's head can be sensed and an image corresponding to the orientation can be displayed on the display regions 756.

The communication portion includes a wireless communication device, and a video signal and the like can be supplied by the wireless communication device. Instead of or in addition to the wireless communication device, a connector that can be connected to a cable for supplying a video signal and a power supply potential may be provided.

The electronic device 700A and the electronic device 700B are provided with a battery so that they can be charged wirelessly and/or by wire.

A touch sensor module may be provided in the housing 721. The touch sensor module has a function of detecting a touch on the outer surface of the housing 721. Detecting a tap operation, a slide operation, or the like by the user with the touch sensor module enables various types of processing. For example, a video can be paused or restarted by a tap operation, and can be fast-forwarded or fast-reversed by a slide operation. When the touch sensor module is provided in each of the two housings 721, the range of the operation can be increased.

Various touch sensors can be applied to the touch sensor module. For example, any of touch sensors of the following types can be used: a capacitive type, a resistive type, an infrared type, an electromagnetic induction type, a surface acoustic wave type, and an optical type. In particular, a capacitive sensor or an optical sensor is preferably used for the touch sensor module.

In the case of using an optical touch sensor, a photoelectric conversion device (also referred to as a photoelectric conversion element) can be used as a light-receiving device (also referred to as a light-receiving element). One or both of an inorganic semiconductor and an organic semiconductor can be used for an active layer of the photoelectric conversion device.

An electronic device 800A illustrated in FIG. 29C and an electronic device 800B illustrated in FIG. 29D each include a pair of display portions 820, a housing 821, a communication portion 822, a pair of wearing portions 823, a control portion 824, a pair of image capturing portions 825, and a pair of lenses 832.

The display apparatus of one embodiment of the present invention can be used in the display portions 820. Thus, the electronic devices are capable of performing ultrahigh-resolution display. Such electronic devices provide an enhanced sense of immersion to the user.

The display portions 820 are positioned inside the housing 821 so as to be seen through the lenses 832. When the pair of the display portions 820 display different images, three-dimensional display using parallax can be performed.

The electronic device 800A and the electronic device 800B can be regarded as electronic devices for VR. The user who wears the electronic device 800A or the electronic device 800B can see images displayed on the display portions 820 through the lenses 832.

The electronic device 800A and the electronic device 800B preferably include a mechanism for adjusting the lateral positions of the lenses 832 and the display portions 820 so that the lenses 832 and the display portions 820 are positioned optimally in accordance with the positions of the user's eyes. Moreover, the electronic device 800A and the electronic device 800B preferably include a mechanism for adjusting focus by changing the distance between the lenses 832 and the display portions 820.

The electronic device 800A or the electronic device 800B can be worn on the user's head with the wearing portions 823. FIG. 29C or the like illustrates an example where the wearing portion 823 has a shape like a temple (also referred to as a joint or the like) of glasses; however, one embodiment of the present invention is not limited thereto. The wearing portion 823 can have any shape with which the user can wear the electronic device, for example, a shape of a helmet or a band.

The image capturing portion 825 has a function of obtaining information on the external environment. Data obtained by the image capturing portion 825 can be output to the display portion 820. An image sensor can be used for the image capturing portion 825. Moreover, a plurality of cameras may be provided so as to support a plurality of fields of view, such as a telescope field of view and a wide field of view.

Although an example where the image capturing portions 825 are provided is shown here, a range sensor capable of measuring a distance between the user and an object (hereinafter also referred to as a sensing portion) just needs to be provided. In other words, the image capturing portion 825 is one embodiment of the sensing portion. For the sensing portion, an image sensor or a distance image sensor such as LIDAR (Light Detection and Ranging) can be used, for example. By using images obtained by a camera and images obtained by the distance image sensor, more information can be obtained and a gesture operation with higher accuracy is possible.

The electronic device 800A may include a vibration mechanism that functions as bone-conduction earphones. For example, any one or more of the display portion 820, the housing 821, and the wearing portion 823 can employ a structure including the vibration mechanism. Thus, without additionally requiring an audio device such as headphones, earphones, or a speaker, the user can enjoy video and sound only by wearing the electronic device 800A.

The electronic device 800A and the electronic device 800B may each include an input terminal. To the input terminal, a cable for supplying a video signal from a video output device or the like, power for charging the battery provided in the electronic device, and the like can be connected.

The electronic device of one embodiment of the present invention may have a function of performing wireless communication with earphones 750. The earphones 750 include a communication portion (not illustrated) and has a wireless communication function. The earphones 750 can receive information (e.g., audio data) from the electronic device with the wireless communication function. For example, the electronic device 700A in FIG. 29A has a function of transmitting information to the earphones 750 with the wireless communication function. As another example, the electronic device 800A illustrated in FIG. 29C has a function of transmitting information to the earphones 750 with the wireless communication function.

The electronic device may include an earphone portion. The electronic device 700B in FIG. 29B includes earphone portions 727. For example, the earphone portion 727 and the control portion can be connected to each other by wire. Part of a wiring that connects the earphone portion 727 and the control portion may be positioned inside the housing 721 or the wearing portion 723.

Similarly, the electronic device 800B illustrated in FIG. 29D includes earphone portions 827. For example, the earphone portion 827 and the control portion 824 are connected to each other by wire. Part of a wiring that connects the earphone portion 827 and the control portion 824 may be positioned inside the housing 821 or the wearing portion 823. Alternatively, the earphone portions 827 and the wearing portions 823 may include magnets. This is preferable because the earphone portions 827 can be fixed to the wearing portions 823 with magnetic force and thus can be easily housed.

The electronic device may include an audio output terminal to which earphones, headphones, or the like can be connected. The electronic device may include one or both of an audio input terminal and an audio input mechanism. As the audio input mechanism, a sound collecting device such as a microphone can be used, for example. The electronic device may have a function of what is called a headset by including the audio input mechanism.

As described above, both the glasses-type device (e.g., the electronic device 700A and the electronic device 700B) and the goggles-type device (e.g., the electronic device 800A and the electronic device 800B) are preferable as the electronic device of one embodiment of the present invention.

The electronic device of one embodiment of the present invention can transmit information to earphones by wire or wirelessly.

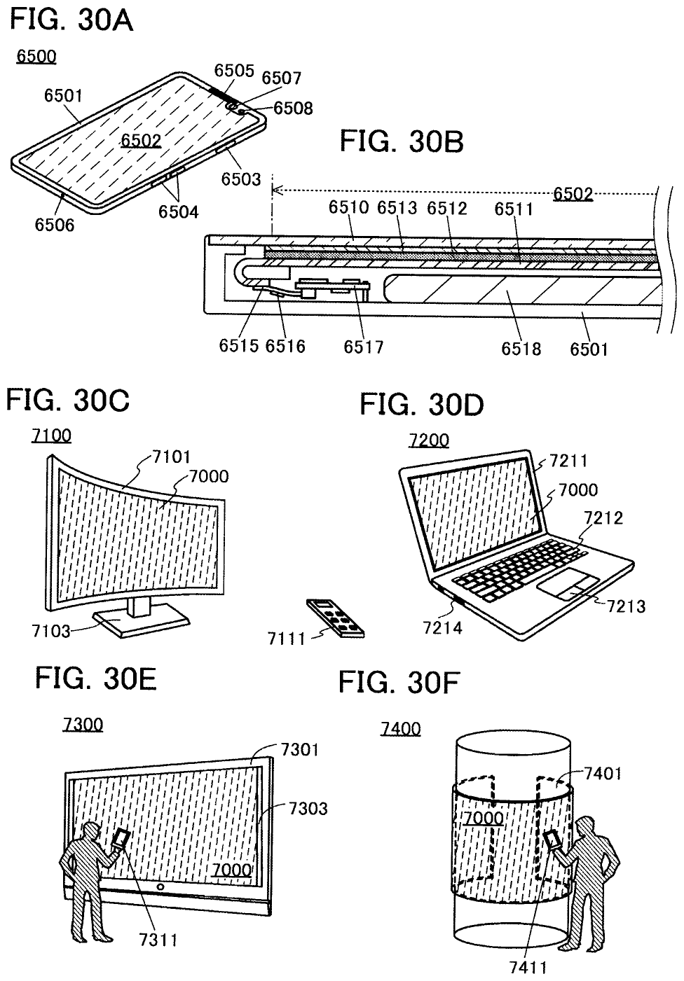

An electronic device 6500 illustrated in FIG. 30A is a portable information terminal that can be used as a smartphone.

The electronic device 6500 includes a housing 6501, a display portion 6502, a power button 6503, buttons 6504, a speaker 6505, a microphone 6506, a camera 6507, a light source 6508, and the like. The display portion 6502 has a touch panel function.

The display apparatus of one embodiment of the present invention can be used for the display portion 6502.

FIG. 30B is a schematic cross-sectional view including an end portion of the housing 6501 on the microphone 6506 side.

A protection member 6510 having a light-transmitting property is provided on a display surface side of the housing 6501, and a display apparatus 6511, an optical member 6512, a touch sensor panel 6513, a printed circuit board 6517, a battery 6518, and the like are provided in a space surrounded by the housing 6501 and the protection member 6510.

The display apparatus 6511, the optical member 6512, and the touch sensor panel 6513 are fixed to the protection member 6510 with an adhesive layer (not illustrated).

Part of the display apparatus 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

A flexible display of one embodiment of the present invention can be used as the display apparatus 6511. Thus, an extremely lightweight electronic device can be achieved. Since the display apparatus 6511 is extremely thin, the battery 6518 with high capacity can be mounted without an increase in the thickness of the electronic device. Moreover, part of the display apparatus 6511 is folded back so that a connection portion with the FPC 6515 is provided on the back side of a pixel portion, whereby an electronic device with a narrow bezel can be achieved.

FIG. 30C illustrates an example of a television device. In a television device 7100, a display portion 7000 is incorporated in a housing 7101. Here, the housing 7101 is supported by a stand 7103.

The display apparatus of one embodiment of the present invention can be used for the display portion 7000.

Operation of the television device 7100 illustrated in FIG. 30C can be performed with an operation switch provided in the housing 7101 and a separate remote controller 7111. Alternatively, the display portion 7000 may include a touch sensor, and the television device 7100 may be operated by touch on the display portion 7000 with a finger or the like. The remote controller 7111 may be provided with a display portion for displaying information output from the remote controller 7111. With operation keys or a touch panel provided in the remote controller 7111, channels and volume can be controlled and videos displayed on the display portion 7000 can be operated.

Note that the television device 7100 has a structure in which a receiver, a modem, and the like are provided. A general television broadcast can be received with the receiver. When the television device is connected to a communication network by wire or wirelessly via the modem, one-way (from a transmitter to a receiver) or two-way (between a transmitter and a receiver or between receivers, for example) information communication can be performed.

FIG. 30D illustrates an example of a laptop personal computer. A laptop personal computer 7200 includes a housing 7211, a keyboard 7212, a pointing device 7213, an external connection port 7214, and the like. In the housing 7211, the display portion 7000 is incorporated.

The display apparatus of one embodiment of the present invention can be used for the display portion 7000.

FIG. 30E and FIG. 30F illustrate examples of digital signage.

Digital signage 7300 illustrated in FIG. 30E includes a housing 7301, the display portion 7000, a speaker 7303, and the like. The digital signage 7300 can also include an LED lamp, an operation key (including a power switch or an operation switch), a connection terminal, a variety of sensors, a microphone, and the like.

FIG. 30F is digital signage 7400 attached to a cylindrical pillar 7401. The digital signage 7400 includes the display portion 7000 provided along a curved surface of the pillar 7401.

The display apparatus of one embodiment of the present invention can be used for the display portion 7000 illustrated in each of FIG. 30E and FIG. 30F.

A larger area of the display portion 7000 can increase the amount of information that can be provided at a time. The larger the display portion 7000 attracts more attention, so that the effectiveness of the advertisement can be increased, for example.

The use of a touch panel in the display portion 7000 is preferable because in addition to display of a still image or a moving image on the display portion 7000, intuitive operation by a user is possible. Moreover, for an application for providing information such as route information or traffic information, usability can be enhanced by intuitive operation.

As illustrated in FIG. 30E and FIG. 30F, it is preferable that the digital signage 7300 or the digital signage 7400 can work with an information terminal 7311 or an information terminal 7411 such as a smartphone a user has through wireless communication. For example, information of an advertisement displayed on the display portion 7000 can be displayed on a screen of the information terminal 7311 or the information terminal 7411. By operation of the information terminal 7311 or the information terminal 7411, display on the display portion 7000 can be switched.

It is possible to make the digital signage 7300 or the digital signage 7400 execute a game with the use of the screen of the information terminal 7311 or the information terminal 7411 as an operation means (controller). Thus, an unspecified number of users can join in and enjoy the game concurrently.

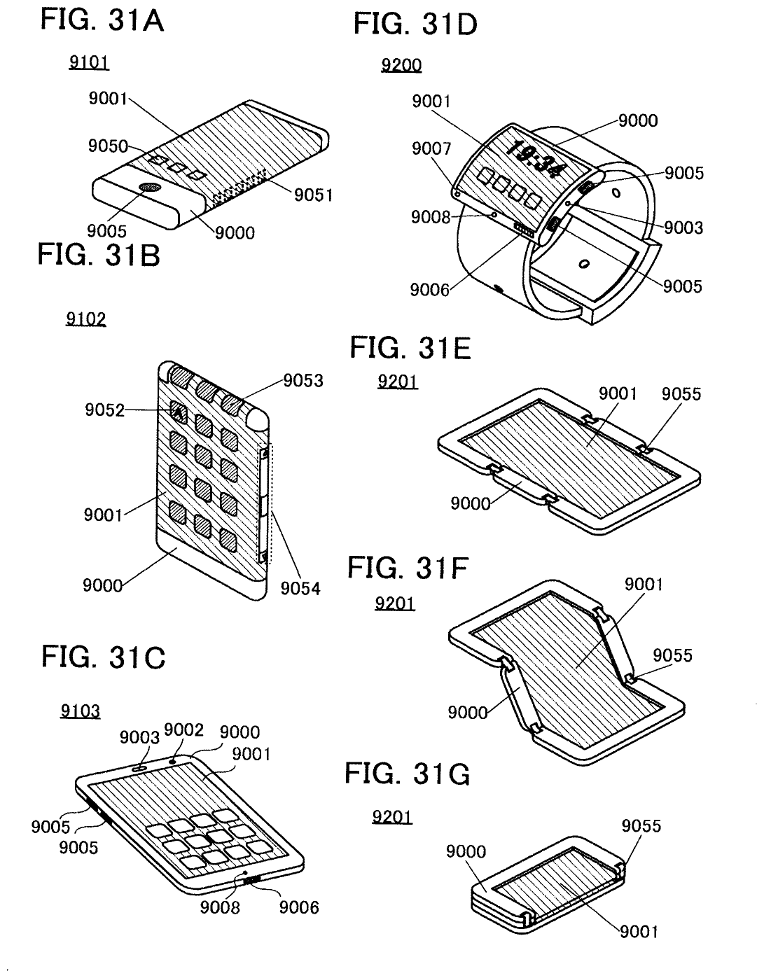

Electronic devices illustrated in FIG. 31A to FIG. 31G each include a housing 9000, a display portion 9001, a speaker 9003, an operation key 9005 (including a power switch or an operation switch), a connection terminal 9006, a sensor 9007 (a sensor having a function of sensing, detecting, or measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays), a microphone 9008, and the like.

The display apparatus of one embodiment of the present invention can be used for the display portion 9001 in FIG. 31A to FIG. 31G.

The electronic devices illustrated in FIG. 31A to FIG. 31G have a variety of functions. For example, the electronic devices can have a function of displaying a variety of information (a still image, a moving image, a text image, and the like) on the display portion, a touch panel function, a function of displaying a calendar, date, time, and the like, a function of controlling processing with the use of a variety of software (programs), a wireless communication function, and a function of reading out and processing a program or data stored in a recording medium. Note that the functions of the electronic devices are not limited thereto, and the electronic devices can have a variety of functions. The electronic devices may include a plurality of display portions. In addition, the electronic devices may each include a camera or the like and have a function of capturing a still image or a moving image and storing the captured image in a recording medium (an external recording medium or a recording medium incorporated in the camera), a function of displaying the captured image on the display portion, or the like.

The details of the electronic devices illustrated in FIG. 31A to FIG. 31G are described below.

FIG. 31A is a perspective view illustrating a portable information terminal 9101. The portable information terminal 9101 can be used as a smartphone, for example. Note that the portable information terminal 9101 may include the speaker 9003, the connection terminal 9006, the sensor 9007, or the like. The portable information terminal 9101 can display characters and image information on its plurality of surfaces. FIG. 31A illustrates an example where three icons 9050 are displayed. Furthermore, information 9051 indicated by dashed rectangles can be displayed on another surface of the display portion 9001. Examples of the information 9051 include notification of reception of an e-mail, an SNS message, or an incoming call, the title and sender of an e-mail, an SNS message, or the like, the date, the time, remaining battery, and the radio field intensity. Alternatively, the icon 9050 or the like may be displayed at the position where the information 9051 is displayed.

FIG. 31B is a perspective view illustrating a portable information terminal 9102. The portable information terminal 9102 has a function of displaying information on three or more surfaces of the display portion 9001. Here, an example is illustrated in which information 9052, information 9053, and information 9054 are displayed on different surfaces. For example, a user can check the information 9053 displayed in a position that can be observed from above the portable information terminal 9102, with the portable information terminal 9102 put in a breast pocket of his/her clothes. The user can see the display without taking out the portable information terminal 9102 from the pocket and decide whether to answer the call, for example.

FIG. 31C is a perspective view illustrating a tablet terminal 9103. The tablet terminal 9103 is capable of executing a variety of applications such as mobile phone calls, e-mailing, viewing and editing texts, music reproduction, Internet communication, and a computer game, for example. The tablet terminal 9103 includes the display portion 9001, a camera 9002, the microphone 9008, and the speaker 9003 on the front surface of the housing 9000; the operation keys 9005 as buttons for operation on the left side surface of the housing 9000; and the connection terminal 9006 on the bottom surface of the housing 9000.

FIG. 31D is a perspective view illustrating a watch-type portable information terminal 9200. For example, the portable information terminal 9200 can be used as a Smartwatch (registered trademark). The display surface of the display portion 9001 is curved, and display can be performed on the curved display surface. Furthermore, for example, mutual communication between the portable information terminal 9200 and a headset capable of wireless communication can be performed, and thus hands-free calling is possible. With the connection terminal 9006, the portable information terminal 9200 can perform mutual data transmission with another information terminal and charging. Note that the charging operation may be performed by wireless power feeding.

FIG. 31E to FIG. 31G are perspective views illustrating a foldable portable information terminal 9201. FIG. 31E is a perspective view of an opened state of the portable information terminal 9201, FIG. 31G is a perspective view of a folded state thereof, and FIG. 31F is a perspective view of a state in the middle of change from one of FIG. 31E and FIG. 31G to the other. The portable information terminal 9201 is highly portable in the folded state and is highly browsable in the opened state because of a seamless large display region. The display portion 9001 of the portable information terminal 9201 is supported by three housings 9000 joined together by hinges 9055. The display portion 9001 can be folded with a radius of curvature of greater than or equal to 0.1 mm and less than or equal to 150 mm, for example.

This embodiment can be combined with the other embodiments as appropriate.

### Example

Described in this example are results of observing the pixel electrode 111 fabricated by the method illustrated in FIG. 9A to FIG. 9E and the EL layer 113 fabricated over the pixel electrode 111 by the method illustrated in FIG. 7A and FIG. 7B, with a scanning transmission electron microscopy (STEM).

In this example, Samples 1A, 1B, 1C, and 1D in each of which the EL layer 113 was formed over the pixel electrode 111 were fabricated by the method described in the above embodiments. Sample 1A and Sample 1B each have a deep depressed portion formed in the insulating layer 255c and Sample 1C and Sample ID each have the pixel electrode 111 with a large thickness.

A method for fabricating Sample 1A to Sample 1D will be described below. First, methods for fabricating the pixel electrode 111 will be described with reference to FIG. 9A to FIG. 9E.

First, as illustrated in FIG. 9A, the insulating layer 255c, the conductive film 11aA, the conductive film 11bA, the conductive film 11cA, and the conductive film 11dA were formed in this order over a silicon substrate, in each of Sample 1A to Sample 1D.

The insulating layer 255c was a silicon oxide film deposited by a PECVD method. The conductive film 11aA was a titanium film with a thickness of 50 nm formed by a DC sputtering method. The conductive film 11bA was an aluminum film formed by a DC sputtering method.

The conductive film 11cA was a titanium film with a thickness of 6 nm formed by a DC sputtering method. Note that the conductive film 11aA, the conductive film 11bA, and the conductive film 11cA were successively formed without exposure to the air. After the formation of the conductive film 11aA, the conductive film 11bA, and the conductive film 11cA, heat treatment was performed at 300° C. in an air atmosphere for one hour; as a result, the conductive film 11cA was oxidized into titanium oxide.

Here, the conductive film 11bA was formed to have a target thickness of 70 nm in Sample 1A and Sample 1B, the conductive film 11bA was formed to have a target thickness of 100 nm in Sample 1C, and the conductive film 11bA was formed to have a target thickness of 180 nm in Sample 1D. Thus, the pixel electrode 111 in Sample 1C and Sample 1D had a larger thickness than that in Sample 1A and Sample 1B, and the pixel electrode 111 in Sample 1D had a larger thickness than that in Sample 1C.

The conductive film 11dA was an indium tin oxide film containing silicon with a thickness of 10 nm. The conductive film 11dA was formed by a DC sputtering method using an indium tin oxide target containing 5 wt % of silicon oxide.

Next, as illustrated in FIG. 9A, the resist mask 12 was formed over the conductive film 11dA in each of Sample 1A to Sample 1D. For the resist mask 12, a positive-type photoresist with a thickness of 1.5 μm was used.

Next, as illustrated in FIG. 9B, wet etching was performed on the conductive film 11dA to form the conductive layer 11d in each of Sample 1A to Sample 1D. For the wet etching of the conductive film 11dA, ITO-07N (produced by KANTO CHEMICAL CO., INC.) was used.

Next, in Sample 1A to Sample 1D, dry etching was performed on the conductive film 11cA, the conductive film 11bA, and the conductive film 11aA to form the conductive layer 11c, the conductive layer 11b, and the conductive layer 11a as illustrated in FIG. 9C. In the dry etching of the conductive film 11cA, the conductive film 11bA, and the conductive film 11aA, 60 sccm of a BCl₃ gas and 20 sccm of a Cl₂ gas were used as etching gases, the pressure was 1.9 Pa, the ICP power was 450 W, the bias power was 100 W, and the substrate temperature was 70° C. Note that since the thickness of the conductive film 11bA differs among Sample 1A to Sample 1D, the etching time was set as appropriate for each of Sample 1A to Sample 1D.

Here, in the above conditions, the etching rates of the conductive film 11cA, the conductive film 11bA, and the conductive film 11aA are different from each other. Thus, the side surfaces of the conductive layer 11a and the conductive layer 11c had a shape projecting from the side surface of the conductive layer 11b as illustrated in FIG. 9C.

Next, in Sample 1A to Sample 1D, dry etching was performed on the exposed insulating layer 255c to form the depressed portion in the insulating layer 255c as illustrated in FIG. 9D. In the dry etching of the insulating layer 255c, 80 sccm of an CF₄ gas was used as an etching gas, the pressure was 2.0 Pa, the ICP power was 500 W, the bias power was 50 W, and the substrate temperature was 70° C.

Here, in the etching step in FIG. 9D, the processing time of Sample 1A was 60 seconds, the processing time of Sample 1B was 120 seconds, and the processing time of Sample 1C and Sample 1D was 15 seconds. Accordingly, in Sample 1A, the depth T2 of the depressed portion of the insulating layer 255c became greater than that in Sample 1C and Sample 1D, and in Sample 1B, the depth T2 of the depressed portion of the insulating layer 255c became greater than that in Sample 1A.

Next, in Sample 1A to Sample 1D, as illustrated in FIG. 9E, the resist mask 12 over the conductive layer 11d was removed by plasma ashing using an oxygen gas and wet etching. Accordingly, the pixel electrode 111 (the conductive layer 11a, the conductive layer 11b, the conductive layer 11c, and the conductive layer 11d) was able to be formed over the insulating layer 255c in each of Sample 1A to Sample 1D.

In such a manner, a plurality of the pixel electrodes 111 was able to be formed in Sample 1A to Sample 1D as illustrated in FIG. 7A. Next, in Sample 1A to Sample 1D, an EL film was formed over the insulating layer 255c and the pixel electrode 111. The EL film was formed to have a target thickness of 180 nm using an evaporation method.

As illustrated in FIG. 7B, the EL film became the first layer 113a over the pixel electrode 111a, the second layer 113b over the pixel electrode 111b, and the fourth layer 113d between the pixel electrode 111a and the pixel electrode 111b.

Furthermore, an aluminum oxide film with a thickness of 15 nm was formed to cover the EL film using an ALD method.

Cross-sectional STEM images of Sample 1A to Sample 1D fabricated in the above manner were captured. The cross-sectional STEM images of Sample 1A to Sample 1D were captured at an acceleration voltage of 200 kV with “HD-2300” produced by Hitachi High-Technologies Corporation.

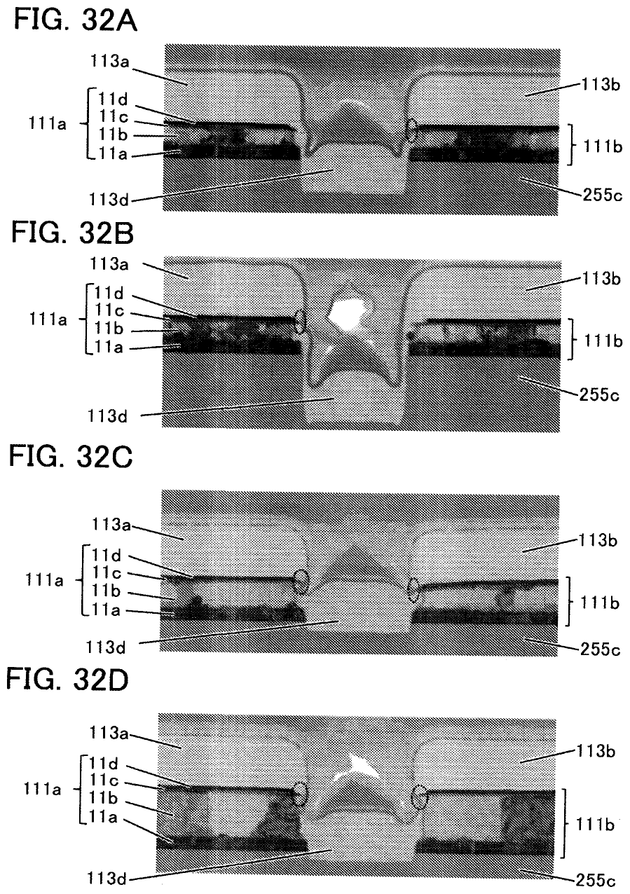

FIG. 32A to FIG. 32D show the cross-sectional STEM images of Sample 1A to Sample 1D. FIG. 32A is the cross-sectional STEM image of Sample 1A, FIG. 32B is the cross-sectional STEM image of Sample 1B, FIG. 32C is the cross-sectional STEM image of Sample 1C, and FIG. 32D is the cross-sectional STEM image of Sample 1D.

As shown in FIG. 32A to FIG. 32D, in each of Sample 1A to Sample 1D, the first layer 113a is formed over the pixel electrode 111a and the second layer 113b is formed over the pixel electrode 111b. The fourth layer 113d is formed in a region of the insulating layer 255c where the depressed portion is formed, which is between the pixel electrode 111a and the pixel electrode 111b.

Here, a region surrounded by a dotted line in FIG. 32A to FIG. 32D represents a region where the first layer 113a and the fourth layer 113d or the second layer 113b and the fourth layer 113d are separated from each other. That is, the second layer 113b and the fourth layer 113d are separated from each other in Sample 1A, the first layer 113a and the fourth layer 113d are separated from each other in Sample 1B, and the first layer 113a and the second layer 113b are separated from the four layer 113d in each of Sample 1C and Sample 1D.

Table 1 shows the thickness T1a of the conductive layer 11a and the conductive layer 11b, the depth T2 of the depressed portion of the insulating layer 255c, the sum of the thickness T1a and the depth T2, and the thickness T3 of the fourth layer 113d in Sample 1A to Sample 1D.

TABLE 1

| | Thickness | Depth | Thickness | Thickness |
|---|---|---|---|---|
| | T1a | T2 | T1a + depth | T3 |
| Sample | [nm] | [nm] | T2 [nm] | [nm] |
| 1A | 122 | 126 | 248 | 192 |
| 1B | 126 | 253 | 379 | 192 |
| 1C | 151 | 37.2 | 188 | 188 |
| 1D | 232 | 34.7 | 267 | 191 |

As shown in Table 1, the sum of the thickness T1a and the depth T2 is larger than or equal to the thickness T3 in each of Sample 1A to Sample 1D. That is, it is confirmed that when the sum of the thickness T1a and the depth T2 is greater than or equal to the thickness T3, at least one of the first layer 113a and the fourth layer 113d, and the second layer 113b and the fourth layer 113d are separated from each other.

In this manner, the EL layer 113 formed over the pixel electrode 111 and the fourth layer 113d formed between the pixel electrodes 111 can be separated from each other by increasing the step formed by the pixel electrode 111 and the depressed portion of the insulating layer 255c. Accordingly, leakage current between the light-emitting devices can be inhibited or sufficiently reduced.

### REFERENCE NUMERALS

AL: wiring, CL: wiring, GL: wiring, RL: wiring, SL: wiring, SLB: wiring, SLG: wiring, SLR: wiring, 11a: conductive layer, 11aA: conductive film, 11b: conductive layer, 11bA: conductive film, 11c: conductive layer, 11cA: conductive film, 11d: conductive layer, 11dA: conductive film, 12: resist mask, 100A: display apparatus, 100B: display apparatus, 100C: display apparatus, 100D: display apparatus, 100E: display apparatus, 100F: display apparatus, 100G: display apparatus, 100H: display apparatus, 100: display apparatus, 101: substrate, 102: substrate, 107: adhesive layer, 108: light-blocking layer, 109a: projecting portion, 109b: projecting portion, 110a: subpixel, 110B: subpixel, 110b: subpixel, 110c: subpixel, 110d: subpixel, 110G: subpixel, 110R: subpixel, 110: pixel, 111a: pixel electrode, 111b: pixel electrode, 111c: pixel electrode, 111: pixel electrode, 112a: conductive layer, 112b: conductive layer, 112c: conductive layer, 113a: first layer, 113b: second layer, 113c: third layer, 113d: fourth layer, 113: EL layer, 114: common layer, 115: common electrode, 123: conductive layer, 124a: pixel, 124b: pixel, 125A: insulating film, 125: insulating layer, 126a: conductive layer, 126b: conductive layer, 126c: conductive layer, 127A: insulating layer, 127: insulating layer, 128: layer, 129a: conductive layer, 129b: conductive layer, 129c: conductive layer, 130a: light-emitting device, 130B: light-emitting device, 130b: light-emitting device, 130c: light-emitting device, 130G: light-emitting device, 130R: light-emitting device, 130: light-emitting device, 131: protective layer, 132a: coloring layer, 132b: coloring layer, 132c: coloring layer, 132: coloring layer, 140: connection portion, 147: resin layer, 151: substrate, 152: substrate, 153: insulating layer, 162: display portion, 164: circuit, 165: wiring, 166: conductive layer, 172: FPC, 173: IC, 201: transistor, 204: connection portion, 205: transistor, 209: transistor, 210: transistor, 211: insulating layer, 213: insulating layer, 214: insulating layer, 215: insulating layer, 218: insulating layer, 221: conductive layer, 222a: conductive layer, 222b: conductive layer, 223: conductive layer, 225: insulating layer, 231i: channel formation region, 231n: low-resistance region, 231: semiconductor layer, 240: capacitor, 241: conductive layer, 242: connection layer, 243: insulating layer, 245: conductive layer, 251: conductive layer, 252: conductive layer, 254: insulating layer, 255a: insulating layer, 255b: insulating layer, 255c: insulating layer, 256: plug, 261: insulating layer, 262: insulating layer, 263: insulating layer, 264: insulating layer, 265: insulating layer, 271: plug, 274a: conductive layer, 274b: conductive layer, 274: plug, 280: display module, 281: display portion, 282: circuit portion, 283a: pixel circuit, 283: pixel circuit portion, 284a: pixel, 284: pixel portion, 285: terminal portion, 286: wiring portion, 290: FPC, 291: substrate, 292: substrate, 301A: substrate, 301B: substrate, 301: substrate, 310A: transistor, 310B: transistor, 310: transistor, 311: conductive layer, 312: low-resistance region, 313: insulating layer, 314: insulating layer, 315: element isolation layer, 320A: transistor, 320B: transistor, 320: transistor, 321: semiconductor layer, 323: insulating layer, 324: conductive layer, 325: conductive layer, 326: insulating layer, 327: conductive layer, 328: insulating layer, 329: insulating layer, 331: substrate, 332: insulating layer, 335: insulating layer, 336: insulating layer, 341: conductive layer, 342: conductive layer, 343: plug, 344: insulating layer, 345: insulating layer, 346: insulating layer, 347: bump, 348: adhesive layer, 400: display apparatus, 401: substrate, 402: driver circuit portion, 403: driver circuit portion, 404: display portion, 405B: subpixel, 405G: subpixel, 405R: subpixel, 405: pixel, 410a: transistor, 410: transistor, 411i: channel formation region, 411n: low-resistance region, 411: semiconductor layer, 412: insulating layer, 413: conductive layer, 414a: conductive layer, 414b: conductive layer, 415: conductive layer, 416: insulating layer, 421: insulating layer, 422: insulating layer, 423: insulating layer, 426: insulating layer, 430: pixel, 431: conductive layer, 450a: transistor, 450: transistor, 451: semiconductor layer, 452: insulating layer, 453: conductive layer, 454a: conductive layer, 454b: conductive layer, 455: conductive layer, 700A: electronic device, 700B: electronic device, 721: housing, 723: wearing portion, 727: earphone portion, 750: earphone, 751: display panel, 753: optical member, 756: display region, 757: frame, 758: nose pad, 761: lower electrode, 762: upper electrode, 763a: light-emitting unit, 763b: light-emitting unit, 763c: light-emitting unit, 763: EL layer, 764: layer, 771a: light-emitting layer, 771b: light-emitting layer, 771c: light-emitting layer, 771: light-emitting layer, 772a: light-emitting layer, 772b: light-emitting layer, 772c: light-emitting layer, 772: light-emitting layer, 773: light-emitting layer, 780a: layer, 780b: layer, 780c: layer, 780: layer, 781: layer, 782: layer, 785: charge-generation layer, 790a: layer, 790b: layer, 790c: layer, 790: layer, 791: layer, 792: layer, 800A: electronic device, 800B: electronic device, 820: display portion, 821: housing, 822: communication portion, 823: wearing portion, 824: control portion, 825: image capturing portion, 827: earphone portion, 832: lens, 6500: electronic device, 6501: housing, 6502: display portion, 6503: power button, 6504: button, 6505: speaker, 6506: microphone, 6507: camera, 6508: light source, 6510: protection member, 6511: display apparatus, 6512: optical member, 6513: touch sensor panel, 6515: FPC, 6516: IC, 6517: printed circuit board, 6518: battery, 7000: display portion, 7100: television device, 7101: housing, 7103: stand, 7111: remote controller, 7200: laptop personal computer, 7211: housing, 7212: keyboard, 7213: pointing device, 7214: external connection port, 7300: digital signage, 7301: housing, 7303: speaker, 7311: information terminal, 7400: digital signage, 7401: pillar, 7411: information terminal, 9000: housing, 9001: display portion, 9002: camera, 9003: speaker, 9005: operation key, 9006: connection terminal, 9007: sensor, 9008: microphone, 9050: icon, 9051: information, 9052: information, 9053: information, 9054: information, 9055: hinge, 9101: portable information terminal, 9102: portable information terminal, 9103: tablet terminal, 9200: portable information terminal, 9201: portable information terminal

1. A display apparatus comprising a first light-emitting device, a second light-emitting device, a first coloring layer, a second coloring layer, and a first insulating layer,
wherein the first light-emitting device comprises a first pixel electrode over the first insulating layer, a first EL layer over the first pixel electrode, and a common electrode over the first EL layer,
wherein the second light-emitting device comprises a second pixel electrode over the first insulating layer, a second EL layer over the second pixel electrode, and the common electrode over the second EL layer,
wherein the first coloring layer is provided to overlap with the first light-emitting device,
wherein the second coloring layer is provided to overlap with the second light-emitting device,
wherein the first coloring layer and the second coloring layer transmit light of different wavelength ranges,
wherein the first insulating layer comprises a depressed portion between the first pixel electrode and the second pixel electrode,
wherein a third EL layer is provided in the depressed portion of the first insulating layer,
wherein the first EL layer, the second EL layer, and the third EL layer contain the same material, and
wherein a sum of a thickness of the first pixel electrode and a depth of the depressed portion is larger than a thickness of the third EL layer.

2. The display apparatus according to claim 1,
wherein the third EL layer is in contact with a bottom surface and a side surface of the depression portion of the first insulating layer, a side surface of the first pixel electrode, and a side surface of the second pixel electrode.

3. The display apparatus according to claim 1,
wherein the thickness of the first pixel electrode is larger than or equal to the thickness of the third EL layer.

4. The display apparatus according to claim 1,
wherein the depth of the depressed portion is larger than or equal to the thickness of the third EL layer, and
wherein the third EL layer is not in contact with neither the first pixel electrode nor the second pixel electrode.

5. The display apparatus according to claim 1,
wherein each of the first pixel electrode and the second pixel electrode comprises a first conductive layer over the first insulating layer and a second conductive layer over the first conductive layer, and
wherein a side surface of the second conductive layer projects from a side surface of the first conductive layer.

6. The display apparatus according to claim 5,
wherein a sum of the thickness of the first pixel electrode in a portion lower than a bottom surface of the second conductive layer and the depth of the depression portion is larger than or equal to the thickness of the third EL layer.

7. The display apparatus according to claim 5,
wherein each of the first pixel electrode and the second pixel electrode comprises a third conductive layer under the first conductive layer,
wherein the first conductive layer has a reflecting property, and
wherein the second conductive layer and the third conductive layer are configured to protect the first conductive layer.

8. The display apparatus according to claim 7,
wherein the first conductive layer contains aluminum.

9. The display apparatus according to claim 8,
wherein the second conductive layer contains titanium oxide.

10. The display apparatus according to claim 9,
wherein the third conductive layer contains titanium.

11. The display apparatus according to claim 10,
wherein the first pixel electrode and the second pixel electrode each comprise a fourth conductive layer over the second conductive layer,
wherein the fourth conductive layer has a higher work function than the second conductive layer,
wherein the second conductive layer and the fourth conductive layer have a light-transmitting property, and
wherein the fourth conductive layer contains an oxide containing any one or more selected from indium, tin, zinc, gallium, titanium, aluminum, and silicon.

12. The display apparatus according to claim 1,
further comprising a second insulating layer over the third EL layer and a third insulating layer over the second insulating layer,
wherein the second insulating layer contains an inorganic material,
wherein the third insulating layer contains an organic material,
wherein part of the second insulating layer and part of the third insulating layer are provided in a position interposed between a side surface of the first EL layer and a side surface of the first pixel electrode, and a side surface of the second EL layer and a side surface of the second pixel electrode, and
wherein another part of the third insulating layer overlaps with part of a top surface of the first EL layer and part of a top surface of the second EL layer with the second insulating layer therebetween.

13. The display apparatus according to claim 12,
wherein the second insulating layer is in contact with the side surface of the first pixel electrode and the side surface of the second pixel electrode.

14. The display apparatus according to claim 12,
wherein the common electrode is provided over the third insulating layer.

15. The display apparatus according to claim 12,
wherein the first light-emitting device comprises a common layer provided between the first EL layer and the common electrode, and
wherein the second light-emitting device comprises the common layer provided between the second EL layer and the common electrode.

16. The display apparatus according to claim 12,
wherein the first coloring layer and the second coloring layer are each provided over the common electrode.

17. The display apparatus according to claim 1,
wherein the first EL layer comprises a first light-emitting unit over the first pixel electrode, a first charge-generation layer over the first light-emitting unit, and a second light-emitting unit over the first charge-generation layer,
wherein the second EL layer comprises a third light-emitting unit over the second pixel electrode, a second charge-generation layer over the third light-emitting unit, and a fourth light-emitting unit over the second charge-generation layer, and
wherein the third EL layer comprises a fifth light-emitting unit over the first insulating layer, a third charge-generation layer over the fifth light-emitting unit, and a sixth light-emitting unit over the third charge-generation layer.

18. The display apparatus according to claim 17,
wherein the first light-emitting unit, the third light-emitting unit, and the fifth light-emitting unit contain the same material,
wherein the first charge-generation layer, the second charge-generation layer, and the third charge-generation layer contain the same material, and
wherein the second light-emitting unit, the fourth light-emitting unit, and the sixth light-emitting unit contain the same material.

19. A method for manufacturing a display apparatus comprising a plurality of pixel electrodes each comprising a first conductive layer, a second conductive layer, and a third conductive layer, the method comprising the steps of:
forming a first conductive film, a second conductive film, and a third conductive film in this order over an insulating layer;
processing the third conductive film, the second conductive film, and the first conductive film into the third conductive layer, the second conductive layer, and the first conductive layer by first dry etching;
processing a side surface of the second conductive layer by isotropic etching;
forming a depressed portion in a region of the insulating layer not overlapping with the plurality of pixel electrodes by second dry etching; and
forming an EL film by an evaporation method,
wherein an etching rate of the second conductive layer is higher than an etching rate of the third conductive layer in the isotropic etching, and
wherein the EL film is divided into first EL layers formed over the plurality of pixel electrodes and second EL layers formed between the plurality of pixel electrodes in a self-aligned manner.

20. The method for manufacturing a display apparatus, according to claim 19,
wherein a gas containing chlorine is used for the isotropic etching.
